(19) United States
(12) Patent Application Publication
(10) Pub. No.: US 2010/0203445 A1
(43) Pub. Date: Aug. 12, 2010

(54) NEGATIVE RESIST COMPOSITION AND RESIST PATTERN FORMING METHOD USING THE SAME

(75) Inventors: Wataru Hoshino, Minami-Ashigara-shi (JP); Masahiro Yoshidome, Haibara-gun (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/679,974

(22) PCT Filed: Sep. 22, 2008
(86) PCT No.: PCT/JP2008/067122

§ 371 Date: Mar. 25, 2010

(30) Foreign Application Priority Data
Sep. 26, 2007 (JP) 2007-250035
Mar. 21, 2008 (JP) 2008-074734

(51) Int. Cl. G03F 7/004; G03F 7/20

(52) U.S. Cl. 430/270.1; 430/325

(57) ABSTRACT

An object of the present invention is to solve the technical task of enhancing the performance in micro-photofabrication using far ultraviolet light, particularly ArF excimer laser at a wavelength of 193 nm, and more specifically, provide a negative resist composition hardly allowing occurrence of pattern collapse and exhibiting good resolution even in the formation of a fine pattern, and a resist pattern forming method using the composition, which are a negative resist composition comprising (A) an alkali-soluble resin, (B) a compound that contains a low molecular compound having a molecular weight of 2,000 or less and having an oxetane structure, and (C) a cationic photopolymerization initiator, and a resist pattern forming method using the composition.

### TECHNICAL FIELD

The present invention relates to a negative resist composition for use in lithography for the production of a semiconductor device such as IC, a liquid crystal display device or a circuit board such as thermal head and further for other photofabrication processes, and a resist pattern forming method using the composition. More specifically, the present invention relates to a negative resist composition suitable for exposure by a projection exposure apparatus using a light source of far ultraviolet light at a wavelength of 200 nm or less, and a resist pattern forming method using the composition.

### BACKGROUND ART

Recently, with the increasing progress to high-density and high-integration semiconductor devices, processing of a finer pattern is required. In order to meet this requirement, the wavelength of the exposure apparatus used for photolithography becomes shorter and shorter, and studies are being made at present even on use of short-wavelength excimer laser light (e.g., XeCl, KrF, ArF) out of far ultraviolet rays.

The resist composition includes “a positive type” using a resin sparingly-soluble or insoluble in a developer, where when exposed to radiation, the exposed area is solubilized in a developer and a pattern is thereby formed, and “a negative type” using a resin soluble in a developer, where when exposed to radiation, the exposed area becomes sparingly-soluble or insoluble in a developer and a pattern is thereby formed. Of these, the resist composition mainly used in practice at present is a positive resist composition.

The fabrication of a semiconductor device or the like involves formation of various patterns such as line, trench and hole, and higher resolution is demanded as the pattern becomes finer. In order to achieve this, a mask giving a high optical contrast is preferably used and in the case of using a mask giving a high optical contrast, a positive resist composition is advantageous for the formation of a line pattern, whereas a negative resist composition is advantageous for the formation of a trench pattern. Accordingly, in order to satisfy the requirement to form various patterns, development of not only a positive resist composition but also a negative resist composition is demanded.

In the case of using light at 248 nm of a KrF excimer laser as the exposure light source, a negative resist composition using a polymer where an acetal or ketal group is introduced as a protective group into a hydroxystyrene-based polymer having small light absorption has been proposed. This composition is suited for exposure using a KrF excimer laser but is not suitable for exposure using an ArF excimer laser, because when an ArF excimer laser is used, sensitivity decreases due to strong absorption at a wavelength of 193 nm and a problem such as deterioration of resolution is incurred.

Accordingly, development of a negative resist material more reduced in the absorption of light at 193 nm and assured of both good sensitivity and high dry etching resistance is demanded, and it is pressing to develop a resist suitable for an exposure method using ArF and capable of giving good sensitivity and high resolution.

As regards the resist for ArF exposure, a resist using a (meth)acrylic acid ester-based resin containing an aliphatic group having small absorption at a wavelength of 193 nm, and a resist having introduced thereinto an alicyclic aliphatic group for imparting etching resistance have been proposed, but sufficient resolution is not obtained.

For example, Patent Documents 1 to 4 use a negative resist where a urea-based crosslinking agent is incorporated into a resin obtained by copolymerizing an aliphatic group-containing repeating unit and an alkali-soluble group-containing repeating unit, but these resists have a problem such as failure in obtaining good resolution or occurrence of pattern collapse.

Patent Document 1: JP-A-2006-317803

Patent Document 2: JP-A-2000-147769

Patent Document 3: JP-A-2002-148805

Patent Document 4: JP-A-2001-343748

### DISCLOSURE OF THE INVENTION

### Problems that the Invention is to Solve

An object of the present invention is to solve the technical task of enhancing the performance in micro-photofabrication using far ultraviolet light, particularly ArF excimer laser at a wavelength of 193 nm, and more specifically, provide a negative resist composition hardly allowing occurrence of pattern collapse and exhibiting good resolution even in the formation of a fine pattern, and a resist pattern forming method using the composition.

### Means for Solving the Problems

As a result of intensive studies on constituent materials of a chemical amplification resist, the present inventors have found that the above-described object can be achieved by using specific materials, and the present invention has been accomplished based on this finding.

That is, the above-described object can be attained by the following constructions.

[1] A negative resist composition comprising (A) an alkali-soluble resin, (B) a compound that contains a low molecular compound having a molecular weight of 2,000 or less and having an oxetane structure, and (C) a cationic photopolymerization initiator.

[2] The negative resist composition as described in [1] above, wherein the (B) low molecular compound having an oxetane structure is a compound having a plurality of oxetane structures in the molecule.

[3] The negative resist composition as described in [1] above, wherein the (A) alkali-soluble resin contains (a1) a repeating unit containing a group having solubility in an alkali developer and (a2) a repeating unit having an alicyclic group.

[4] The negative resist composition as described in [1] above, wherein the (A) alkali-soluble resin further contains (a3) a repeating unit having an oxetane structure.

[5] The negative resist composition as described in [1] above, wherein the acid generated from the component (C) upon irradiation with an actinic ray or radiation has a pKa of −8 or less.

[6] A resist pattern forming method comprising a step of forming a resist film by using the negative resist composition described in [1] above, a step of exposing the resist film, and a step of developing the resist film.

Furthermore, the preferred embodiment of the present invention is achieved by the following constructions.

[7] The negative resist composition as described in [1], wherein the acid generated from the component (C) upon irradiation with an actinic ray or radiation is a fluorinated sulfonimide acid compound.

[8] The negative resist composition as described in [7], wherein the fluorinated sulfonimide acid compound is represented by the following formula (I):

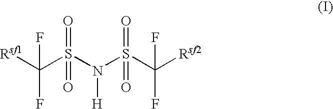

wherein each of R^{sf1} and R^{sf2} independently represents a hydrogen atom, a fluorine atom or an alkyl group, provided that R^{sf1} and R^{sf2} may combine with each other to form a ring.

[9] The negative resist composition as described in [1], wherein the acid generated from the component (C) upon irradiation with an actinic ray or radiation is a fluorinated sulfonmethide acid compound.

[10] The negative resist composition as described in [9], wherein the fluorinated sulfonmethide acid compound is represented by the following formula (II):

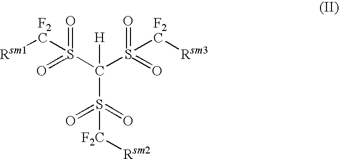

wherein each of R^{sm1} to R^{sm3} independently represents a hydrogen atom, a fluorine atom or an alkyl group, and any two members may combine with each other to form a ring.

### ADVANTAGE OF THE INVENTION

According to the present invention, a negative resist composition enabling formation of a fine pattern with high resolution and hardly allowing occurrence of pattern collapse, and a resist pattern forming method using the composition can be provided.

### BEST MODE FOR CARRYING OUT THE INVENTION

Respective components of the negative resist composition of the present invention are described in detail below.

Incidentally, in the present invention, when a group (atomic group) is denoted without specifying whether substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group).

The negative resist composition of the present invention comprises (A) an alkali-soluble resin, (B) a low molecular compound having an oxetane structure, and (C) a cationic photopolymerization initiator. In the negative resist composition of the present invention, by the action of an acid generated from the (C) cationic photopolymerization initiator upon exposure at the formation of a resist pattern, a polymerization reaction occurs between (B) oxetane structure-containing low molecular compounds (depending on the case, between (A) an alkali-soluble resin and (B) a low molecular compound having an oxetane structure) and a three-dimensional structure is formed in the exposed area, whereby the exposed area is insolubilized in an alkali developer and a high contrast for an alkali developer is produced between the exposed area and the unexposed area.

Thanks to such an action, only the exposed area is selectively insolubilized in alkali, and a fine pattern can be thereby formed.

### (A) Alkali-Soluble Resin

The negative resist composition of the present invention contains (A) an alkali-soluble resin.

The alkali-soluble resin is generally synthesized by the polymerization, such as radical polymerization, of a monomer having a partial structure to be polymerized and contains a repeating unit derived from the monomer having a partial structure to be polymerized. Examples of the partial structure to be polymerized include an ethylenically polymerizable partial structure.

As for the repeating unit used in the alkali-soluble resin (A), at least one kind of a repeating unit selected from repeating units derived from monomers having an ethylenically polymerizable partial structure represented by the following formula (ASM-1) or (ASM-2) is preferably used.

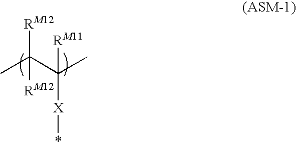

In formula (ASM-1), each of R^{M11} and R^{M12} independently represents a hydrogen atom, a halogen atom or an organic group. Each R^{M12} may be the same as or different from every other R^{M12}.

X represents a single bond or a divalent linking group.

The bond indicated by * represents a bond to an arbitrary group present on the side chain of the alkali-soluble resin.

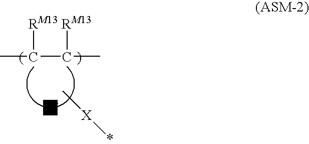

In formula (ASM-2), each R^{M13} independently represents a hydrogen atom, a halogen atom or an organic group.

Z′ represents an atomic group for forming an alicyclic structure together with two carbon atoms shown in formula (ASM-2).

X represents a single bond or a divalent linking group.

The bond indicated by * represents a bond to an arbitrary group present on the side chain of the alkali-soluble resin.

Examples of the organic group in R^{M11} to R^{M13} include an alkyl group, an alkyl halide group, an alkoxy group, an alkoxy halide group, a carboxyl group and a cyano group. These groups may further have a substituent, and examples of the substituent include a halogen atom, a hydroxyl group, a cyano group, a thiol group, an alkoxy group, an alkylthio group, an alkoxycarbonyl group, an alkylcarbonyloxy group and an alkylamide group.

R^{M11} is preferably a hydrogen atom, an alkyl group (preferably having a carbon number of 1 to 6), an alkyl group substituted by a hydroxyl group, an alkyl group substituted by an alkoxy group, an alkyl group substituted by an alkylcarbonyloxy group, a carboxyl group or an alkyl halide group.

R^{M12} is preferably, each independently, a hydrogen atom, an alkyl group (preferably having a carbon number of 1 to 6), a carboxyl group or an alkyl halide group.

R^{M13} is preferably, each independently, a hydrogen atom, a halogen atom (fluorine, chlorine, bromine, iodine), an alkyl group (preferably having a carbon number of 1 to 6), a carboxyl group, an alkoxy group (preferably having a carbon number of 1 to 6) or the like. These groups may further substituted by a halogen atom or the like.

Examples of the divalent linking group of X include —C(═O)—, an oxygen atom, a sulfur atom, —N(R^{b})—, an alkylene group, a cycloalkylene group, and a combination of two or more thereof. In the formula, R^{b} represents a hydrogen atom or an alkyl group.

The alicyclic structure formed by Z′ together with two carbon atoms shown in formula (ASM-2) may be substituted by a halogen atom or an organic group. Examples of the organic group that may be substituted on the alicyclic structure include an alkyl group (preferably having a carbon number of 1 to 6), a monocyclic or polycyclic cycloalkyl group (preferably having a carbon number of 3 to 20), an alkoxy group, an alkylamino group, an alkoxycarbonyl group, an alkylsulfone group and an alkylamide group.

In the case where Z′ forms an alicyclic structure together with two carbon atoms shown in formula (ASM-2), examples of the alicyclic structure include cyclopentane, cyclohexane, norbornane, tricyclodecane and tetracyclododecane.

The repeating unit containing a partial structure represented by formula (ASM-1) is preferably a repeating unit represented by the following formula (ASM-11):

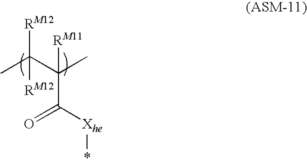

In formula (ASM-11), R^{M11} and R^{M12} have the same meanings as those in formula (ASM-1).

The bond indicated by * represents a bond to an arbitrary group present on the side chain of the alkali-soluble resin.

Xₕₑ represents an oxygen atom, a sulfur atom or —N(R^{he}) wherein R^{he} represents a hydrogen atom or an alkyl group.

The structure bonded through the bond indicated by * is preferably, as described later, a structure such as a group having solubility in an alkali developer, an aliphatic group, a group having an alicyclic hydrocarbon structure substituted by a polar group, a group having an oxetane structure, and a lactone-containing monocyclic or polycyclic aliphatic group.

Specific examples of the monomer corresponding to the repeating unit represented by formula (ASM-11) include an acrylic acid, a methacrylic acid, an α-hydroxymethylacrylic acid, a trifluoromethylacrylic acid, a maleic acid, a fumaric acid, an itaconic acid, and their ester, amide and acid anhydride.

The repeating unit represented by formula (ASM-2) is preferably a repeating unit represented by any one of the following formulae (ASM-2a) to (ASM-2c):

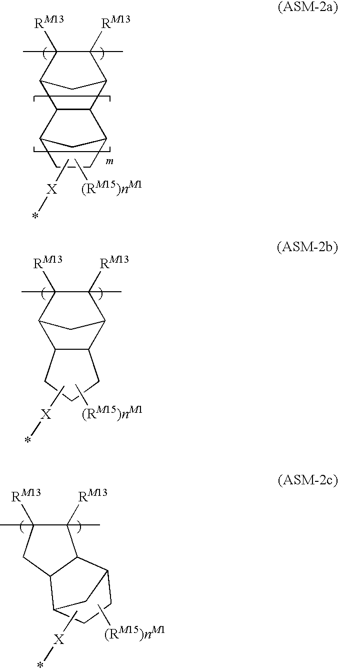

In formulae (ASM-2a) to (ASM-2c), R^{M13} and X have the same meanings as R^{M13} and X in formula (ASM-2).

R^{M15} represents, when a plurality of R^{M15}'s are present, each independently represents, an organic group.

m represents an integer of 0 or more and is preferably an integer of 0 to 2, more preferably 0 or 1.

n^{M1} represents an integer of 0 or more and is preferably an integer of 0 to 3.

The bond indicated by * represents a bond to an arbitrary group present on the side chain of the alkali-soluble resin.

Examples of the organic group in R^{M15} include a linear or branched alkyl group, a monocyclic or polycyclic cycloalkyl group, an alkoxy group, an alkylamino group, an alkoxycarbonyl group, an alkylsulfone group and an alkylamide group, which each may have a substituent.

The structure bonded through the bond indicated by * is preferably, as described later, a structure such as a group having solubility in an alkali developer, an aliphatic group, a group having an alicyclic hydrocarbon structure substituted by a polar group, a group having an oxetane structure, and a lactone-containing monocyclic or polycyclic aliphatic group.

Various structures working out to the side chain of the later-described alkali-soluble resin may be bonded directly to the partial structure represented by formula (ASM-1) or (ASM-2) to be polymerized or may be bonded to the partial structure represented by formula (ASM-1) or (ASM-2) to be polymerized, through a linking group (for example, at least one structure selected from a linear or branched aliphatic structure and a monocyclic or polycyclic aliphatic structure).

In the case of bonding through a linking group, examples of the repeating unit include the repeating units represented by the following formulae (ASS-1) to (ASS-3):

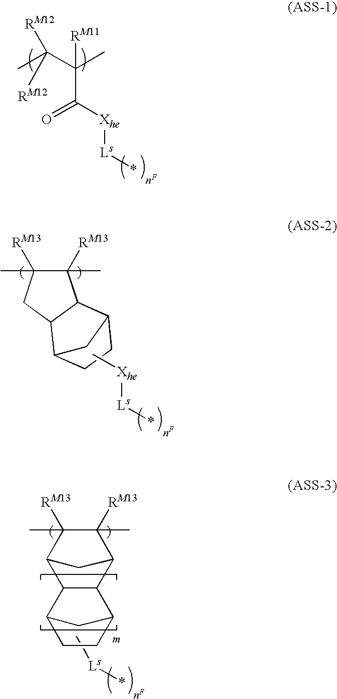

In formulae (ASS-1) to (ASS-3), R^{M11}, R^{M12} and R^{M13} have the same meanings as R^{M11}, R^{M12} and R^{M13} in formulae (ASM-1), (ASM-2) and (ASM-2a) to (ASM-2c).

Xₕₑ has the same meanings as Xₕₑ in formula (ASM-11).

The bond indicated by * represents a bond to an arbitrary group present on the side chain of the alkali-soluble resin.

L^{S} represents a single bond or an (n^{F}+1)-valent linking group.

m represents an integer of 0 or more and is preferably 0 or 1.

n^{F} represents an integer of 1 or more and is preferably 1.

The (n^{F}+1)-valent linking group of L^{S} includes an oxygen atom, a nitrogen atom, —N(R^{N})—, —C(═O)—, —S(═O)₂—, a linking group family shown below, and an (n^{F}+1)-valent group formed by removing (n^{F}−1) hydrogen atoms from a divalent group composed of a combination of the atoms or groups above.

R^{N} represents a hydrogen atom or an alkyl group.

The linking group family is preferably composed of a group having a linear or branched aliphatic structure or a monocyclic or polycyclic aliphatic structure. The linear or branched aliphatic structure preferably has a carbon number of 1 to 30, more preferably from 1 to 10. The monocyclic or polycyclic aliphatic structure preferably has a carbon number of 5 to 30, more preferably from 6 to 25.

Examples of the linking group family include structures shown by the following (SP1) and (SP2):

### Linking Group Family (SP1):

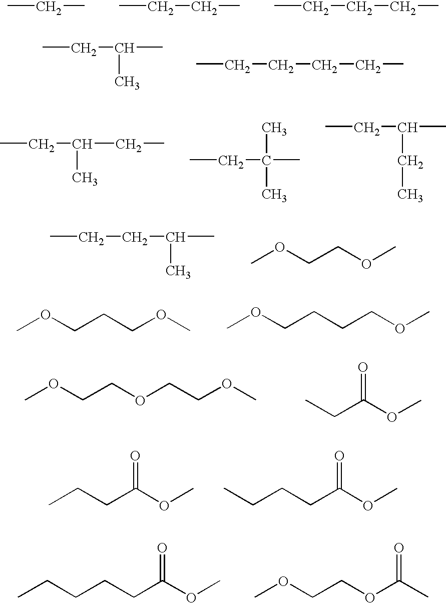

### Linking Group Family (SP2):

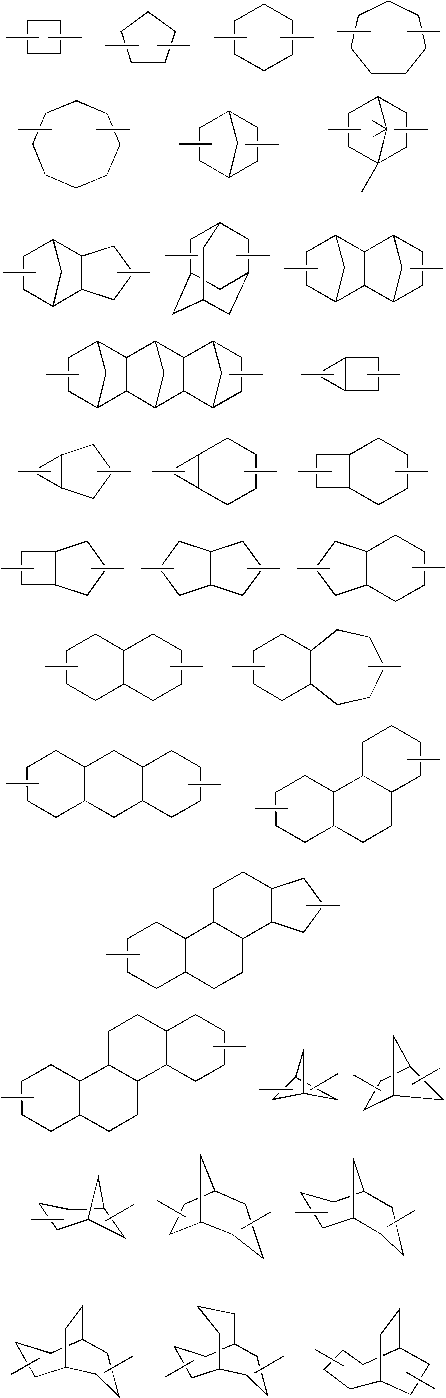

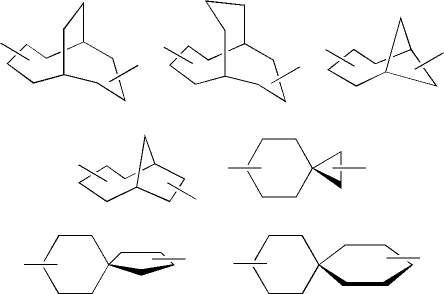

These structures may further have a substituent, and a polyvalent structure formed by removing an arbitrary number of hydrogen atoms from such an aliphatic structure is also included in the linking structure. Examples of the substituent include an alkyl group, an aryl group, an alkoxy group, an alkylcarbonyl group, an alkoxycarbonyl group, an alkylcarbonyloxy group, an alkylamino group, an alkylamide group, an alkylaminocarbonyl group, an alkylthio group, an alkylsulfone group, an alkylsulfonyl group and an alkylsulfonylamide group.

(a1) Alkali-Soluble Repeating Unit

The (A) alkali-soluble resin for use in the present invention preferably contains (a1) a repeating unit containing a group having solubility in an alkali developer (hereinafter, sometimes referred to as an “alkali-soluble group”). By virtue of having this repeating unit, the alkali-soluble resin dissolves in an alkali developer. Incidentally, the alkali-soluble resin is sufficient if when a film is formed using the resist composition, the film dissolves in an alkali developer, and the alkali-soluble resin need not necessarily have alkali developer solubility by itself, because a film formed using the resist composition often dissolves in an alkali developer depending on, for example, the property or content of other components contained in the resist composition. However, also in this case, the (A) alkali-soluble resin preferably contains (a1) a repeating unit having an alkali-soluble group.

Examples of the group having solubility in an alkali developer (alkali-soluble group) include organic groups including an organic group containing a fluorine-substituted alcohol structure, an organic group containing an carboxylic acid structure, an organic group containing a sulfonamide structure, an organic group containing a furfuryl alcohol structure, an organic group containing a carbamate structure, an organic group containing a tautomeric alcohol structure, an organic group containing a thiol structure, an organic group containing a ketone oxime structure, an organic group containing a dicarbonyl methylene structure, an organic group containing an N-hydroxysuccinimide structure, an organic group having a triazine skeleton, an organic group containing an amic acid structure, and an organic group containing a sulfonic acid structure.

Examples of the alkali-soluble group include the groups shown below.

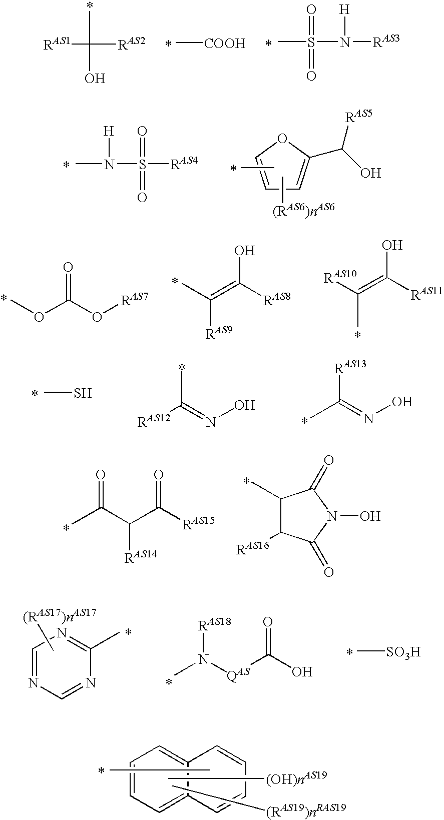

In examples of the alkali-soluble group above, * represents a bond to the resin structure. Preferably, * represents a bond that is bonded to * in the structure represented by formula (ASM-1) or (ASM-2).

The alkali-soluble group may be bonded directly to the partial structure represented by formula (ASM-1) or (ASM-2) to be polymerized or, as shown in formulae (ASS-1) to (ASS-3), may be bonded to the partial structure to be polymerized, through an organic group.

In examples of the alkali-soluble group above, each of R^{AS1} and R^{AS2} independently represents a hydrogen atom, a fluorine atom or a fluorine-substituted alkyl group, and at least one of R^{AS1} and R^{AS2} is a fluorine atom or a fluorine-substituted alkyl group. R^{AS1} and R^{AS2} may be the same or different.

Examples of the organic group containing such a fluorine-substituted alcohol structure are set forth below. In the following examples, * represents a bond. Preferably, * represents a bond that is bonded to * in the structure represented by formula (ASM-1) or (ASM-2).

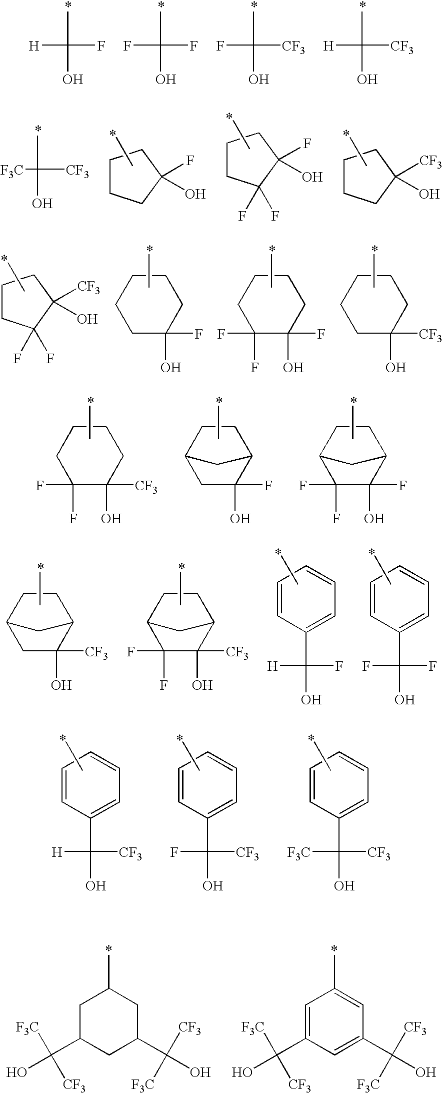

In examples of the alkali-soluble group above, each of R^{AS3} and R^{AS4} independently represents an alkyl group (linear or branched), a cycloalkyl group (monocyclic or polycyclic), an aryl group, an alkylcarbonyl group, a cycloalkylcarbonyl group, an alkylsulfonyl group or a cycloalkylsulfonyl group. These groups may further have a substituent. Also, these groups may further contain an ether structure, an ester structure, an amide structure, a sulfone structure or a sulfonyl structure. The hydrogen atom in R^{AS3} and R^{AS4} may be substituted for by a fluorine atom. In view of alkali solubility, R^{AS3} and R^{AS4} are preferably a linear or branched alkyl group which may contain an ether or ester structure, more preferably a group where the hydrogen atom is substituted for by a fluorine atom.

Examples of R^{AS3} and R^{AS4} include a methyl group, an ethyl group, a 2-hydroxyethyl group, a 2-methoxyethyl group, a 2-methoxycarbonylethyl group, a 2-tert-butoxycarbonylethyl group, a cyclopentyl group, a cyclohexyl group, a norbornyl group, an isobornyl group, a tricyclodecanyl group, a tetracyclododecanyl group, an adamantyl group, a trifluoromethyl group and a nonafluorobutyl group.

Examples of the organic group containing a sulfonamide structure (—SO₂NH—) include the groups shown below. In the following examples, * represents a bond. Preferably, * represents a bond that is bonded to * in the structure represented by formula (ASM-1) or (ASM-2).

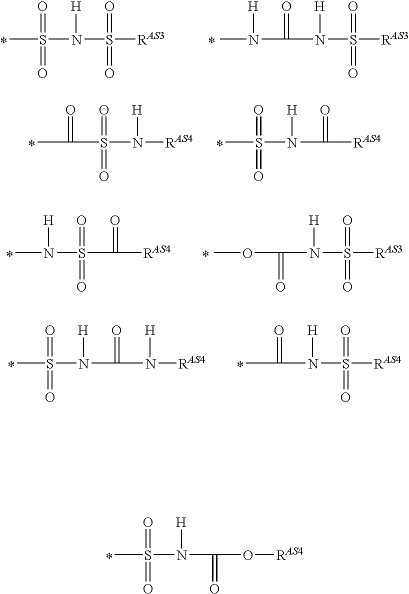

In the formulae, each of R^{AS5} and R^{AS6} independently represents a hydrogen atom, an alkyl group (preferably having a carbon number of 1 to 6), a cycloalkyl group (preferably having a carbon number of 4 to 7), an alkoxy group (preferably having a carbon number of 1 to 6), an alkylcarbonyl group (preferably having a carbon number of 1 to 6), an alkylsulfone group (preferably having a carbon number of 1 to 6) or an alkylamide group (preferably having a carbon number of 1 to 6), and n^{AS6} represents an integer of 0 to 5. n^{AS6} is preferably an integer of 0 to 2. In the case where a plurality of R^{AS6}'s are present, each may be the same as or different from every other R^{AS6}. Also, these groups may be further substituted.

R^{AS7} represents a hydrogen atom, an alkyl group (preferably having a carbon number of 1 to 6) or a cycloalkyl group (preferably having a carbon number of 4 to 7). These groups may be further substituted.

Each of R^{AS8} and R^{AS14} independently represents a hydrogen atom, an alkyl group (preferably having a carbon number of 1 to 6) or a cycloalkyl group (preferably having a carbon number of 4 to 7). These groups may be further substituted.

R^{AS15} represents a hydrogen atom, an alkyl group (preferably having a carbon number of 1 to 6), a cycloalkyl group (preferably having a carbon number of 4 to 7) or an alkoxy group (preferably having a carbon number of 1 to 6). These groups may be further substituted.

R^{AS16} represents a hydrogen atom, an alkyl group (preferably having a carbon number of 1 to 6) or a cycloalkyl group (preferably having a carbon number of 4 to 7). These groups may be further substituted.

R^{AS17} represents a hydrogen atom, an alkyl group (preferably having a carbon number of 1 to 6), a cycloalkyl group (preferably having a carbon number of 4 to 7) or an alkylamino group (preferably having a carbon number of 1 to 6). In the case where a plurality of R^{AS17}'s are present, each may be the same as or different from every other R^{AS17}. Also, these groups may be further substituted.

n^{AS17} is an integer of 0 to 2.

R^{AS18} represents an alkyl group (preferably having a carbon number of 1 to 6) or a cycloalkyl group (preferably having a carbon number of 4 to 7), and Q^{AS} represents a single bond or an alkylene group (preferably having a carbon number of 1 to 2). These groups may be further substituted.

R^{AS19} represents an alkyl group (preferably having a carbon number of 1 to 10), a cycloalkyl group (preferably having a carbon number of 3 to 20), an alkoxy group, an alkylthio group, an alkylcarbonyloxy group, an alkoxycarbonyl group, an alkyl amino group or an alkylamide group. In the case where a plurality of R^{AS19}'s are present, each may be the same as or different from every other R^{AS19}.

n^{AS19} represents an integer of 1 to 7 and is preferably 1 or 2, more preferably 1.

n^{RAS19} represents an integer of 0 to 7 and is preferably an integer of 0 to 2, more preferably 0.

Among these alkali-soluble groups, an organic group containing a fluorine-substituted alcohol structure, an organic group containing a carboxylic acid structure, an organic group containing a sulfonamide structure, an organic group containing a sulfonimide structure, and an organic group containing a dicarbonyl methylene structure are preferred.

Examples of the (a1) repeating unit having an alkali-soluble group are set forth below, but the present invention is not limited thereto. In the structural formulae, R^{x} represents a hydrogen atom, a methyl group, a trifluoromethyl group or a hydroxymethyl group.

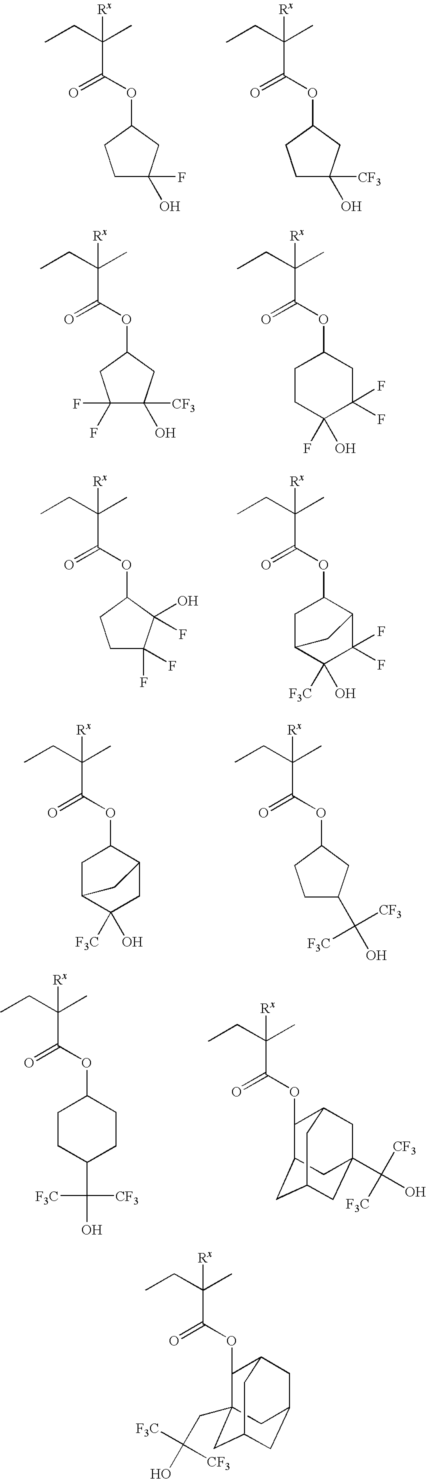

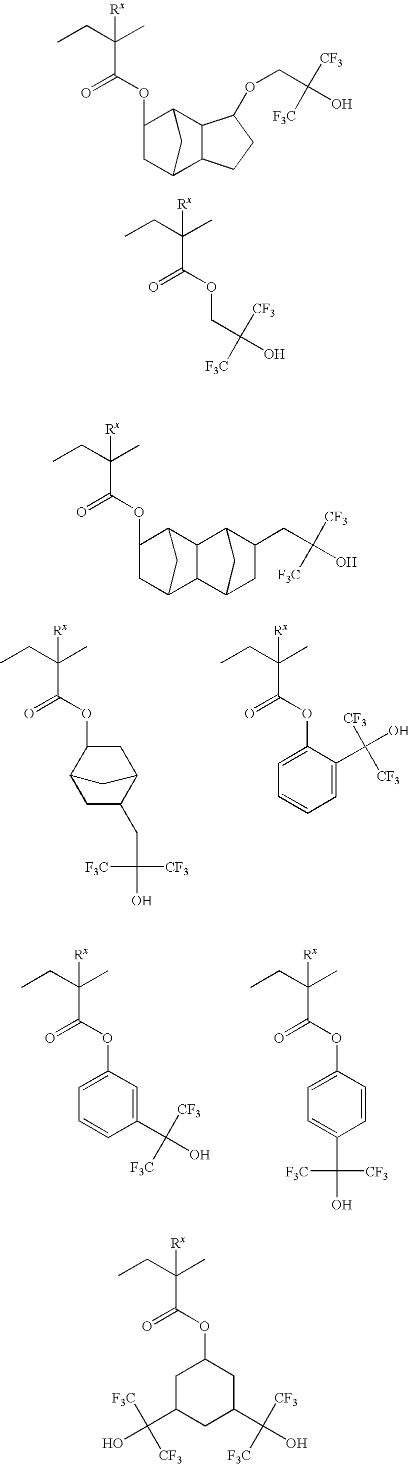

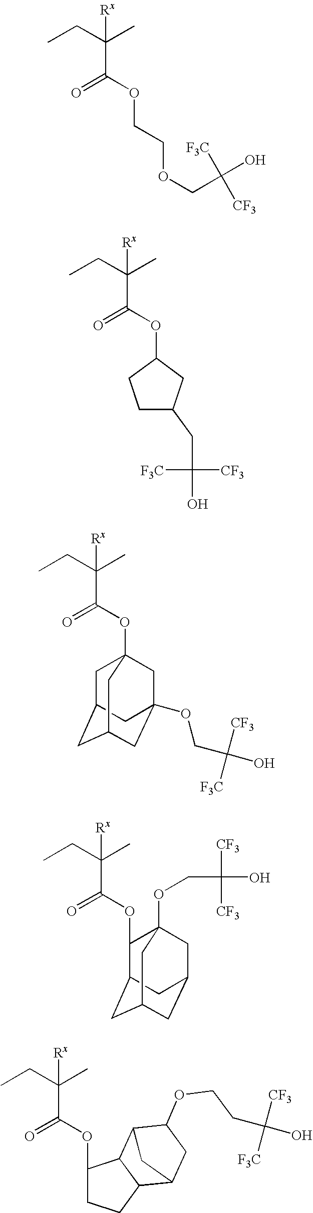

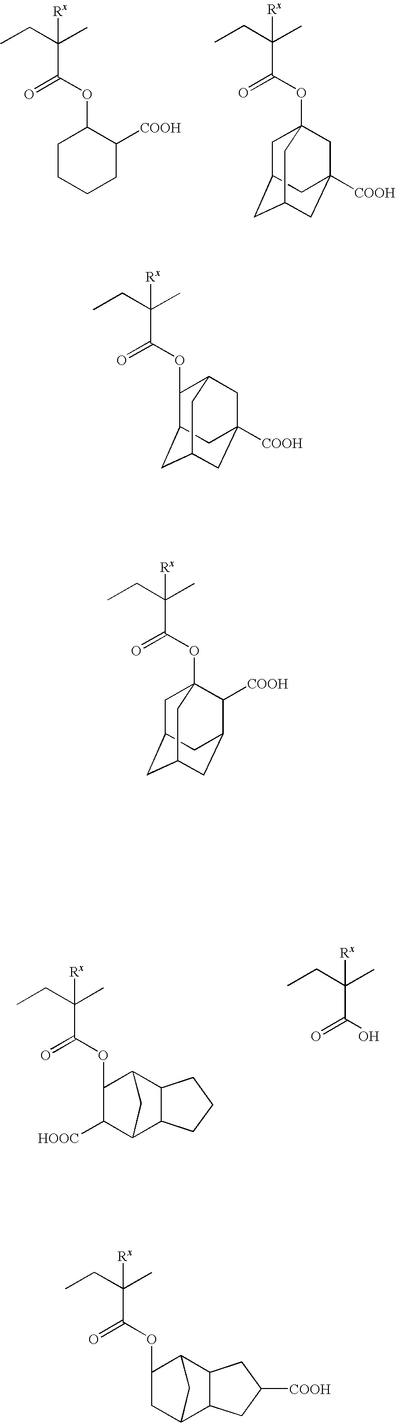

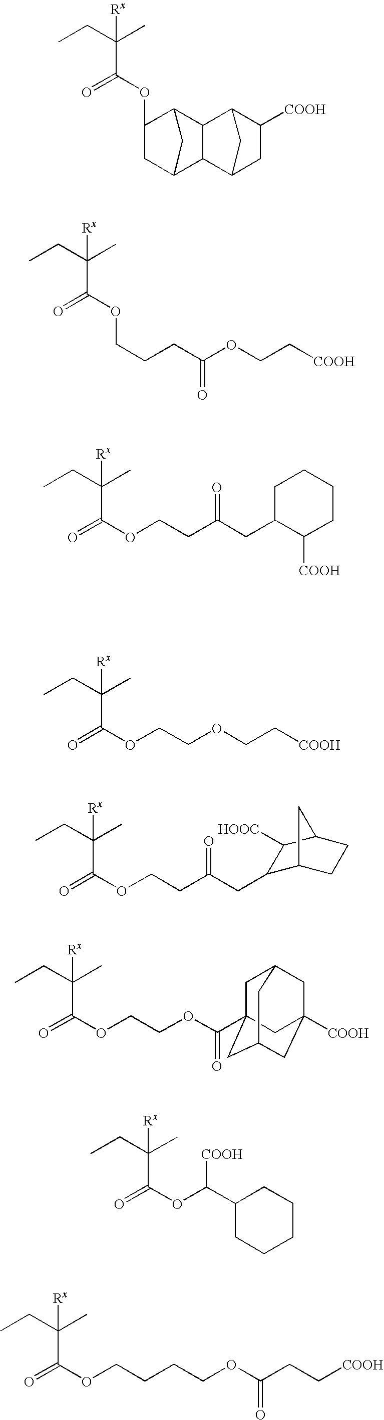

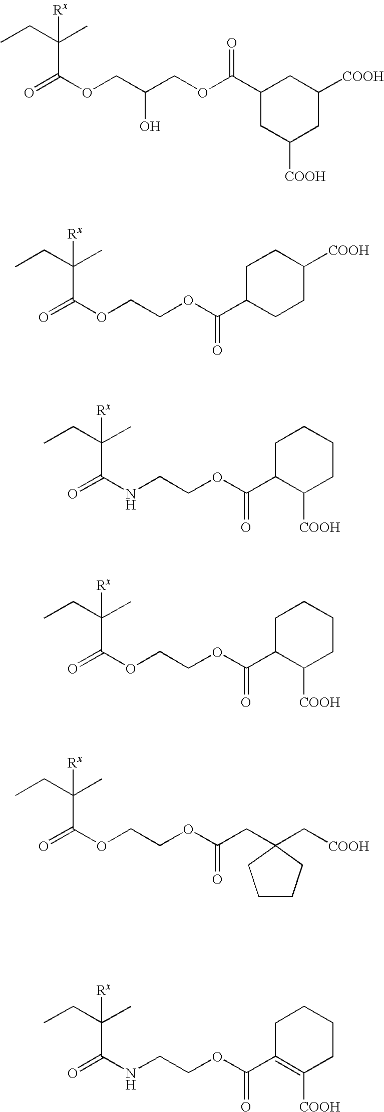

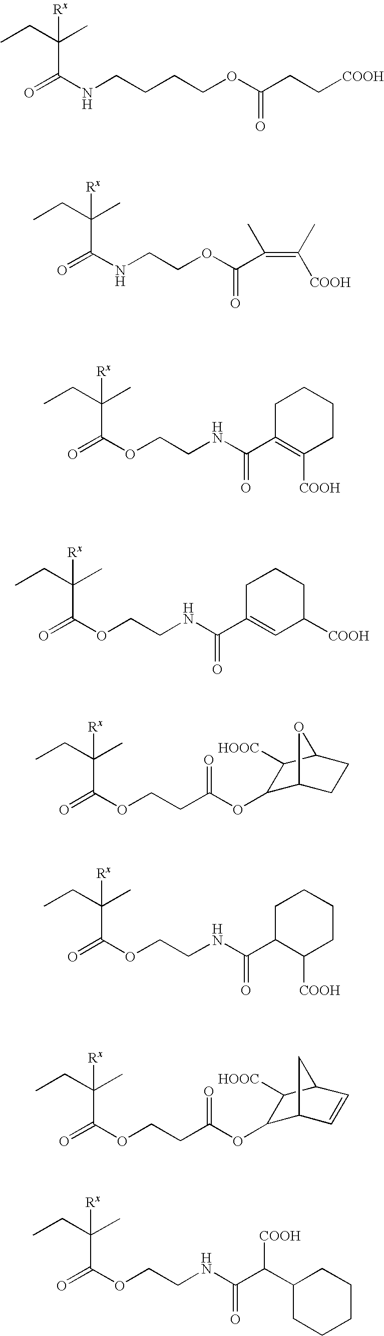

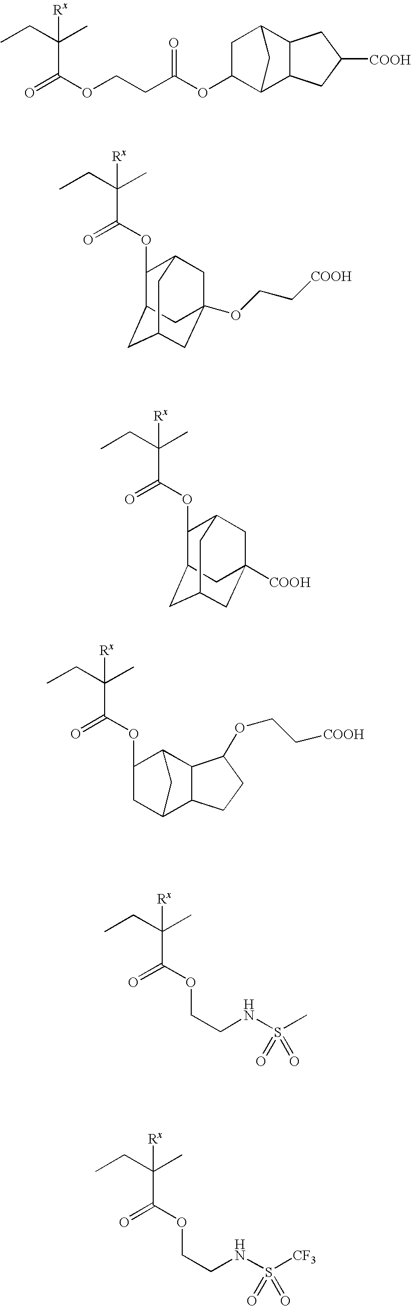

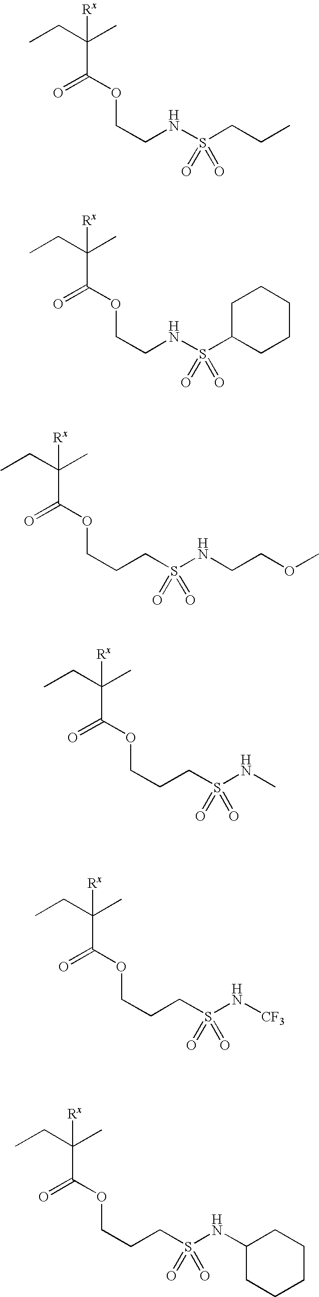

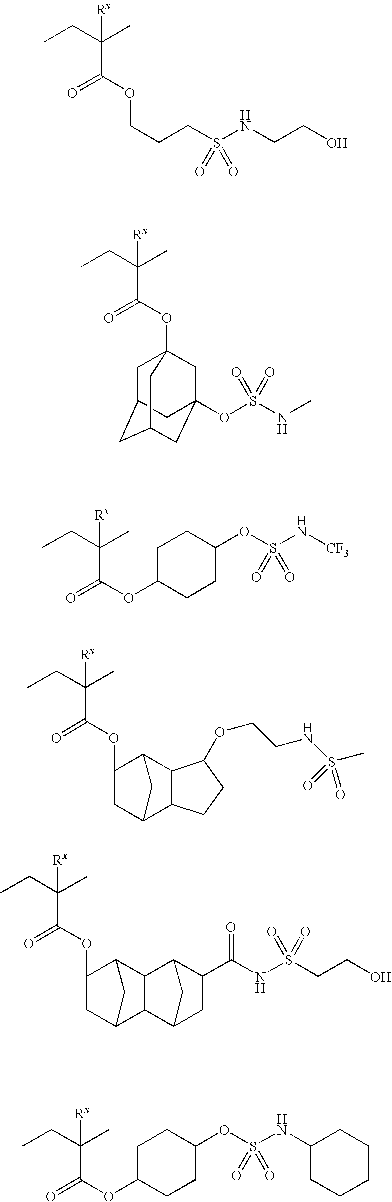

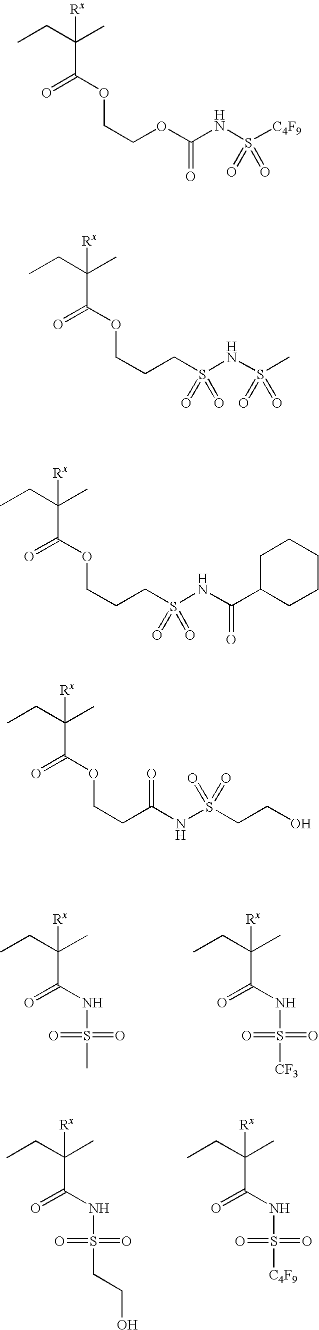

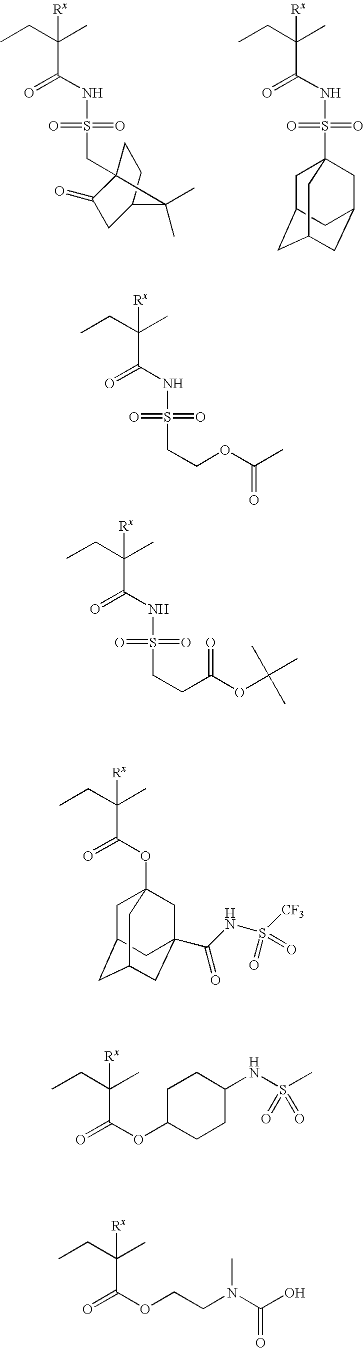

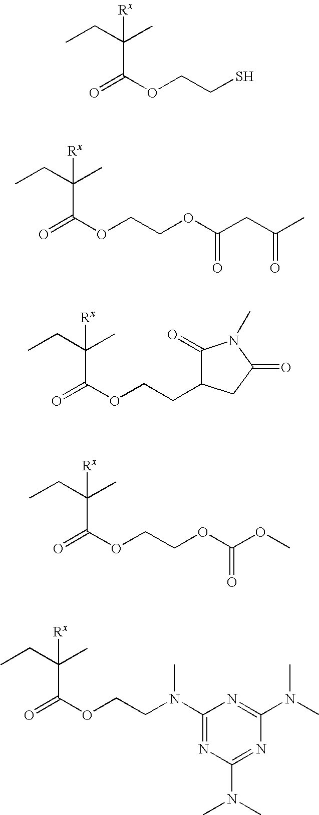

(a2) Repeating Unit Having Aliphatic Group

The alkali-soluble resin for use in the present invention may contain (a2) a repeating unit having an aliphatic group. By virtue of containing this repeating unit, the dissolution rate of the resist film can be adjusted or the etching resistance can be increased.

The aliphatic group indicates a group having a substituted or unsubstituted, linear, branched, monocyclic or polycyclic aliphatic group. However, the aliphatic group is preferably not a group having solubility in an alkali developer but a group composed of a carbon atom and a hydrogen atom. In view of etching resistance, a polycyclic aliphatic group is preferred.

Examples of the linear or branched aliphatic group include a methyl group, an ethyl group, an n-propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl and an eicosyl group; examples of the monocyclic aliphatic group include a cyclobutyl group, a cyclopentyl group, a cyclohexyl group, a cycloheptyl and a cyclooctyl group; and examples of the polycyclic aliphatic group include a norbornyl group, an isobornyl group, a tricyclodecanyl group, a tetracyclododecanyl group, a hexacycloheptadecanyl group, an adamantyl group, a diamantyl group, a spirodecanyl and a spiroundecanyl group.

The aliphatic group may be substituted. The substituent includes various substituents such as halogen atom, alkyl group, alkoxy group, amino group, alkoxycarbonyl group, alkylsulfone group, cyano group and hydroxyl group. A substituent appropriate for enhancing the performance of the resist, such as etching resistance and hydrophilicity/hydrophobicity, may be selected from these substituents and used.

Examples of the repeating unit having an aliphatic group are set forth below, but the present invention is not limited thereto. In the structural formulae, R^{X} represents a hydrogen atom, a methyl group, a trifluoromethyl group or a hydroxymethyl group.

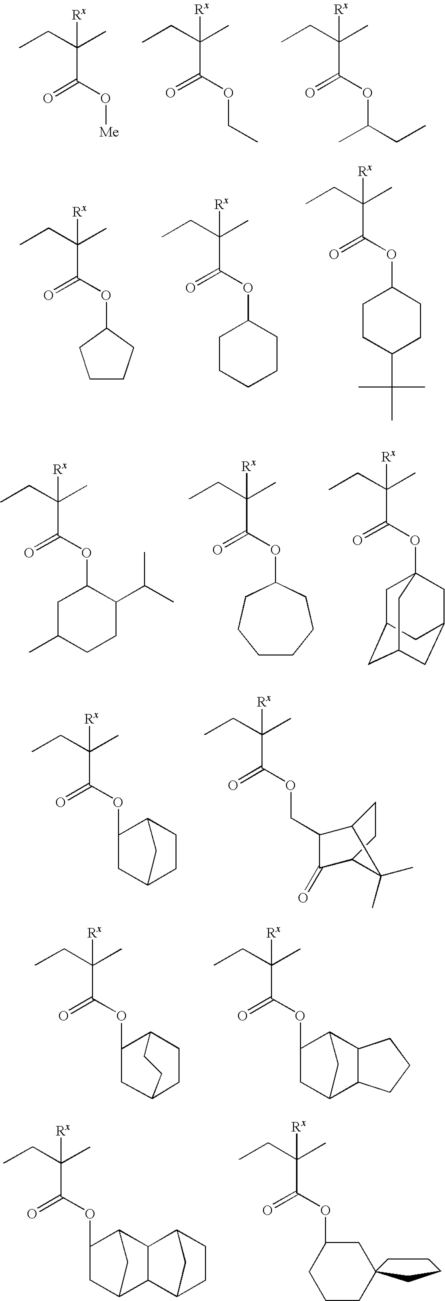

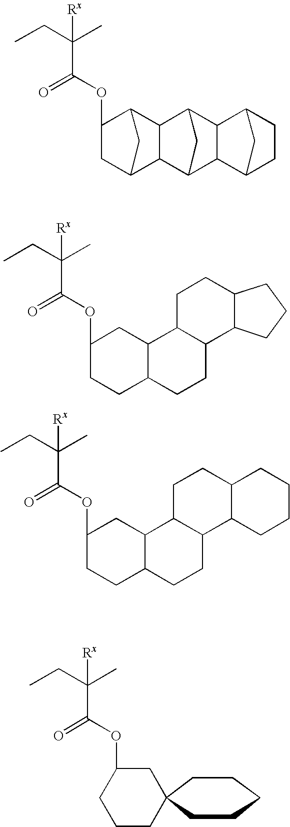

The alkali-soluble resin for use in the present invention may have a repeating unit containing a group having an alicyclic hydrocarbon structure substituted by a polar group. Thanks to this repeating unit, for example, the adhesion to substrate and the affinity for developer can be enhanced. The alicyclic hydrocarbon structure of the alicyclic hydrocarbon structure substituted by a polar group may include a monocyclic structure and a polycyclic structure but in view of etching resistance, a polycyclic structure is preferred.

Specific examples of the alicyclic hydrocarbon structure include: as the monocyclic structure, a cyclobutyl structure, a cyclopentyl structure, a cyclohexyl structure, a cycloheptyl structure and a cyclooctyl structure; and as the polycyclic structure, a norbornyl structure, an isobornyl structure, a tricyclodecanyl structure, a tetracyclododecanyl structure, a hexacycloheptadecanyl structure, an adamantyl structure, a diamantyl structure, a spirodecanyl structure and a spiroundecanyl structure. Among these, an adamantyl structure, a diamantyl structure and a norbornyl structure are preferred.

The polar group includes various polar groups, but above all, a hydroxyl group and a cyano group are preferred. The group having an alicyclic hydrocarbon structure substituted by a polar group is preferably a group represented by the following formulae (KCA-1) to (KCA-4):

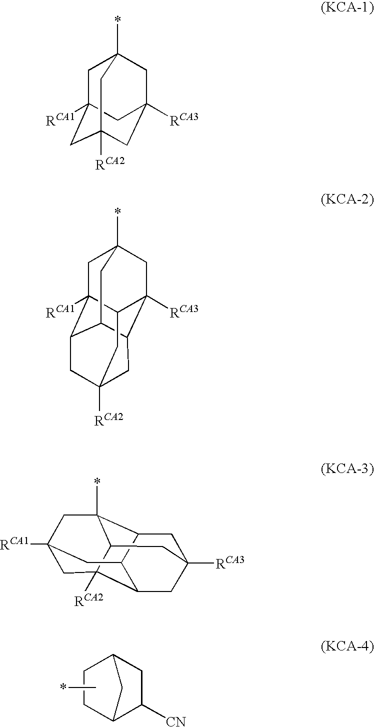

In formulae (KCA-1) to (KCA-4), each of R^{CA1} to R^{CA3} independently represents a hydrogen atom, a hydroxyl group or a cyano group, provided that at least one of R^{CA1} to R^{CA3} represents a hydroxyl group or a cyano group. A structure where one or two members out of R^{CA1} to R^{CA3} are a hydroxyl group with the remaining being a hydrogen atom is preferred. In formula (KCA-1), it is more preferred that two members out of R^{CA1} to R^{CA3} are a hydroxyl group and the remaining is a hydrogen atom.

* represents a bond. Preferably, * represents a bond that is bonded to * in the structure represented by formula (ASM-1) or (ASM-2).

Specific examples of the repeating unit having a group represented by formulae (KCA-1) to (KCA-4) are set forth below, but the present invention is not limited thereto. R^{X} represents a hydrogen atom, a methyl group, a trifluoromethyl group or a hydroxymethyl group.

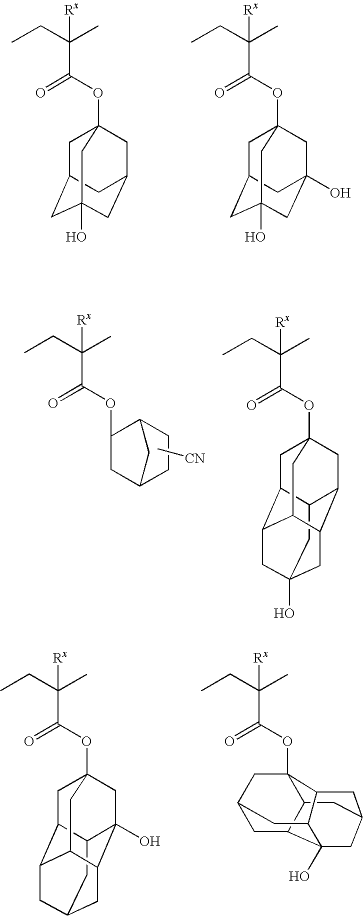

The alkali-soluble resin for use in the present invention may contain, as the (a2) repeating unit having an aliphatic group, a repeating unit represented by the following formula (KI):

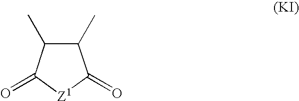

In formula (KI), Z¹ represents —O— or —N(R^{Z11})—. R^{Z11} represents a hydrogen atom, a hydroxyl group, an alkyl group or —OSO₂—R^{Z12}. R^{Z12} represents an alkyl group, a cycloalkyl group or a camphor residue. The alkyl group of R^{Z11} and R^{Z12} may be substituted by a halogen atom (preferably fluorine atom) or the like.

Specific examples of the repeating unit represented by formula (KI) are set forth below, but the present invention is not limited thereto.

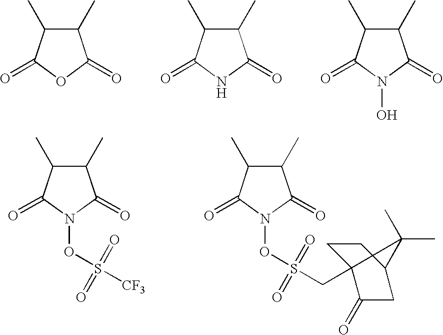

(a3) Repeating Unit Having Polymerizable Group (Oxetane Structure)

The alkali-soluble resin for use in the present invention may further contain (a3) a repeating unit having an oxetane structure. In this case, since the alkali-soluble resin contains a repeating unit having an oxetane structure, the oxetane structure and the later-described cationic polymerizable monomer (a low molecular compound having a molecular weight of 2,000 or less and having an oxetane structure) bring about a cationic polymerization reaction and the exposed area forms a three-dimensional structure involving the resin components, so that a high dissolution contrast for an alkali developer can be obtained.

The oxetane structure as used herein indicates a cyclic structure composed of one hydrogen atom and three carbon atoms.

The repeating unit having an oxetane structure can be formed, for example, by polymerizing a monomer having an oxetane structure and corresponding to the repeating unit represented by formula (ASM-1) or (ASM-2).

The monomer having an oxetane structure and corresponding to the repeating unit represented by formula (ASM-1) or (ASM-2) can be synthesized by a known method, or a commercial product available from Toagosei Chemical Industry Co., Ltd. and the like may be used.

The oxetane structure includes, as one embodiment, a structure represented by the following formula (OXM):

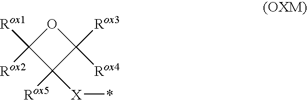

In formula (OXM), each of R^{OX1} to R^{OX5} independently represents a hydrogen atom, a halogen atom or a monovalent organic group.

* represents a bond. Preferably, * represents a bond that is bonded to * in the structure represented by formula (ASM-1) or (ASM-2).

X represents a single bond or a linking group.

Two or more members selected from R^{OX1}, R^{OX2} and R^{OX5}, two or more members selected from R^{OX3}, R^{OX4} and X, or R^{OX5} and X may combine with each other to form a ring.

Preferred examples of R^{OX1} to R^{OX5} include a hydrogen atom, a halogen atom, an amino group, a carboxyl group, an alkoxycarbonyl group, a cyano group, an alkyl group which may have a substituent, an alkoxy group which may have a substituent, and an alkylamino group which may have a substituent. Examples of the substituent which these groups may further have include a hydroxyl group, a cyano group, an alkoxy group, an alkylcarbonyl group, an alkoxycarbonyl group, an alkylcarbonyloxy group, an alkylthio group, an alkylsulfone group, an alkylsulfonyl group, an alkylamino group and an alkylamide group.

Examples of the linking group of X include an alkylene group, a cycloalkylene group, an ether bond, and a group formed by connecting a plurality of these groups or bonds.

Incidentally, as for the structure represented by formula (OXM), an embodiment where R^{OX1} to R^{OX4} are a hydrogen atom, R^{OX5} is an alkyl group having a carbon number of 1 to 3 and X is a single bond or an alkylene group having a carbon number of 1 to 3 is preferred.

The repeating unit having an oxetane structure may contain one oxetane structure or a plurality of oxetane structures, but the number of oxetane structures is preferably from 1 to 4, more preferably from 1 to 2.

Examples of the repeating unit having an oxetane structure are set forth below, but the present invention is not limited thereto.

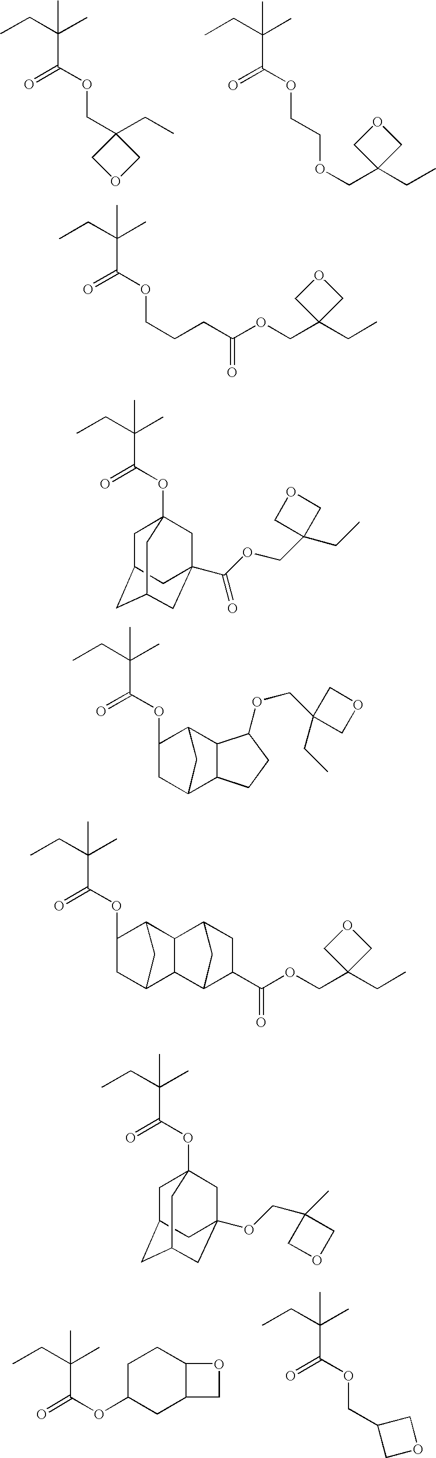

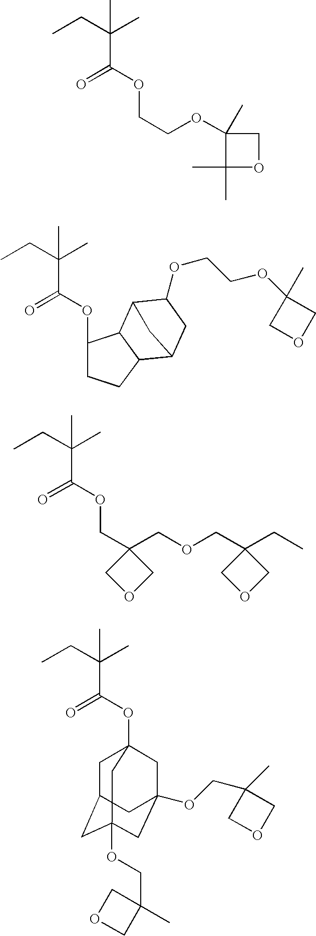

(a4) Repeating Unit Having Lactone Structure

The (A) alkali-soluble resin for use in the present invention may contain a repeating unit having a lactone structure.

The lactone structure is ring-opened by the effect of an alkali developer and generates a carboxylic acid. The generated carboxylic acid affords a function of elevating the solubility in an alkali developer. At this time, the exposed area is considered to form a three-dimensional network structure by crosslinking and allow less penetration of the developer compared with the unexposed area. The lactone structure itself is more hydrophobic than the carboxyl group after ring opening and the affinity for an alkali developer in the exposed area becomes lower than that in the unexposed area. Thanks to such an action, when the resin has a lactone structure, it is expected that the dissolution contrast between the unexposed area and the exposed area is more increased or the exposed area is prevented from swelling, which leads to enhancement of the resolution.

As for the lactone structure, any structure may be used as long as it has a lactone structure, but a 5- to 7-membered ring lactone structure is preferred, and the 5- to 7-membered ring lactone structure is preferably condensed with another ring structure in the form of forming a bicyclo or Spiro structure. It is more preferred to have a repeating unit having a lactone structure represented by any one of the following formulae (LC1-1) to (LC1-16). The group having a lactone structure may be bonded directly to the main chain. Among these lactone structures, preferred are (LC1-1), (LC1-4), (LC1-5), (LC1-6), (LC1-13) and (LC1-14), and more preferred is (LC1-4). By virtue of using a specific lactone structure, the line edge roughness and development defect are improved.

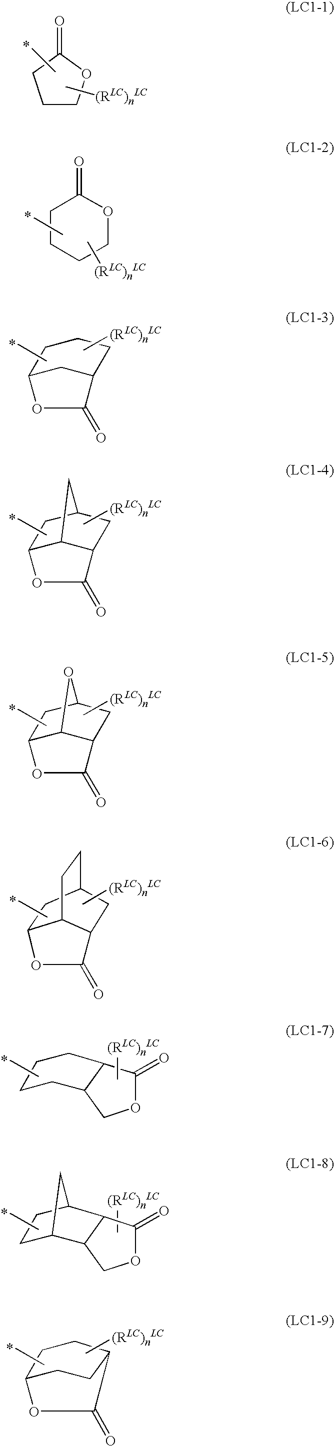

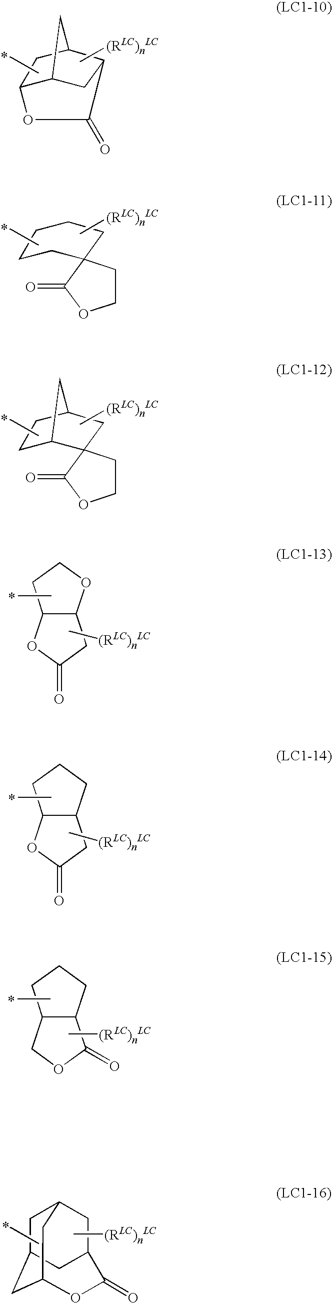

The lactone structure moiety may or may not have a substituent (R^{LC}). Preferred examples of the substituent (R^{LC}) include an alkyl group having a carbon number of 1 to 8, a cycloalkyl group having a carbon number of 4 to 7, an alkoxy group having a carbon number of 1 to 8, an alkoxycarbonyl group having a carbon number of 1 to 8, a carboxyl group, a halogen atom, a hydroxyl group, a cyano group and an acid-decomposable group. Among these, an alkyl group having a carbon number of 1 to 4, a cyano group and an acid-decomposable group are more preferred. n^{LC} represents an integer of 0 to 4. When n^{LC} is an integer of 2 or more, each R^{LC} may be the same as or different from every other R^{LC} and also, the plurality of R^{LC}'s may combine with each other to form a ring.

* represents a bond that is bonded to formula (ASM-1) or (ASM-2).

The repeating unit having a lactone structure usually has an optical isomer, but any optical isomer may be used. One optical isomer may be used alone or a plurality of optical isomers may be mixed and used. In the case of mainly using one optical isomer, the optical purity (ee) thereof is preferably 90 or more, more preferably 95 or more.

Specific examples of the repeating unit having a lactone structure are set forth below, but the present invention is not limited thereto. In the formulae, R^{X} is a hydrogen atom, a methyl group, a trifluoromethyl group or a hydroxymethyl group.

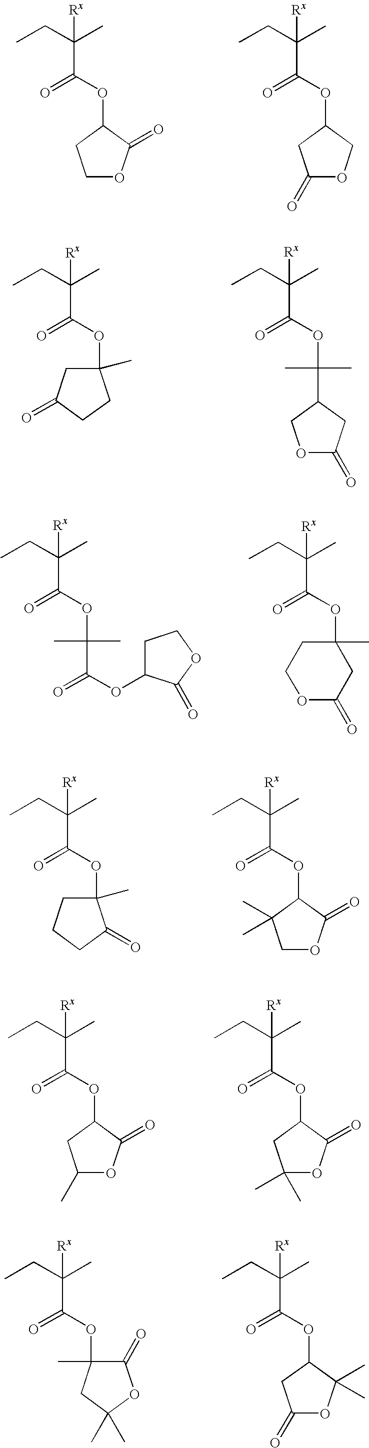

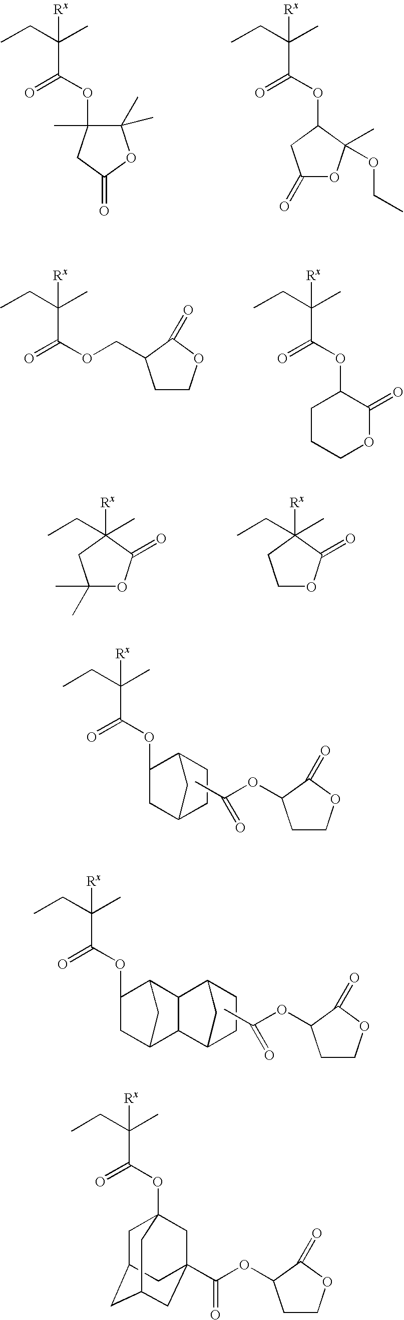

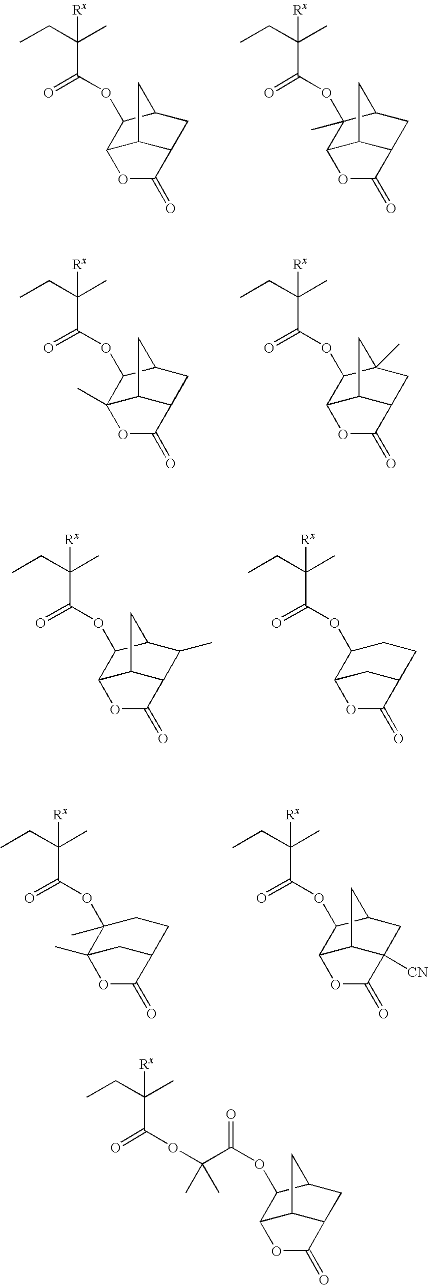

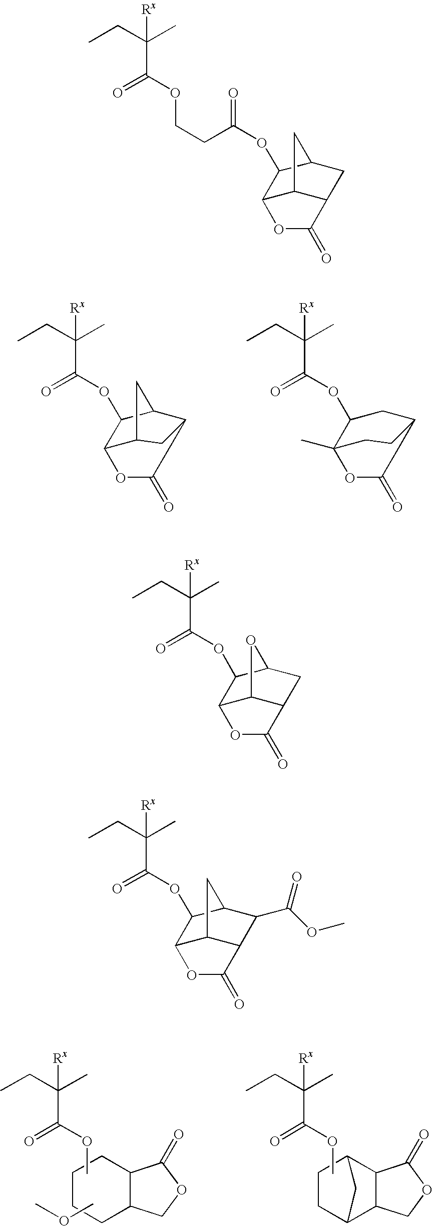

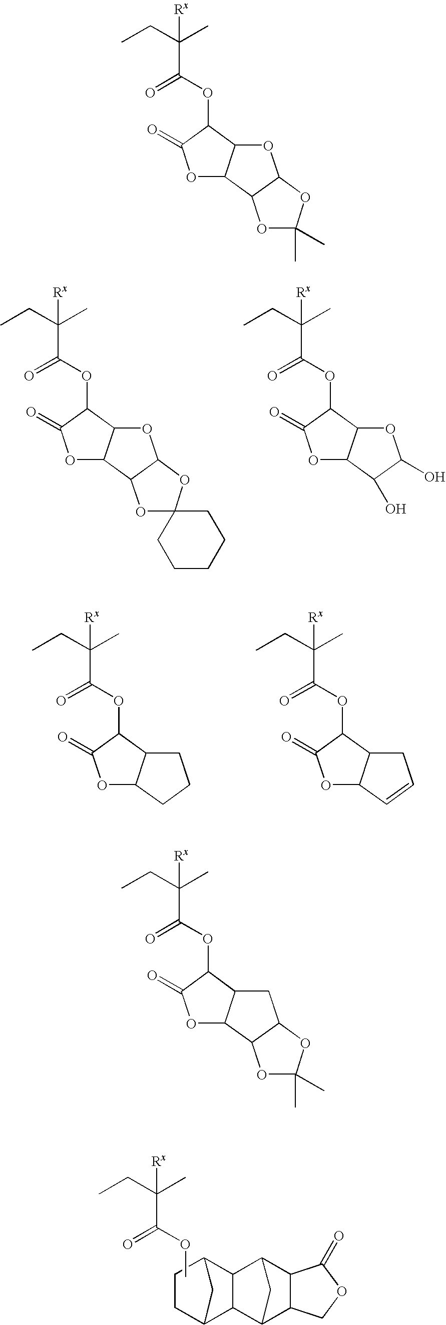

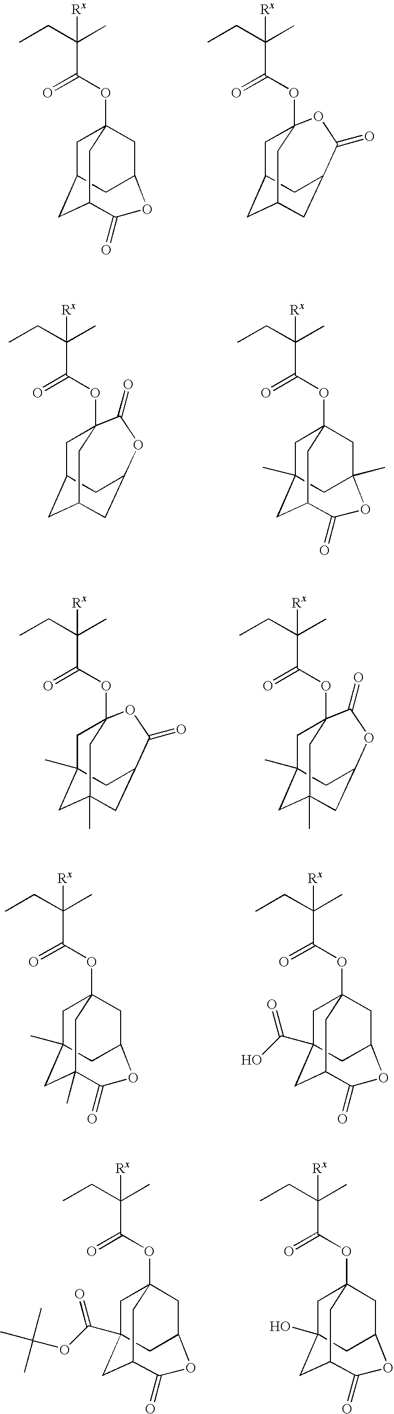

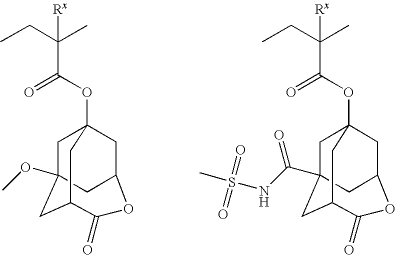

### Compositional Ratio, Polymerization Method, Etc.:

The compositional ratio of respective components in the repeating unit above varies depending on the repeating unit used.

The compositional proportion of the (a1) repeating unit having an alkali-soluble group is generally from 5 to 50 mol %, preferably from 8 to 35 mol %, more preferably from 12 to 30 mol %, based on all repeating units of the resin (A).

The compositional proportion of the (a2) repeating unit having an aliphatic group is generally from 15 to 90 mol %, preferably from 25 to 80 mol %, more preferably from 30 to 60 mol %, based on all repeating units of the resin (A).

The compositional proportion of the (a3) repeating unit having an oxetane structure is generally from 5 to 90 mol %, preferably from 5 to 80 mol %, more preferably from 10 to 60 mol %, based on all repeating units of the resin (A).

In the case of containing (a4) a repeating unit having a lactone structure, the compositional proportion of the repeating unit is generally from 1 to 50 mol %, preferably from 5 to 45 mol %, more preferably from 10 to 40 mol %, based on all repeating units of the resin (A).

The (A) alkali-soluble resin is composed of a copolymer of the above-described repeating units, and its weight average molecular weight (Mw) is usually from 1,000 to 100,000, preferably from 1,000 to 20,000, more preferably from 1,000 to 10,000.

The value (polydispersity, Pd (=Mw/Mn)) obtained by dividing the weight average molecular weight by the number average molecular weight of the (A) alkali-soluble resin is generally from 1 to 3, preferably from 1 to 2.5, more preferably from 1 to 2.0.

As regards the alkali-soluble resin for use in the present invention, various commercial products may be used, or the resin may be synthesized by an ordinary method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone. The polymerization is more preferably performed using the same solvent as the solvent used in the resist composition of the present invention. By the use of this solvent, production of particles during storage can be suppressed.

The polymerization reaction is preferably performed in an inert gas atmosphere such as nitrogen and argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the polymerization initiator include azobisisobutyronitrile, azobisdimethylvaleronitrile and dimethyl 2,2′-azobis(2-methylpropionate). The polymerization initiator is added additionally or in parts, if desired. The polymerization reaction may also be performed by adding a chain transfer agent in addition to the polymerization initiator. The concentration at the polymerization reaction is generally from 5 to 50 mass %, preferably from 30 to 50 mass %. After the completion of reaction, the reaction product is poured in a solvent, and the desired polymer is collected by a method such as powder or solid recovery. The reaction concentration is generally from 5 to 50 mass %, preferably from 10 to 30 mass %, and the reaction temperature is usually from 10 to 150° C., preferably from 30 to 120° C., more preferably from 60 to 100° C.

After the completion of reaction, the reaction product is allowed to cool to room temperature and purified. The purification may be performed by a normal method, for example, a liquid-liquid extraction method of applying water washing or combining an appropriate solvent to remove residual monomers or oligomer components; a purification method in a solution sate, such as ultrafiltration of removing by extraction only polymers having a molecular weight not more than a specific molecular weight; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent to the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing such a solvent, and the like according to the kind of the polymer. Among these solvents, the precipitation or reprecipitation solvent is preferably a solvent containing at least a hydrocarbon, an ether, an ester, an alcohol or water.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of generally on the order of 30 to 100° C., preferably on the order of 30 to 50° C.

Incidentally, after the resin is once precipitated and separated, the resin may be again dissolved in a solvent and then put into contact with a solvent in which the resin is sparingly soluble or insoluble. More specifically, there may be used a method comprising, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

The content of the (A) alkali-soluble resin in the negative resist composition is preferably from 5 to 95 mass %, more preferably from 10 to 95 mass %, still more preferably from 15 to 95 mass %, based on the entire solid content of the negative resist composition.

### (B) Low Molecular Compound Having Molecular Weight of 2,000 or Less and Having Oxetane Structure

The negative resist composition of the present invention contains (B) a low molecular compound having a molecular weight of 2,000 or less and having an oxetane structure. The low molecular compound having an oxetane structure (a cyclic skeleton formed by one oxygen atom and three carbon atoms) (hereinafter, sometimes referred to as a “polymerizable monomer”) for use in the present invention causes a cationic polymerization reaction by the action of an acid generated from a cationic photopolymerization initiator, and oxetane structure-containing low molecular compounds are allowed to react with each other.

The (B) low molecular compound having an oxetane structure is a compound having a molecular weight of 2,000 or less, preferably a compound having a molecular weight of 100 to 1,800, more preferably a compound having a molecular weight of 130 to 1,600, still more preferably a compound having a molecular weight of 200 to 1,500.

The low molecular compound having an oxetane structure can be synthesized based on a known method, or a commercial product available from Toagosei Chemical Industry Co., Ltd. and the like may be used.

The polymerizable monomer which can be used in the present invention is preferably an oxetane structure-containing low molecular compound represented by the following formula (1):

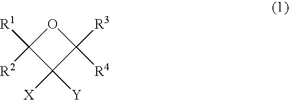

In formula (1), each of R¹ to R⁴ independently represents a hydrogen atom, a halogen atom, or a monovalent organic group which may have a substituent, and respective adjacent groups may combine with each other to form a ring. Each of R¹ to R⁴ is preferably a hydrogen atom, a halogen atom, an amino group, a carboxyl group, an alkoxycarbonyl group, a cyano group, an alkyl group which may have a substituent, an alkoxy group which may have a substituent, or an alkylamino group which may have a substituent.

Each of X and Y represents a single bond, a methylene group, an oxygen atom, a sulfur atom, a carbonyl group or a structure connected to an organic group through) —N(R⁰)—. R⁰ represents a hydrogen atom or a monovalent organic group. Examples of the organic group include an alkyl group, an aryl group (including a heteroaryl group), an alkenyl group, an alkynyl group, an amino group and an alkylamino group.

Each of X and Y may independently have a substituent, and examples of the substituent include an alkyl group, an alkenyl group, an alkynyl group, an alkoxy group, a halogen atom, an amino group, an alkylamino group, a carboxyl group, an alkoxycarbonyl group and a cyano group.

The polymerizable monomer preferably has a plurality of oxetane structures, and examples of the monomer include a compound having a plurality of oxetane structures, where a plurality of compounds represented by formula (1) are combined between groups represented by any of R¹ to R⁴, X and Y.

As for the polymerizable monomer, one kind may be used alone, or a plurality of kinds may be used in combination.

The polymerizable monomer executes a polymerizing function either when having one oxetane structure in the molecule or when having a plurality of oxetane structures, but in view of sensitivity, the polymerizable monomer preferably has a plurality of oxetane structures, and the number of oxetane structures is preferably from 2 to 10, more preferably from 2 to 8, still more preferably from 2 to 6, and most preferably from 2 to 4.

By virtue of having a plurality of oxetane structures in the polymerizable monomer molecule, the exposed area is allowed to take a more complicatedly entangled polymer structure and exhibit high sensitivity and high dissolution contrast for an alkali developer and at the same time, is prevented from swelling, as a result, high resolution is achieved.

In the polymerizable monomer having a plurality of oxetane structures in one molecule, the oxetane structures may be the same or different in kind.

Also, a polymerizable monomer having the same oxetane structures in one molecule may be mixed with a polymerizable monomer having a plurality of different oxetane structures.

Furthermore, the sensitivity can be balanced with other performances by using different functional numbers or different oxetane structures in combination.

The polymerizable monomer may be in a chemical form such as monomer, prepolymer (i.e., dimer, trimer, oligomer), a mixture of these, or a copolymer thereof. Examples of the monomer and copolymer thereof include an unsaturated carboxylic acid (e.g., acrylic acid, methacrylic acid, itaconic acid, crotonic acid, isocrotonic acid, maleic acid), and esters and amides thereof. Among these, esters of an unsaturated carboxylic acid with an aliphatic polyhydric alcohol compound, and amides of an unsaturated carboxylic acid with an aliphatic polyvalent amine compound are preferred.

Examples of the polymerizable monomer for use in the present invention are set forth below, but the present invention is not limited thereto.

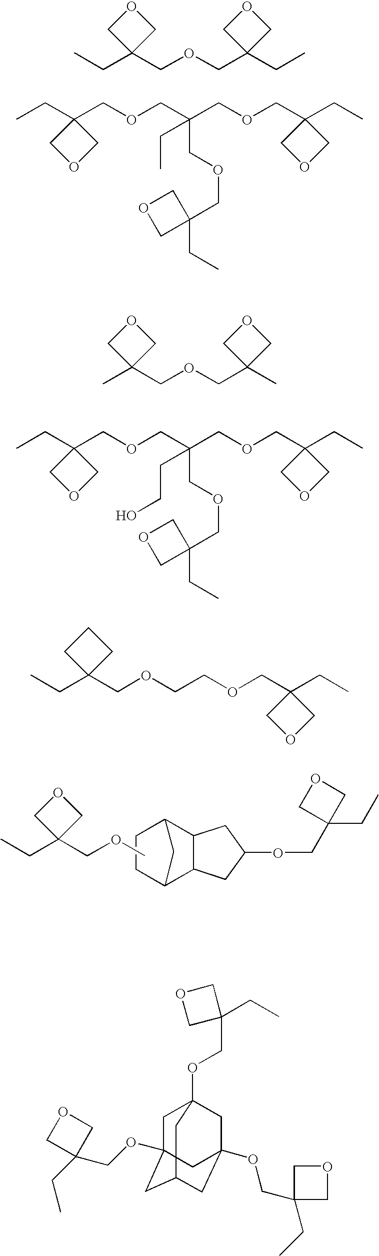

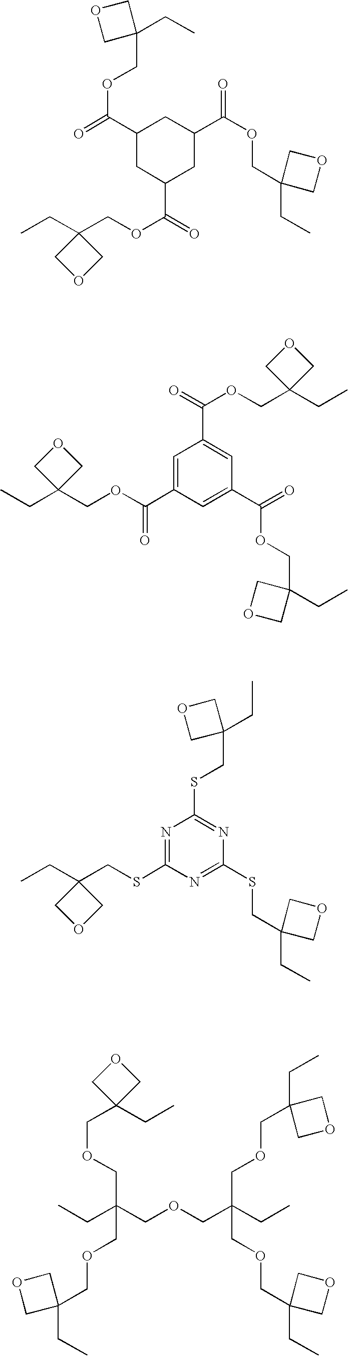

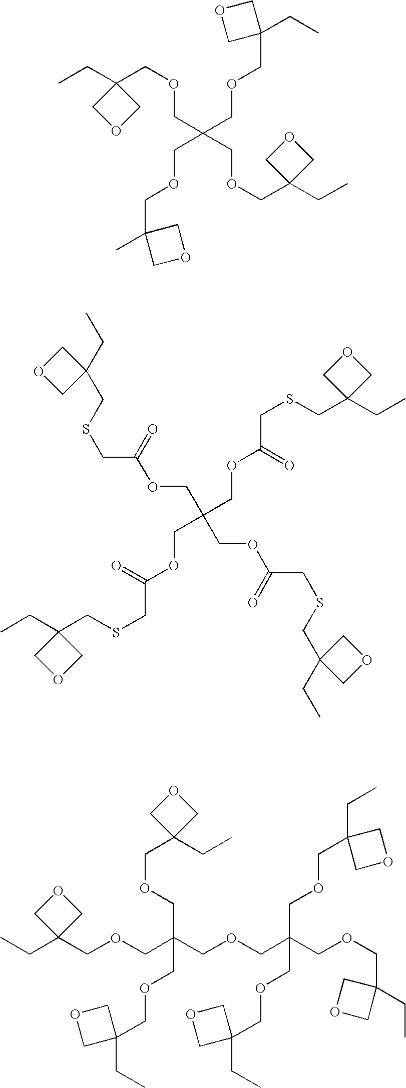

The content of the polymerizable monomer for use in the present invention is preferably from 0.5 to 90 wt %, more preferably from 5 to 80 wt %, still more preferably from 10 to 80 wt %, and most preferably from 15 to 80 wt %, based on the alkali-soluble resin.

### (C) Cationic Photopolymerization Initiator

The negative resist composition of the present invention contains a compound capable of allowing a crosslinking reaction (cationic polymerization reaction) to proceed upon irradiation with an actinic ray or radiation (hereinafter, sometimes referred to as a “cationic photopolymerization initiator”).

The cationic photopolymerization initiator which can be used may be appropriately selected from a general photo-initiator for cationic photopolymerization, a photo-initiator for radical photopolymerization, a photo-decoloring agent for dyes, a photo-discoloring agent, a compound known to generate an acid upon irradiation with an actinic ray or radiation and used for microresist or the like, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Out of the cationic photopolymerization initiators, preferred compounds include the compounds represented by the following formulae (ZI), (ZII) and (ZIII):

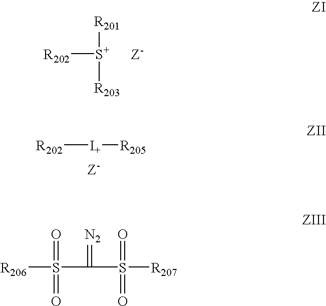

In formula (ZI), each of R₂₀₁, R₂₀₂ and R₂₀₃ independently represents an organic group.

The number of carbons in the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylene, pentylene).

Z⁻ represents a non-nucleophilic anion.

Examples of the non-nucleophilic anion as Z⁻ include a sulfonate anion, a carboxylate anion, a sulfonylimide anion, a bis(alkylsulfonyl)imide anion and a tris(alkylsulfonyl)methide anion.

The non-nucleophilic anion is an anion having an extremely low ability of causing a nucleophilic reaction and this anion can suppress the decomposition with aging due to intramolecular nucleophilic reaction. Thanks to this anion, the aging stability of the resist is enhanced.

Examples of the sulfonate anion include an aliphatic sulfonate anion, an aromatic sulfonate anion and a camphorsulfonate anion.

Examples of the carboxylate anion include an aliphatic carboxylate anion, an aromatic carboxylate anion and an aralkylcarboxylate anion.

The aliphatic moiety in the aliphatic sulfonate anion may be an alkyl group or a cycloalkyl group but is preferably an alkyl group having a carbon number of 1 to 30 or a cycloalkyl group having a carbon number of 3 to 30, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a boronyl group.

The aromatic group in the aromatic sulfonate anion is preferably an aryl group having a carbon number of 6 to 14, and examples thereof include a phenyl group, a tolyl group and a naphthyl group.

Each of the alkyl group, cycloalkyl group and aryl group in the aliphatic sulfonate anion and aromatic sulfonate anion may have a substituent. Examples of the substituent of the alkyl group, cycloalkyl group and aryl group in the aliphatic sulfonate anion and aromatic sulfonate anion include a nitro group, a halogen atom (e.g., fluorine, chlorine, bromine, iodine), a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 2 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of to 20), and a cycloalkylalkyloxyalkyloxy group (preferably having a carbon number of 8 to 20). As for the aryl group and ring structure in each group, examples of the substituent further include an alkyl group (preferably having a carbon number of 1 to 15).

Examples of the aliphatic moiety in the aliphatic carboxylate anion include the same alkyl groups and cycloalkyl groups as those in the aliphatic sulfonate anion.

Examples of the aromatic group in the aromatic carboxylate anion include the same aryl groups as those in the aromatic sulfonate anion.

The aralkyl group in the aralkylcarboxylate anion is preferably an aralkyl group having a carbon number of 6 to 12, and examples thereof include a benzyl group, a phenethyl group, a naphthylmethyl group, a naphthylethyl group and a naphthylmethyl group.

Each of the alkyl group, cycloalkyl group, aryl group and aralkyl group in the aliphatic carboxylate anion, aromatic carboxylate anion and aralkylcarboxylate anion may have a substituent. Examples of the substituent of the alkyl group, cycloalkyl group, aryl group and aralkyl group in the aliphatic carboxylate anion, aromatic carboxylate anion and aralkylcarboxylate anion include the same halogen atoms, alkyl groups, cycloalkyl groups, alkoxy groups and alkylthio groups as those in the aromatic sulfonate anion.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group. Examples of the substituent of such an alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom-substituted alkyl group being preferred.

Other examples of the non-nucleophilic anion include fluorinated phosphorus, fluorinated boron and fluorinated antimony.

The non-nucleophilic anion of Z⁻ is preferably an aliphatic sulfonate anion substituted by a fluorine atom at the α-position of the sulfonic acid, an aromatic sulfonate anion substituted by a fluorine atom or a fluorine atom-containing group, a bis(alkylsulfonyl)imide anion with the alkyl group being substituted by a fluorine atom, or a tris(alkylsulfonyl)methide anion with the alkyl group being substituted by a fluorine atom. The non-nucleophilic anion is more preferably a perfluoroaliphatic sulfonate anion having a carbon number of 4 to 8 or a benzenesulfonate anion having a fluorine atom, still more preferably nonafluorobutanesulfonate anion, perfluorooctanesulfonate anion, pentafluorobenzenesulfonate anion or 3,5-bis(trifluoromethyl)benzenesulfonate anion.

A bis(alkylsulfonyl)imide anion with the alkyl group being substituted by a fluorine atom and a tris(alkylsulfonyl)methide anion with the alkyl group being substituted by a fluorine atom are most preferred.

Examples of the organic group as R₂₀₁, R₂₀₂ and R₂₀₃ include the corresponding groups in the compounds (ZI-1), (ZI-2) and (ZI-3) described later.

The compound may be a compound having a plurality of structures represented by formula (ZI), for example, may be a compound having a structure where at least one of R₂₀₁ to R₂₀₃ in the compound represented by formula (ZI) is bonded to at least one of R₂₀₁ to R₂₀₃ in another compound represented by formula (ZI).

The component (ZI) is more preferably a compound (ZI-1), (ZI-2) or (ZI-3) described below.

The compound (ZI-1) is an arylsulfonium compound where at least one of R₂₀₁ to R₂₀₃ in formula (ZI) is an aryl group, that is, a compound having arylsulfonium as the cation.

In the arylsulfonium compound, all of R₂₀₁ to R₂₀₃ may be an aryl group or a part of R₂₀₁ to R₂₀₃ may be an aryl group with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group or a naphthyl group, more preferably a phenyl group. The aryl group may be an aryl group having a heterocyclic structure containing an oxygen atom, a nitrogen atom, a sulfur atom or the like. Examples of the aryl group having a heterocyclic structure include a pyrrole residue (a group formed by removing one hydrogen atom from a pyrrole), a furan residue (a group formed by removing one hydrogen atom from a furan), a thiophene residue (a group formed by removing one hydrogen atom from a thiophene), an indole residue (a group formed by removing one hydrogen atom from an indole), a benzofuran residue (a group formed by removing one hydrogen atom from a benzofuran) and a benzothiophene residue (a group formed by removing one hydrogen atom from a benzothiophene). In the case where the arylsulfonium compound has two or more aryl groups, these two or more aryl groups may be the same or different.

The alkyl or cycloalkyl group which is present, if desired, in the arylsulfonium compound is preferably a linear or branched alkyl group having a carbon number of 1 to 15 or a cycloalkyl group having a carbon number of 3 to 15, and examples thereof include a methyl group, an ethyl group, a propyl group, an n-butyl group, a sec-butyl group, a tert-butyl group, a cyclopropyl group, a cyclobutyl group and a cyclohexyl group.

Each of the aryl group, alkyl group and cycloalkyl group of R₂₀₁ to R₂₀₃ may have, as the substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4, or an alkoxy group having a carbon number of 1 to 4. The substituent may be substituted on any one of three members R₂₀₁ to R₂₀₃ or may be substituted on all of these three members. In the case where R₂₀₁ to R₂₀₃ are an aryl group, the substituent is preferably substituted at the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein includes an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ independently represents preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10 (e.g., methyl, ethyl, propyl, butyl, pentyl) and a cycloalkyl group having a carbon number of 3 to 10 (e.g., cyclopentyl, cyclohexyl, norbornyl). The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5 (e.g., methoxy, ethoxy, propoxy, butoxy, pentoxy).

Each of R₂₀₁ to R₂₀₃ may be further substituted by a halogen atom, an alkoxy group (for example, having a carbon number of 1 to 5), a hydroxyl group, a cyano group or a nitro group.

The compound (ZI-3) is a compound represented by the following formula (ZI-3), and this is a compound having a phenacylsulfonium salt structure.

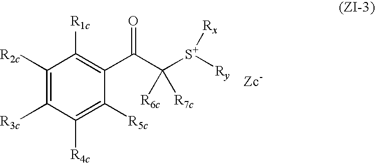

In formula (ZI-3), each of R_{1c} to R_{5c} independently represents a hydrogen atom, an alkyl group, a cycloalkyl group, an alkoxy group or a halogen atom.

Each of R_{6c} and R_{7c} independently represents a hydrogen atom, an alkyl group or a cycloalkyl group.

Each of Rₓ and R_{y} independently represents an alkyl group, a cycloalkyl group, an allyl group or a vinyl group.

Any two or more members out of R_{1c} to R_{5c}, a pair of R_{6c} and R_{7c}, or a pair of Rₓ and R_{y} may combine to form a ring structure. This ring structure may contain an oxygen atom, a sulfur atom, an ester bond or an amide bond. Examples of the group formed by combining any two or more members out of R_{1c} to R_{5c} a pair of R_{6c} and R_{7c}, or a pair of Rₓ and R_{y} include a butylene group and a pentylene group.

Zc⁻ represents a non-nucleophilic anion, and examples thereof are the same as those of the non-nucleophilic anion of Z⁻ in formula (ZI).

The alkyl group as R_{1c} to R_{7c} may be either linear or branched and is, for example, an alkyl group having a carbon number of 1 to 20, preferably a linear or branched alkyl group having a carbon number of 1 to 12 (e.g., methyl, ethyl, linear or branched propyl, linear or branched butyl, linear or branched pentyl). The cycloalkyl group is, for example, a cycloalkyl group having a carbon number of 3 to 8 (e.g., cyclopentyl, cyclohexyl).

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (e.g., methoxy, ethoxy, linear or branched propoxy, linear or branched butoxy, linear or branched pentoxy) or a cyclic alkoxy group having a carbon number of 3 to 8 (e.g., cyclopentyloxy, cyclohexyloxy).

A compound where any one of R_{1c} to R_{5c} is a linear or branched alkyl group, a cycloalkyl group or a linear, branched or cyclic alkoxy group is preferred, and a compound where the sum of carbon numbers of R_{1c} to R_{5c} is from 2 to 15 is more preferred. Thanks to such a compound, the solvent solubility is more enhanced and production of particles during storage is suppressed.

Examples of the alkyl group and cycloalkyl group as Rₓ and R_{y} are the same as those of the alkyl group and cycloalkyl group in R_{1c} to R_{7c}. Among these, a 2-oxoalkyl group, a 2-oxocycloalkyl group and an alkoxycarbonylmethyl group are preferred.

Examples of the 2-oxoalkyl group and 2-oxocycloalkyl group include a group having >C═O at the 2-position of the alkyl group or cycloalkyl group as R_{1c} to R_{7c}.

Examples of the alkoxy group in the alkoxycarbonylmethyl group are the same as those of the alkoxy group in R_{1c} to R_{5c}.

Each of Rₓ and R_{y} is preferably an alkyl or cycloalkyl group having a carbon number of 4 or more, more preferably 6 or more, still more preferably 8 or more.

In formulae (ZII) and (ZIII), each of R₂₀₄ to R₂₀₇ independently represents an aryl group, an alkyl group or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure containing an oxygen atom, a nitrogen atom, a sulfur atom or the like. Examples of the aryl group having a heterocyclic structure include a pyrrole residue (a group formed by removing one hydrogen atom from a pyrrole), a furan residue (a group formed by removing one hydrogen atom from a furan), a thiophene residue (a group formed by removing one hydrogen atom from a thiophene), an indole residue (a group formed by removing one hydrogen atom from an indole), a benzofuran residue (a group formed by removing one hydrogen atom from a benzofuran) and a benzothiophene residue (a group formed by removing one hydrogen atom from a benzothiophene).

The alkyl group and cycloalkyl group in R₂₀₄ to R₂₀₇ are preferably a linear or branched alkyl group having a carbon number of 1 to 10 (e.g., methyl, ethyl, propyl, butyl, pentyl) and a cycloalkyl group having a carbon number of 3 to 10 (e.g., cyclopentyl, cyclohexyl, norbornyl).

The aryl group, alkyl group and cycloalkyl group of R₂₀₄ to R₂₀₇ may have a substituent. Examples of the substituent which the aryl group, alkyl group and cycloalkyl group of R₂₀₄ to R₂₀₇ may have include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group and a phenylthio group.

Z⁻ represents a non-nucleophilic anion, and examples thereof are the same as those of the non-nucleophilic anion of Z⁻ in formula (ZI).

In the present invention, the acid generated from the component (C) upon irradiation with an actinic ray or radiation is preferably a fluorinated sulfonimide acid compound.

The fluorinated sulfonimide acid compound is more preferably a compound represented by the following formula (I):

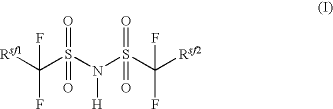

In formula (I), each of R^{sf1} and R^{sf2} independently represents a hydrogen atom, a fluorine atom or an alkyl group, provided that R^{sf1} and R^{sf2} may combine with each other to form a ring.

The alkyl group in R^{sf1} and R^{sf2} is preferably a linear or branched alkyl group having a carbon number of 1 to 10 (e.g., methyl, ethyl, propyl, butyl, pentyl) or a cycloalkyl group having a carbon number of 3 to 10 (e.g., cyclopentyl, cyclohexyl, norbornyl).

In the present invention, the acid generated from the component (C) upon irradiation with an actinic ray or radiation is preferably a fluorinated sulfonmethide acid compound.

The fluorinated sulfonmethide acid compound is more preferably a compound represented by the following formula (II):

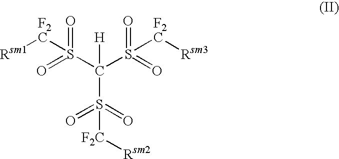

In formula (II), each of R^{sm1} to R^{sm3} independently represents a hydrogen atom, a fluorine atom or an alkyl group, and any two members may combine with each other to form a ring.

The alkyl group in R^{sm1} to R^{sm3} is preferably a linear or branched alkyl group having a carbon number of 1 to 10 (e.g., methyl, ethyl, propyl, butyl, pentyl) or a cycloalkyl group having a carbon number of 3 to 10 (e.g., cyclopentyl, cyclohexyl, norbornyl).

Other examples of the cationic photopolymerization initiator include the compounds represented by the following formulae (ZIV), (ZV) and (ZVI):

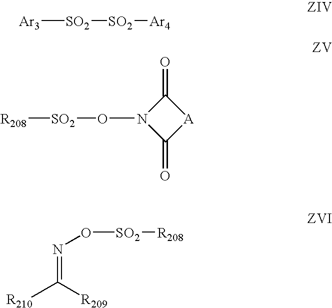

In formulae (ZIV) to (ZVI), each of Arₐ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the cationic photopolymerization initiators, more preferred are the compounds represented by formulae (ZI) to (ZIII).

Also, the cationic photopolymerization initiator is preferably a compound capable of generating an acid having one sulfonic acid group or imide group, more preferably a compound capable of generating a monovalent perfluoroalkanesulfonic acid, a compound capable of generating an aromatic sulfonic acid substituted by a monovalent fluorine atom or a fluorine atom-containing group, or a compound capable of generating an imide acid substituted by a monovalent fluorine atom or a fluorine atom-containing group, still more preferably a sulfonium salt of fluoro-substituted alkanesulfonic acid, fluorine-substituted benzenesulfonic acid, fluorine-substituted imide acid or fluorine-substituted methide acid. As for the cationic photopolymerization initiator which can be used, in terms of pKa, the acid generated is preferably a fluoro-substituted alkanesulfonic acid, a fluoro-substituted benzenesulfonic acid or a fluoro-substituted imide acid, whose pKa is −1 or less, more preferably a fluoro-substituted alkanesulfonic acid, a fluoro-substituted benzenesulfonic acid or a fluoro-substituted imide acid, whose pKa is −8 or less, still more preferably a fluoro-substituted alkanesulfonic acid, a fluoro-substituted benzenesulfonic acid or a fluoro-substituted imide acid, whose pKa is −11 or less. With low pKa, the sensitivity is enhanced.

Out of cationic photopolymerization initiators, preferred examples are set forth below.

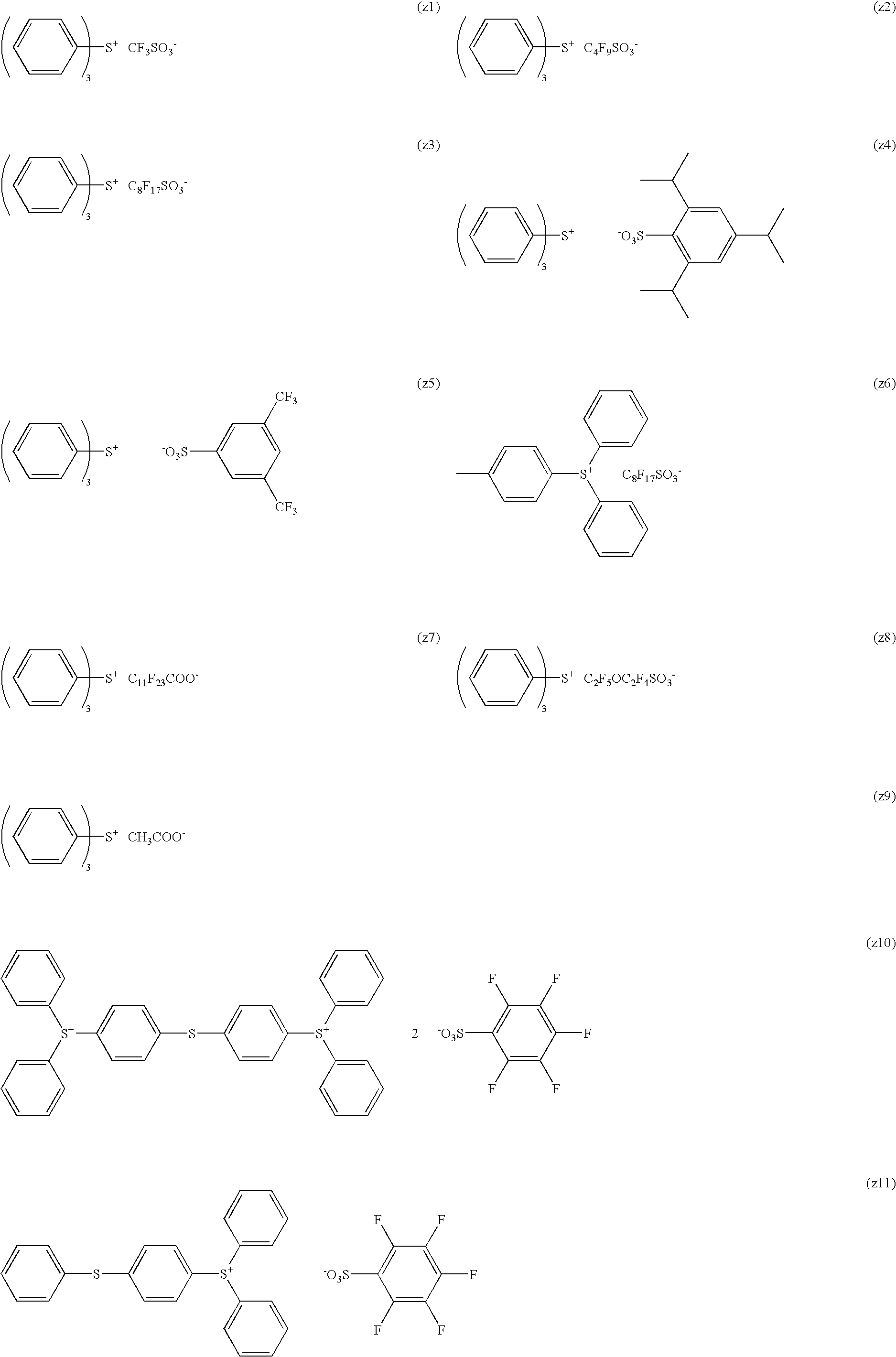

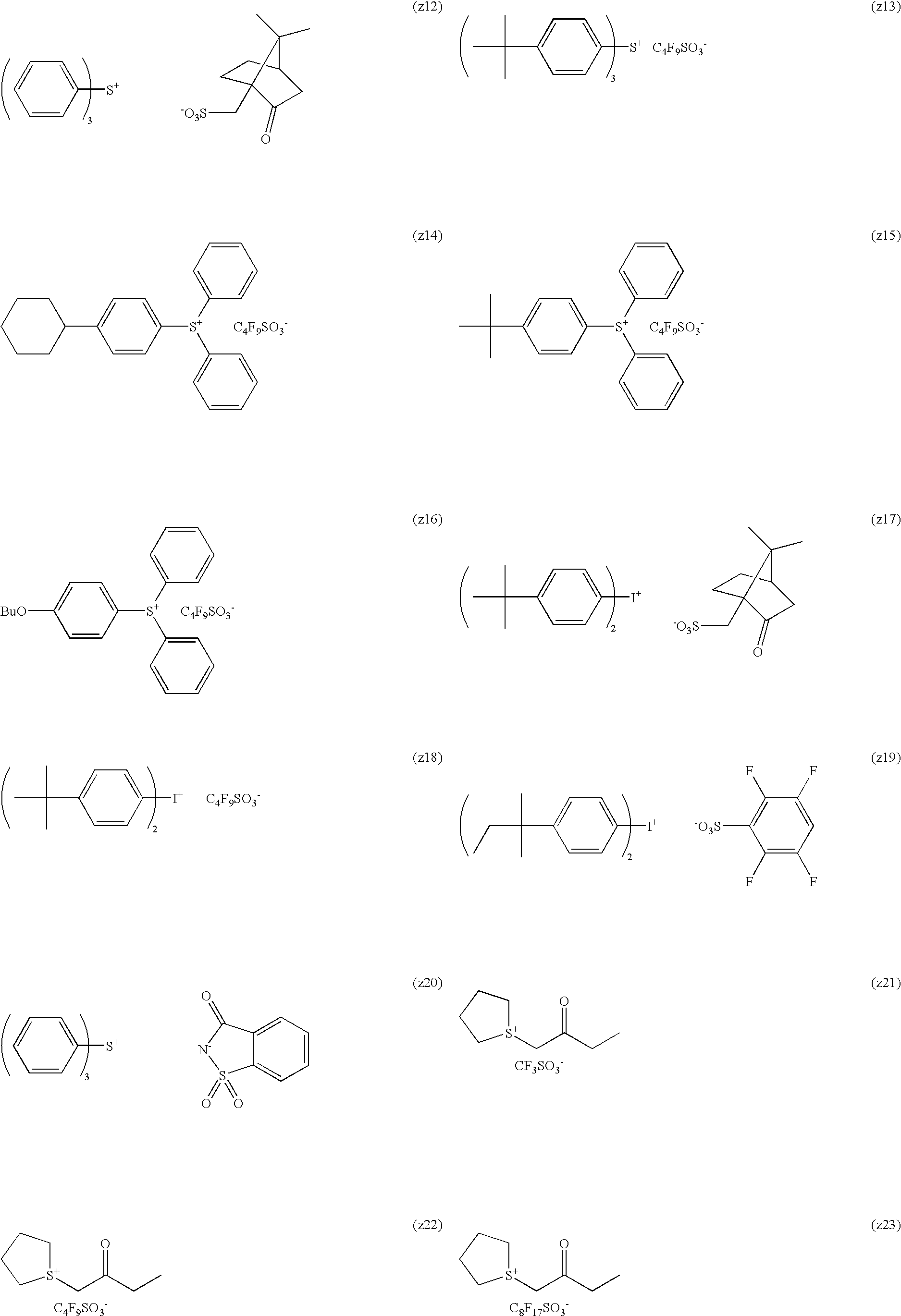

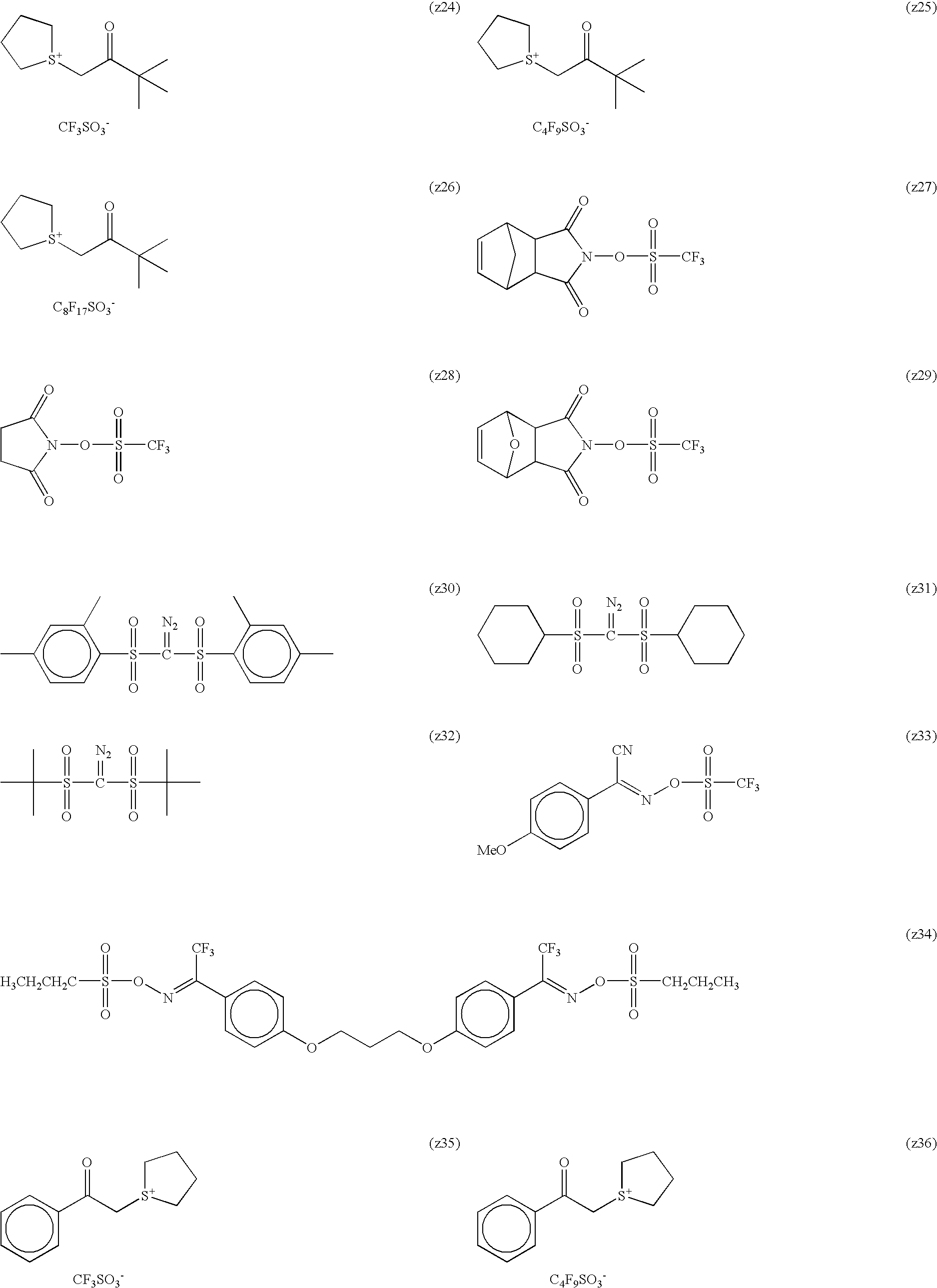

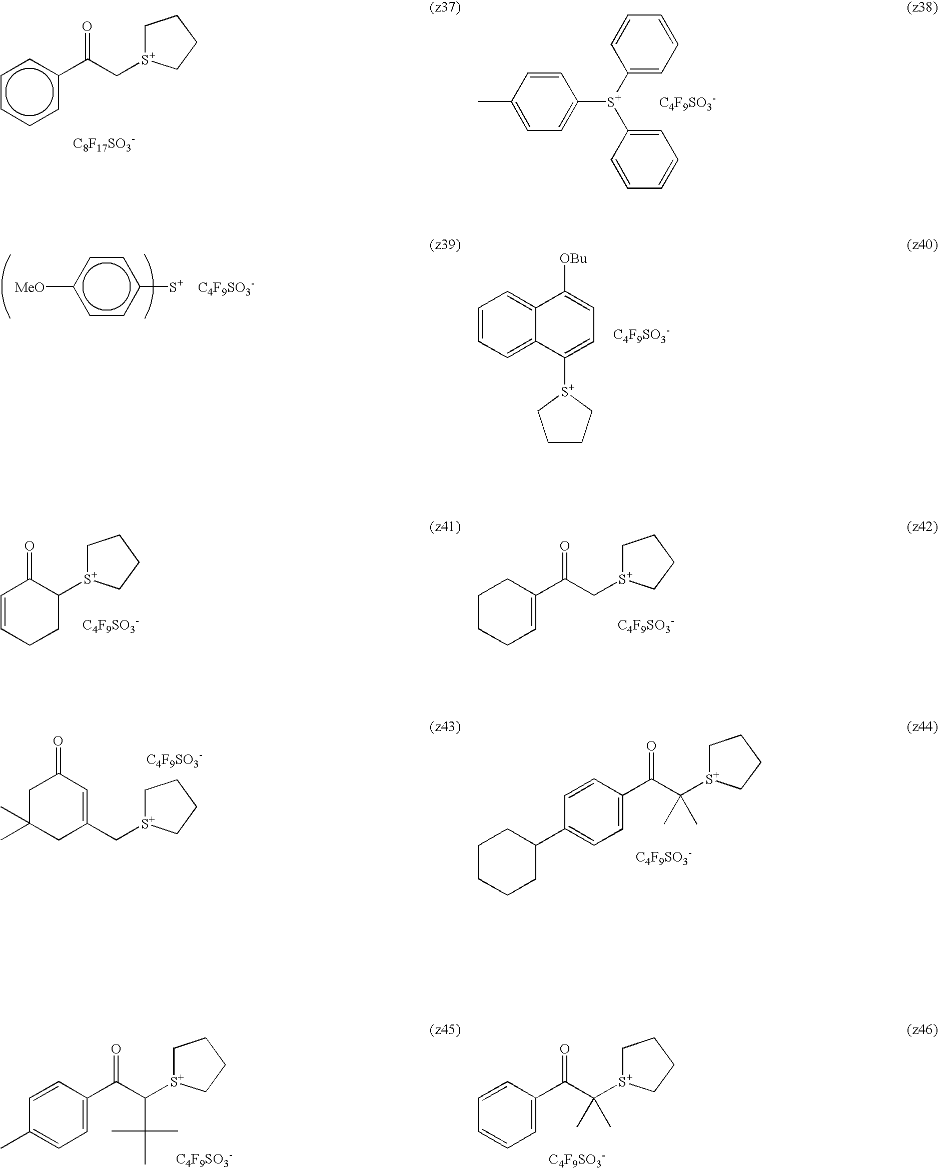

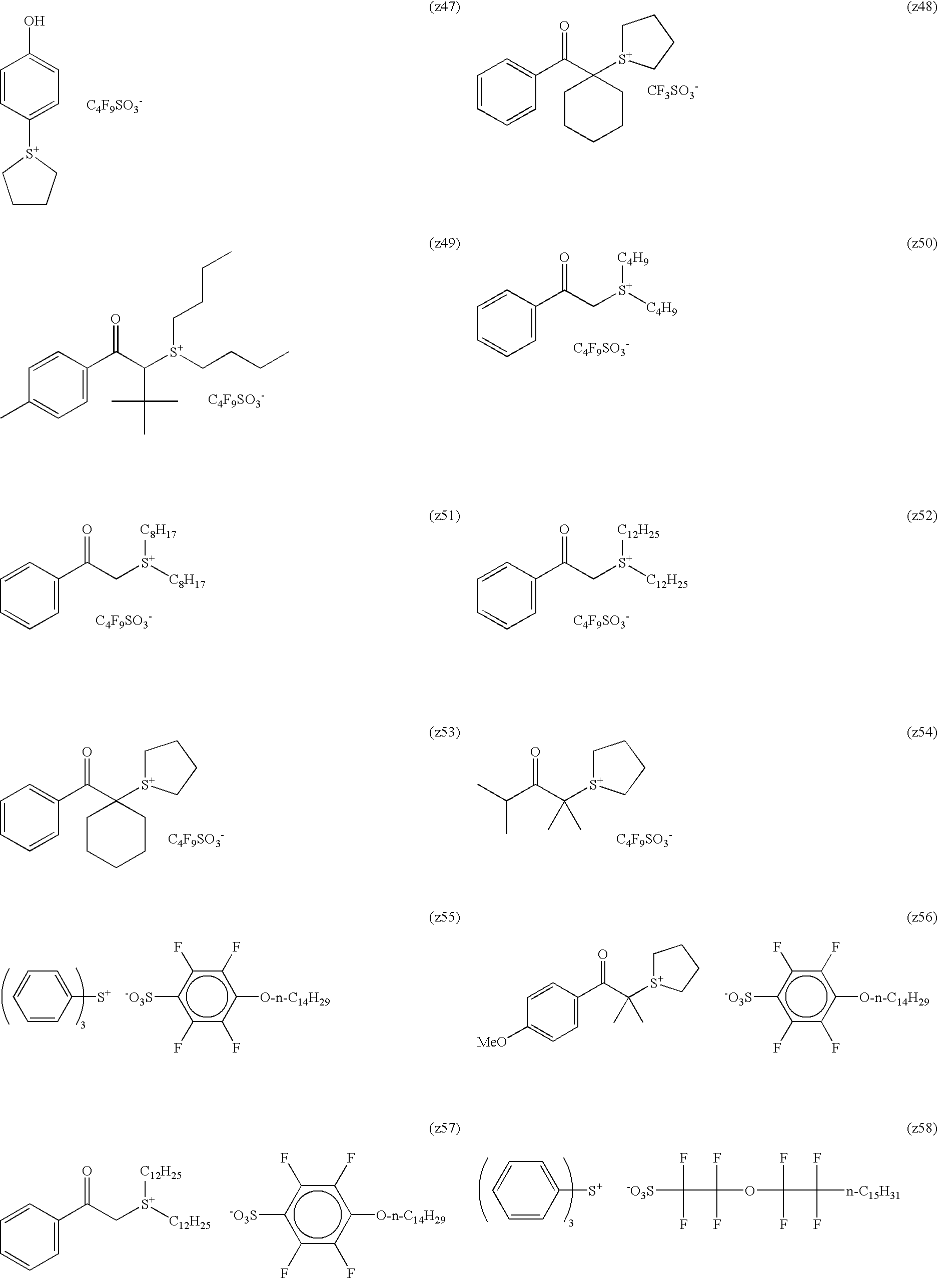

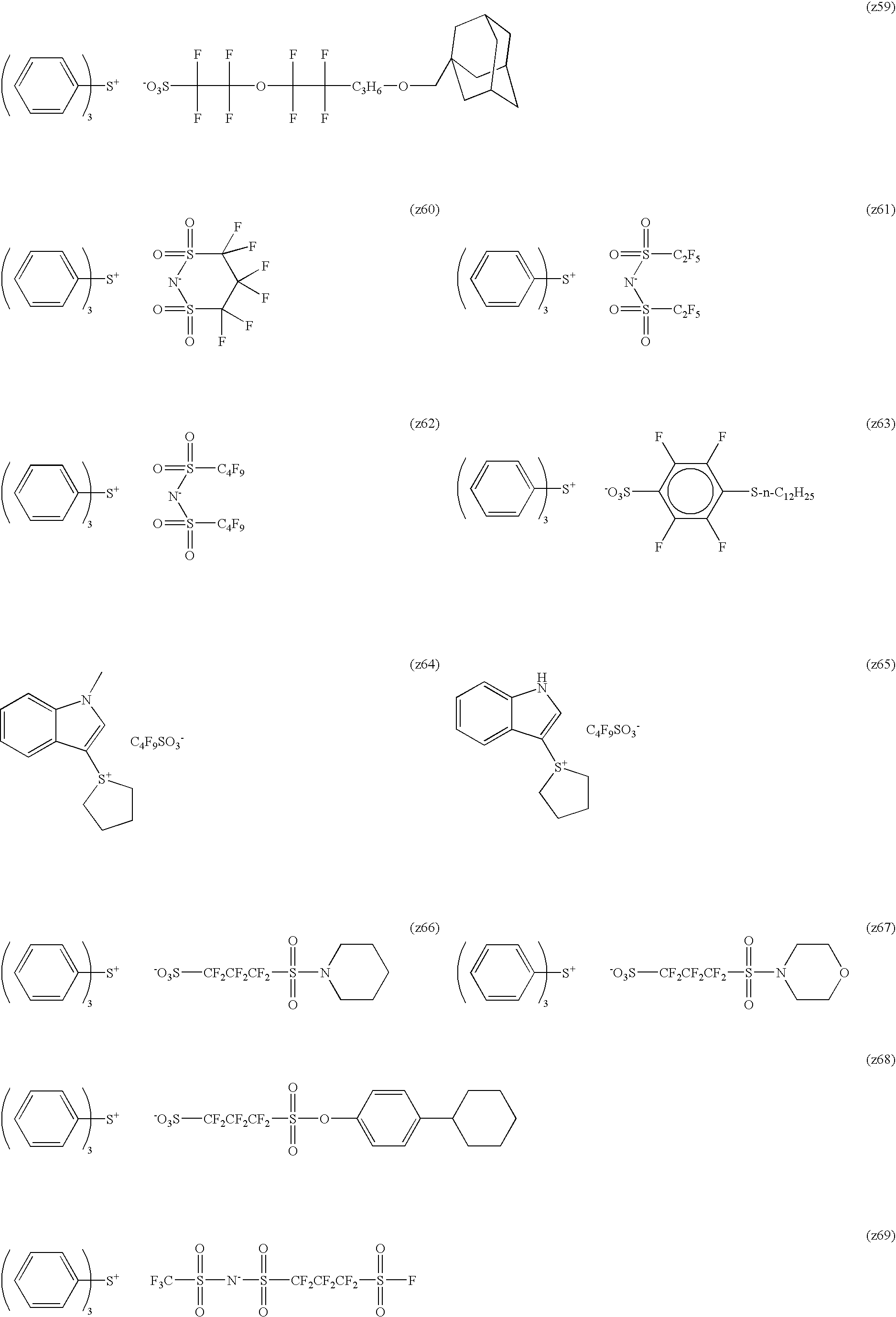

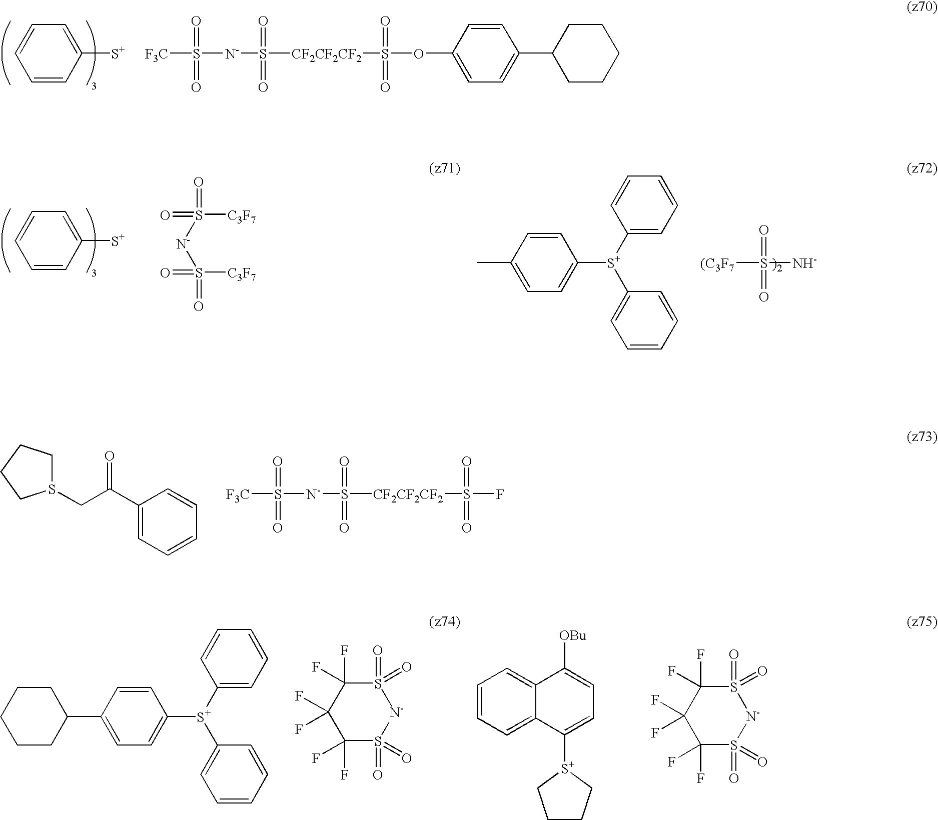

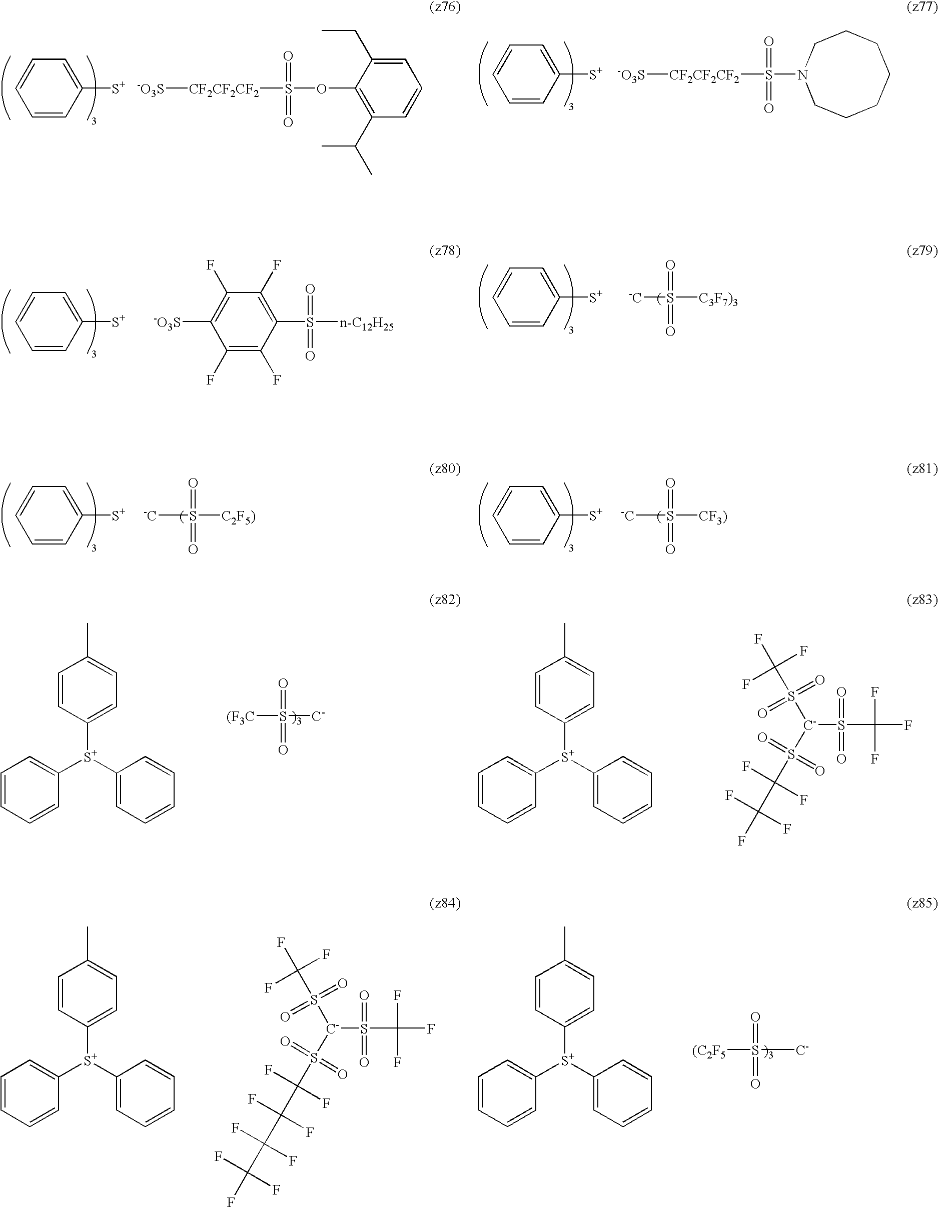

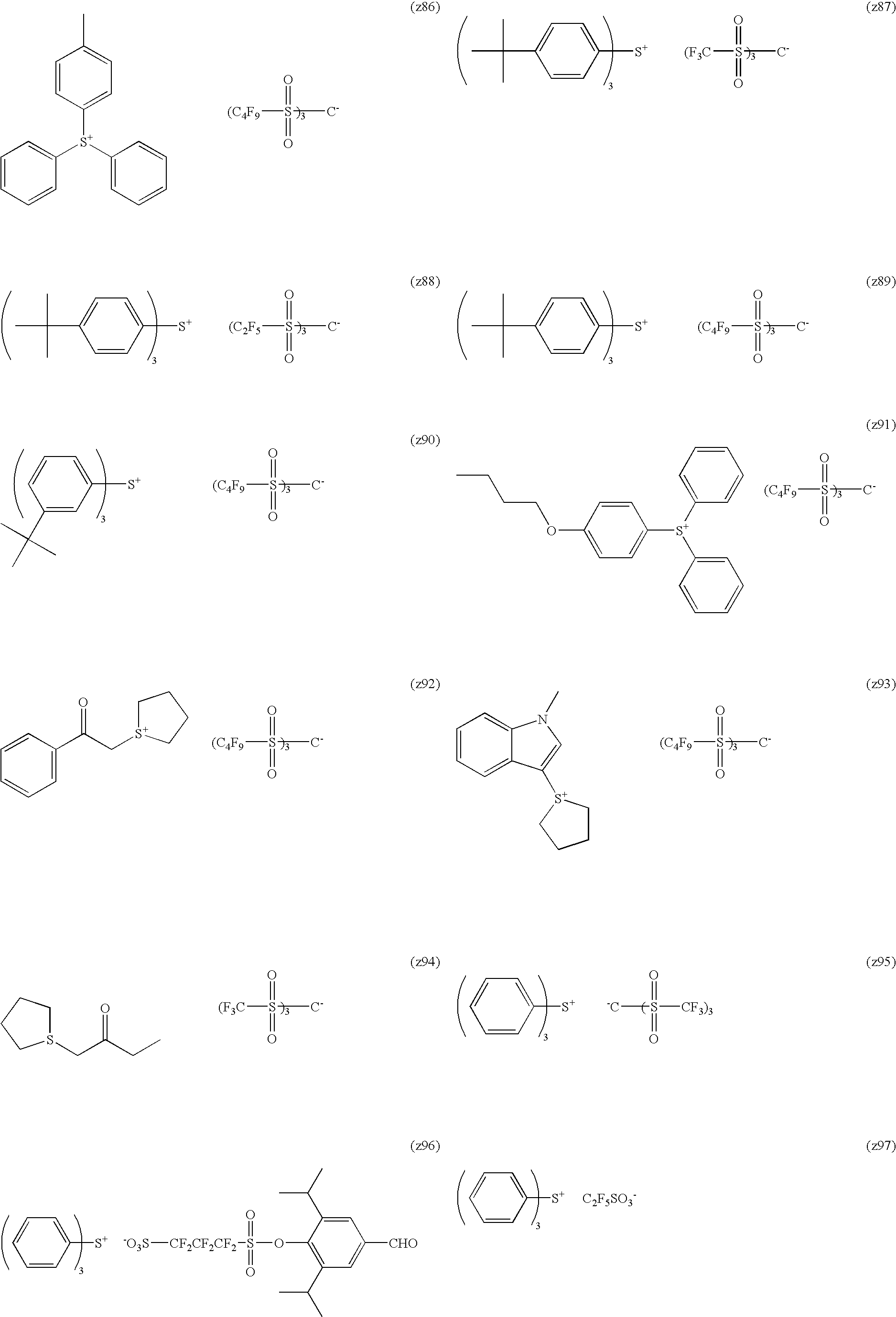

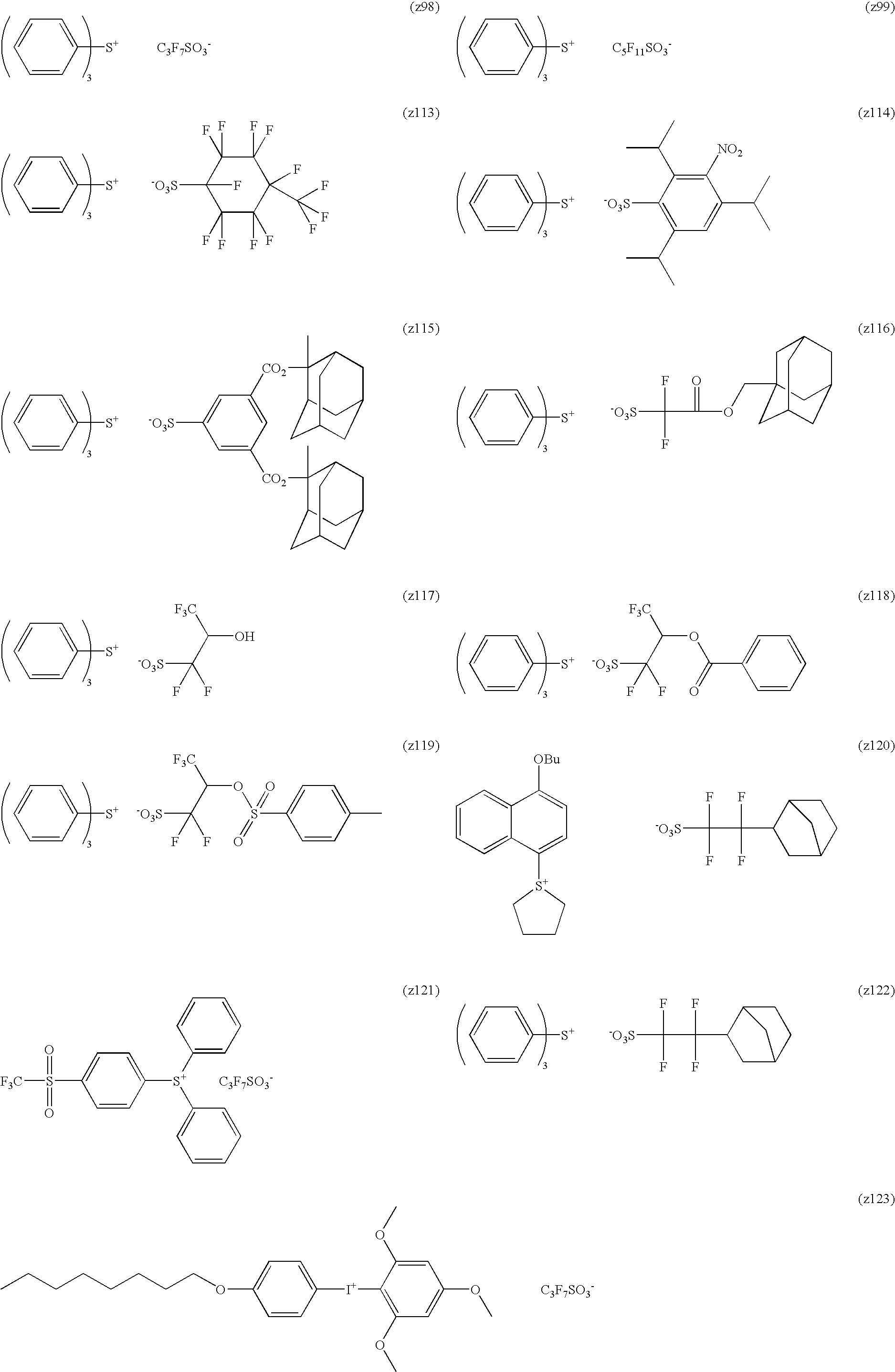

The cationic photopolymerization initiator preferably generates an acid having pKa of −8 or less.

The cationic photopolymerization initiator more preferably generates a fluoro-substituted alkanesulfonic acid, a fluoro-substituted benzenesulfonic acid or a fluoro-substituted imide acid, whose pKa is −8 or less, and in this case, the sensitivity is enhanced.

Among the above-described examples of the cationic photopolymerization initiator, (Z60) to (Z62) and (Z69) to (Z95) are more preferred, and (Z79) to (Z95) are still more preferred.

As for the cationic photopolymerization initiator, one kind may be used alone, or two or more kinds may be used in combination.

The content of the cationic photopolymerization initiator in the negative resist composition is preferably from 0.1 to 20 mass %, more preferably from 0.5 to 10 mass %, still more preferably from 1 to 7 mass %, based on the entire solid content of the negative resist composition.

### (D) Basic Compound

The negative resist composition of the present invention preferably contains a basic compound so as to reduce the change in performance with aging from exposure to heating.

The basic compound is preferably a compound having a structure represented by the following formulae (A) to (E):

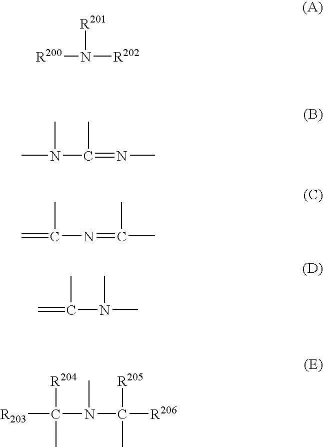

In formulae (A) to (E), each of R²⁰⁰, R²⁰¹ and R²⁰², which may be the same or different, represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine together to form a ring.

As for the alkyl group above, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

Each of R²⁰³, R²⁰⁴, R²⁰⁵ and R²⁰⁶, which may be the same or different, represents an alkyl group having a carbon number of 1 to 20.

The alkyl group in these formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having at least one member selected from a hydroxyl group and an ether bond; and an aniline derivative having at least one member selected from a hydroxyl group and an ether bond.

Examples of the compound having an imidazole structure include imidazole, 2,4,5-triphenylimidazole and benzimidazole. Examples of the compound having a diazabicyclo structure include 1,4-diazabicyclo[2,2,2]octane, 1,5-diazabicyclo[4,3,0]non-5-ene and 1,8-diazabicyclo[5,4,0]undec-7-ene. Examples of the compound having an onium hydroxide structure include triarylsulfonium hydroxide, phenacylsulfonium hydroxide and sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. Examples of the compound having an onium carboxylate structure include a compound where the anion moiety of the compound having an onium hydroxide structure becomes a carboxylate, such as acetate, adamantane-1-carboxylate and perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline and N,N-dihexylaniline. Examples of the alkylamine derivative having at least one member selected from a hydroxyl group and an ether bond include ethanolamine, diethanolamine, triethanolamine and tris(methoxyethoxyethyl)amine. Examples of the aniline derivative having at least one member selected from a hydroxyl group and an ether bond include N,N-bis(hydroxyethyl)aniline.

Other examples include at least one kind of a nitrogen-containing compound selected from a phenoxy group-containing amine compound, a phenoxy group-containing ammonium salt compound, a sulfonic acid ester group-containing amine compound and a sulfonic acid ester group-containing ammonium salt compound.

As for the amine compound, a primary, secondary or tertiary amine compound can be used, and an amine compound where at least one alkyl group is bonded to the nitrogen atom is preferred. The amine compound is more preferably a tertiary amine compound. In the amine compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom, in addition to the alkyl group.

The amine compound preferably contains an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

As for the ammonium salt compound, a primary, secondary, tertiary or quaternary ammonium salt compound can be used, and an ammonium salt compound where at least one alkyl group is bonded to the nitrogen atom is preferred. In the ammonium salt compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom, in addition to the alkyl group.

The ammonium salt compound preferably contains an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

Examples of the anion of the ammonium salt compound include a halogen atom, a sulfonate, a borate and a phosphate, with a halogen atom and a sulfonate being preferred. The halogen atom is preferably chloride, bromide or iodide, and the sulfonate is preferably an organic sulfonate having a carbon number of 1 to 20. The organic sulfonate includes an alkylsulfonate having a carbon number of 1 to 20 and an arylsulfonate. The alkyl group of the alkylsulfonate may have a substituent, and examples of the substituent include fluorine, chlorine, bromine, an alkoxy group, an acyl group and an aryl group. Specific examples of the alkylsulfonate include methanesulfonate, ethanesulfonate, butanesulfonate, hexanesulfonate, octanesulfonate, benzylsulfonate, trifluoromethanesulfonate, pentafluoroethanesulfonate and nonafluorobutanesulfonate. The aryl group of the arylsulfonate includes a benzene ring, a naphthalene ring and an anthracene ring. The benzene ring, naphthalene ring and anthracene ring may have a substituent, and the substituent is preferably a linear or branched alkyl group having a carbon number of 1 to 6, or a cycloalkyl group having a carbon number of 3 to 6. Specific examples of the linear or branched alkyl group and cycloalkyl group include methyl, ethyl, n-propyl, isopropyl, n-butyl, i-butyl, tert-butyl, n-hexyl and cyclohexyl. Other examples of the substituent include an alkoxy group having a carbon number of 1 to 6, a halogen atom, cyano, nitro, an acyl group and an acyloxy group.

The phenoxy group-containing amine compound and the phenoxy group-containing ammonium salt compound are a compound where the alkyl group of an amine compound or ammonium salt compound has a phenoxy group at the terminal opposite the nitrogen atom. The phenoxy group may have a substituent. Examples of the substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group and an aryloxy group. The substitution site of the substituent may be any of 2- to 6-positions, and the number of substituents may be any in the range from 1 to 5.

The compound preferably has at least one oxyalkylene group between the phenoxy group and the nitrogen atom. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The sulfonic acid ester group in the sulfonic acid ester group-containing amine compound and sulfonic acid ester group-containing ammonium salt compound may be any of an alkylsulfonic acid ester, a cycloalkylsulfonic acid ester and an arylsulfonic acid ester. In the case of an alkylsulfonic acid ester, the alkyl group preferably has a carbon number of 1 to 20; in the case of a cycloalkylsulfonic acid ester, the cycloalkyl group preferably has a carbon number of 3 to 20; and in the case of an arylsulfonic acid ester, the aryl group preferably has a carbon number of 6 to 12. The alkylsulfonic acid ester, cycloalkylsulfonic acid ester and arylsulfonic acid ester may have a substituent, and the substituent is preferably a halogen atom, a cyano group, a nitro group, a carboxyl group, a carboxylic acid ester group or a sulfonic acid ester group.

The compound preferably has at least one oxyalkylene group between the sulfonic acid ester group and the nitrogen atom. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The phenoxy group-containing amine compound can be obtained by reacting a phenoxy group-containing primary or secondary amine with a haloalkyl ether under heating, adding an aqueous solution of a strong base such as sodium hydroxide, potassium hydroxide and tetraalkylammonium, and extracting the compound with an organic solvent such as ethyl acetate and chloroform. Alternatively, a primary or secondary amine is reacted under heating with a haloalkyl ether having a phenoxy group at the terminal and after adding an aqueous solution of a strong base such as sodium hydroxide, potassium hydroxide and tetraalkylammonium, the compound can be extracted with an organic solvent such as ethyl acetate and chloroform.

One of these basic compounds may be used alone, or two or more thereof may be used.

The amount of the basic compound used is usually from 0.001 to 1.0 mass %, preferably from 0.01 to 5 mass %, based on the solid content of the negative resist composition.

The ratio between the cationic photopolymerization initiator and the basic compound used in the composition is preferably cationic photopolymerization initiator/basic compound (by mol)=from 2.5 to 300. That is, the molar ratio is preferably 2.5 or more in view of sensitivity and resolution and preferably 300 or less from the standpoint of suppressing the reduction in resolution due to thickening of the resist pattern with aging after exposure until heat treatment. The cationic photopolymerization initiator/basic compound (by mol) is more preferably from 5.0 to 200, still more preferably from 7.0 to 150.

### (E) Hydrophobic Resin

The exposure may be performed by filling a liquid (immersion medium) having a refractive index higher than that of air between the resist film and the lens of an exposure apparatus at the irradiation with an actinic ray or radiation (immersion exposure). Thanks to this exposure, the resolution can be enhanced. The immersion medium used may be any liquid as long as it has a refractive index higher than that of air, but pure water is preferred.

The immersion medium (immersion liquid) used in the immersion exposure is described below.

The immersion liquid is preferably a liquid being transparent to light at the exposure wavelength and having as small a temperature coefficient of refractive index as possible so as to minimize the distortion of an optical image projected on the resist film. In particular, when the exposure light source is an ArF excimer laser (wavelength: 193 nm), water is preferably used in view of easy availability and easy handleability, in addition to the above-described aspects.

Furthermore, a medium having a refractive index of 1.5 or more may also be used, because the refractive index can be more increased. This medium may be either an aqueous solution or an organic solvent.

In the case of using water as the immersion liquid, for the purpose of decreasing the surface tension of water and increasing the surface activity, an additive (liquid) that does not dissolve the resist film on a wafer and at the same time, gives only a negligible effect on the optical coat at the undersurface of the lens element, may be added in a small ratio. The additive is preferably an aliphatic alcohol having a refractive index nearly equal to that of water, and specific examples thereof include methyl alcohol, ethyl alcohol and isopropyl alcohol. By virtue of adding an alcohol having a refractive index nearly equal to that of water, even when the alcohol component in water is evaporated and its concentration is changed, the change in the refractive index of the liquid as a whole can be advantageously made very small. On the other hand, if a substance opaque to light at 193 nm or an impurity greatly differing in the refractive index from water is mingled, this incurs distortion of the optical image projected on the resist. Therefore, water used is preferably distilled water. Pure water after further being subjected to filtration through an ion exchange filter or the like may also be used.

The electrical resistance of the immersion liquid is preferably 18.3 MQcm or more, and TOC (organic material concentration) is preferably 20 ppb or less. Also, the immersion liquid is preferably subjected to a deaeration treatment.

Furthermore, the lithography performance can be raised by increasing the refractive index of the immersion liquid. From such a viewpoint, an additive capable of increasing the refractive index may be added to water, or heavy water (D₂O) may be used in place of water.

In the case where the resist film formed of the negative resist composition of the present invention is exposed through an immersion medium, a hydrophobic resin (HR) may be further added, if desired, to the resist composition. In this case, the hydrophobic resin (HR) is unevenly distributed to the surface layer of the resist film and when the immersion medium is water, the resist film formed can be enhanced in the receding contact angle on the resist film surface for water as well as in the followability of the immersion liquid. The hydrophobic resin (HR) may be any resin as long as the receding contact angle on the surface is enhanced by its addition, but a resin having at least either a fluorine atom or a silicon atom is preferred. The receding contact angle of the resist film for the immersion liquid (more specifically, for water at 23° C. under 1 atm) is preferably from 60 to 90°, more preferably 70° or more. The amount of the hydrophobic resin added may be appropriately adjusted to give a resist film having a receding contact angle in the range above but is preferably from 0.1 to 10 mass %, more preferably from 0.1 to 5 mass %, based on the entire solid content of the negative resist composition. The hydrophobic resin (HR) is, as described above, unevenly distributed to the interface but unlike a surfactant, need not have necessarily a hydrophilic group within the molecule and may not contribute to uniform mixing of polar/nonpolar substances.

The fluorine atom or silicon atom in the hydrophobic resin (HR) may be present in the main chain of the resin or may be substituted on the side chain.

The hydrophobic resin (HR) is preferably a resin having a fluorine atom-containing alkyl group, a fluorine atom-containing cycloalkyl group or a fluorine atom-containing aryl group, as a fluorine atom-containing partial structure.

The fluorine atom-containing alkyl group (preferably having a carbon number of 1 to 10, more preferably from 1 to 4) is a linear or branched alkyl group with at least one hydrogen atom being substituted for by a fluorine atom and may further have other substituents.

The fluorine atom-containing cycloalkyl group is a monocyclic or polycyclic cycloalkyl group with at least one hydrogen atom being substituted for by a fluorine atom and may further have other substituents.

The fluorine atom-containing aryl group is an aryl group (e.g., phenyl, naphthyl) with at least one hydrogen atom being substituted for by a fluorine atom and may further have other substituents.

Preferred examples of the fluorine atom-containing alkyl group, fluorine atom-containing cycloalkyl group and fluorine atom-containing aryl group include the groups represented by the following formulae (F2) to (F4), but the present invention is not limited thereto.

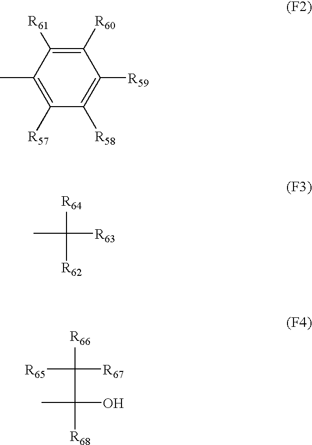

In formulae (F2) to (F4), each of R₅₇ to R₆₈ independently represents a hydrogen atom, a fluorine atom or an alkyl group, provided that at least one of R₅₇ to R₆₁, at least one of R₆₂ to R₆₄ and at least one of R₆₅ to R₆₈ are a fluorine atom or an alkyl group (preferably having a carbon number of 1 to 4) with at least one hydrogen atom being substituted for by a fluorine atom. It is preferred that R₅₇ to R₆₁ and R₆₅ to R₆₇ all are a fluorine atom. Each of R₆₂, R₆₃ and R₆₈ is preferably an alkyl group (preferably having a carbon number of 1 to 4) with at least one hydrogen atom being substituted for by a fluorine atom, more preferably a perfluoroalkyl group having a carbon number of 1 to 4. R₆₂ and R₆₃ may combine with each other to form a ring.

Specific examples of the group represented by formula (F2) include p-fluorophenyl group, pentafluorophenyl group and 3,5-di(trifluoromethyl)phenyl group.

Specific examples of the group represented by formula (F3) include trifluoroethyl group, pentafluoropropyl group, pentafluoroethyl group, heptafluorobutyl group, hexafluoroisopropyl group, heptafluoroisopropyl group, hexafluoro(2-methyl)isopropyl group, nonafluorobutyl group, octafluoroisobutyl group, nonafluorohexyl group, nonafluoro-tert-butyl group, perfluoroisopentyl group, perfluorooctyl group, perfluoro(trimethyl)hexyl group, 2,2,3,3-tetrafluorocyclobutyl group and perfluorocyclohexyl group. Among these, hexafluoroisopropyl group, heptafluoroisopropyl group, hexafluoro(2-methyl)isopropyl group, octafluoroisobutyl group, nonafluoro-tert-butyl group and perfluoroisopentyl group are preferred, and hexafluoroisopropyl group and heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

Specific examples of the repeating unit having a fluorine atom are set forth below, but the present invention is not limited thereto.

In specific examples, X₁ represents a hydrogen atom, —CH₃, —F or —CF₃.

X₂ represents —F or —CF₃.

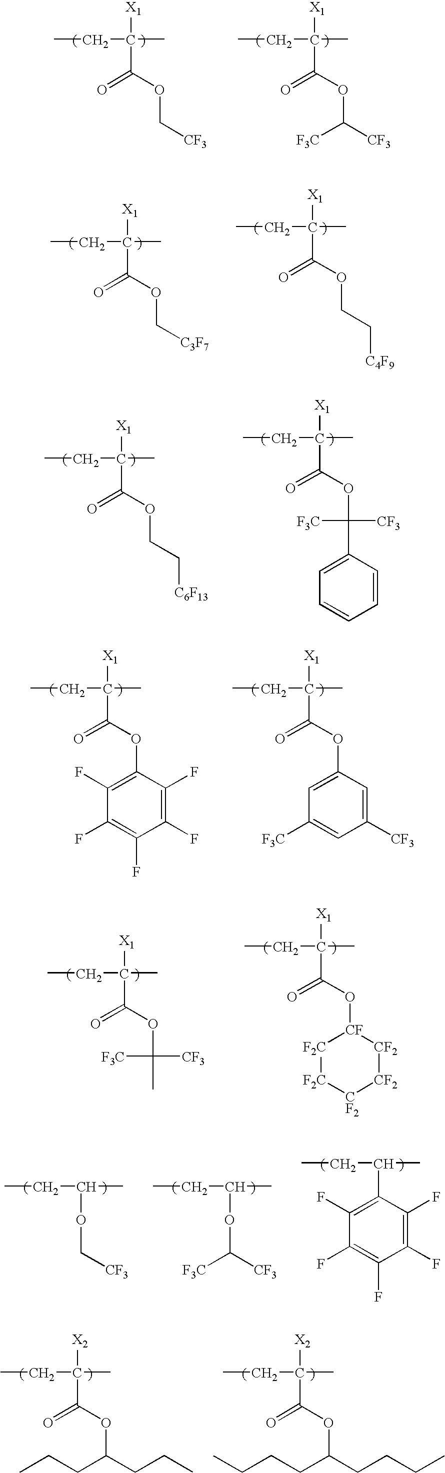

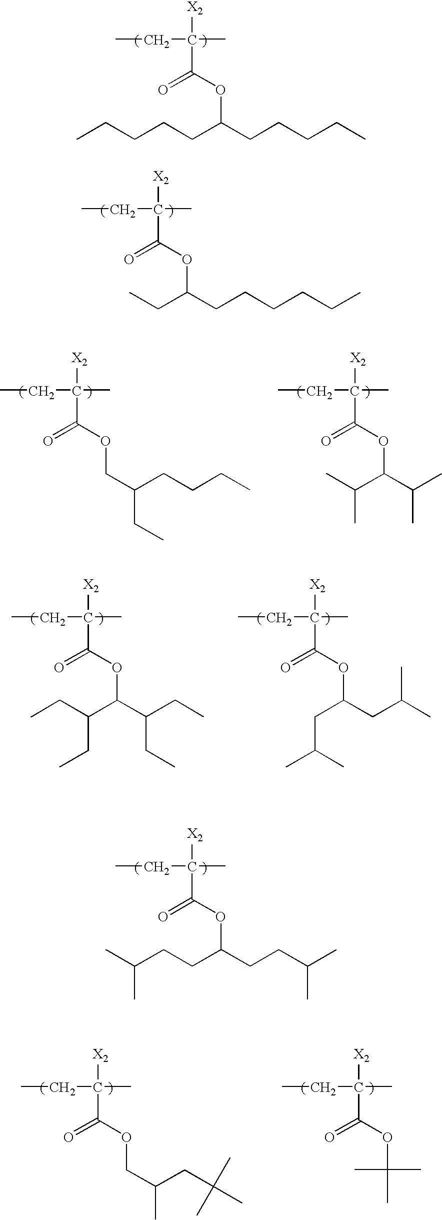

The hydrophobic resin (HR) is preferably a resin having an alkylsilyl structure (preferably a trialkylsilyl group) or a cyclic siloxane structure, as a silicon atom-containing partial structure.

Specific examples of the alkylsilyl structure and cyclic siloxane structure include the groups represented by the following formulae (CS-1) to (CS-3):

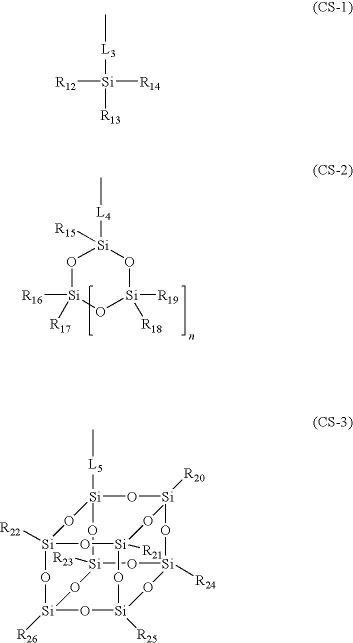

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group is a sole group or a combination of two or more groups, selected from the group consisting of an alkylene group, a phenyl group, an ether group, a thioether group, a carbonyl group, an ester group, an amide group, a urethane group and a urea group.

n represents an integer of 1 to 5.

Specific examples of the repeating unit having a silicon atom are set forth below, but the present invention is not limited thereto.

In specific examples, X₁ represents a hydrogen atom, —CH₃, —F or —CF₃.

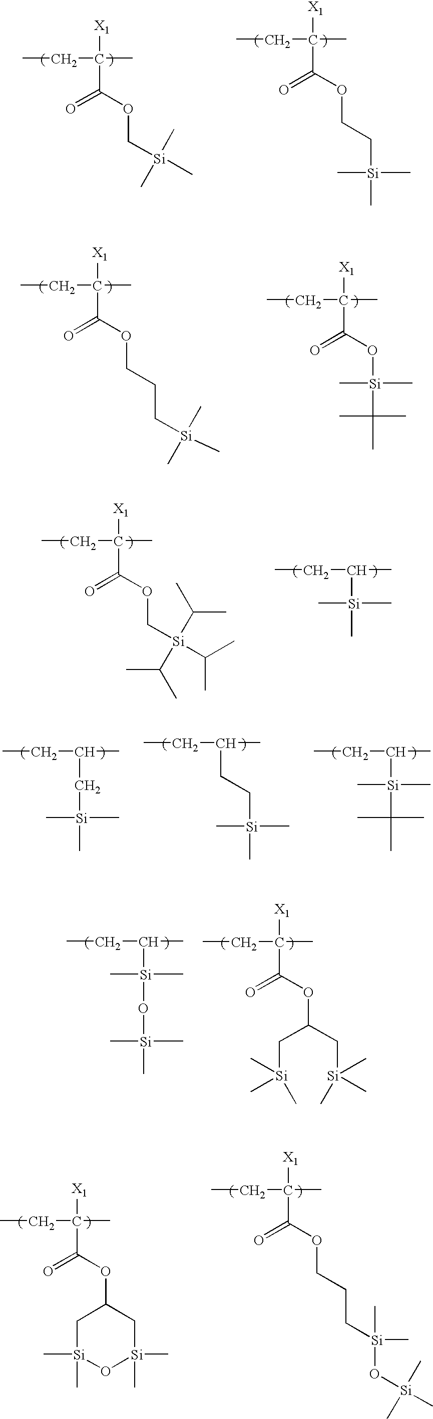

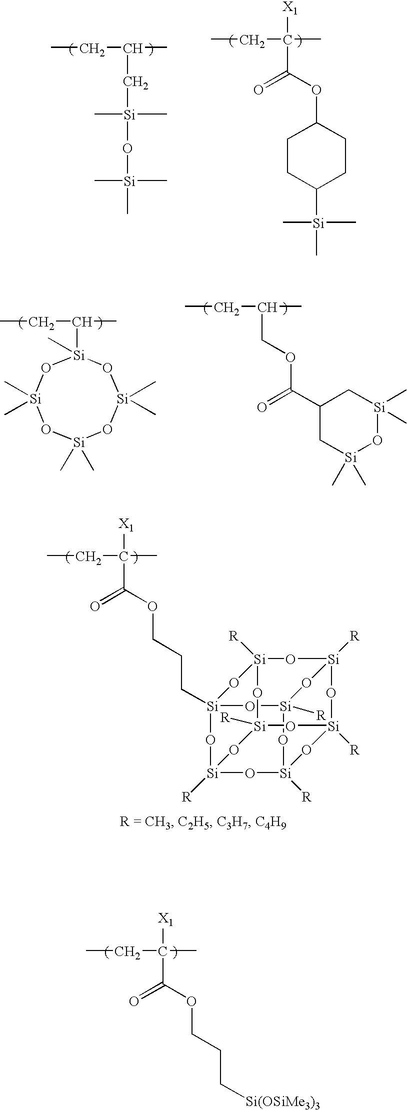

Furthermore, the hydrophobic resin (HR) may contain at least one group selected from the group consisting of the following (x) to (z):

(x) an alkali-soluble group,

(y) a group capable of decomposing by the action of an alkali developer to increase the solubility in an alkali developer, and

(z) a group capable of decomposing by the action of an acid.

Examples of the (x) alkali-soluble group include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group.

Preferred alkali-soluble groups include a fluorinated alcohol group (preferably hexafluoroisopropanol), a sulfonimide group and a bis(carbonyl)methylene group.

As for the repeating unit having (x) an alkali-soluble group, all of a repeating unit where an alkali-soluble group is directly bonded to the resin main chain, such as repeating unit by an acrylic acid or a methacrylic acid, a repeating unit where an alkali-soluble group is bonded to the resin main chain through a linking group, and a repeating unit where an alkali-soluble group is introduced into the polymer chain terminal by using an alkali-soluble group-containing polymerization initiator or chain transfer agent at the polymerization, are preferred.

The content of the repeating unit having (x) an alkali-soluble group is preferably from 1 to 50 mol %, more preferably from 3 to 35 mol %, still more preferably from 5 to 20 mol %, based on all repeating units in the polymer.

Specific examples of the repeating unit having (x) an alkali-soluble group are set forth below, but the present invention is not limited thereto.

In the formulae, Rx represents H, CH₃, CF₃ or CH₂OH.

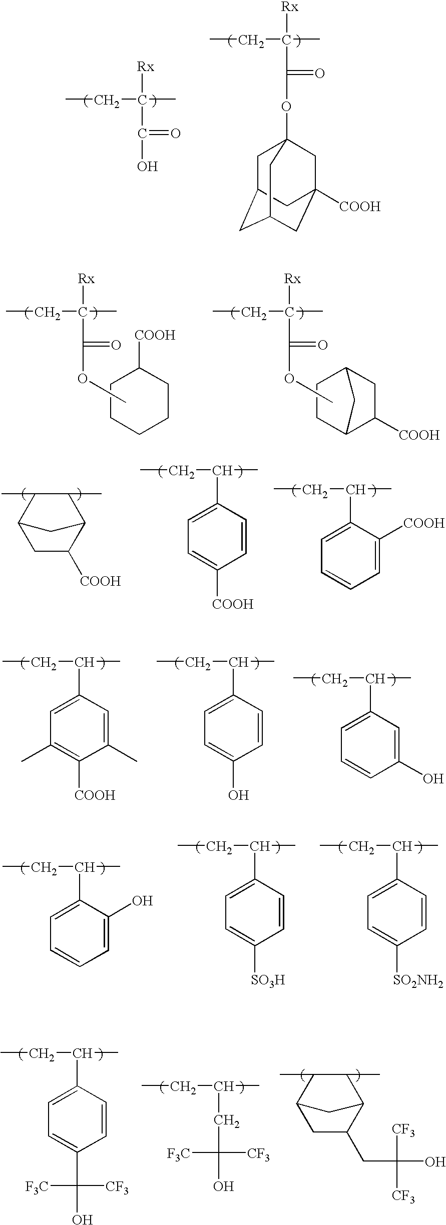

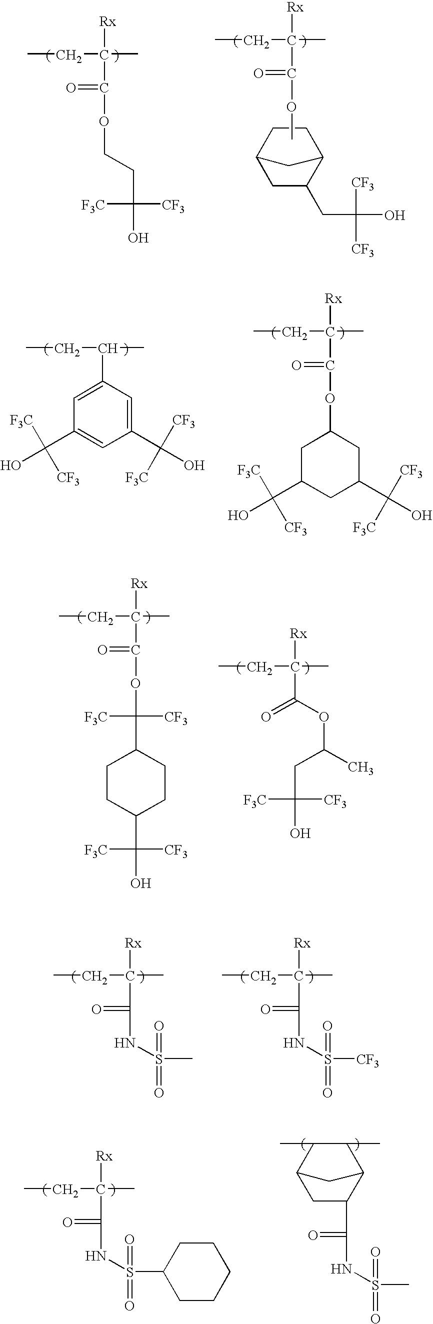

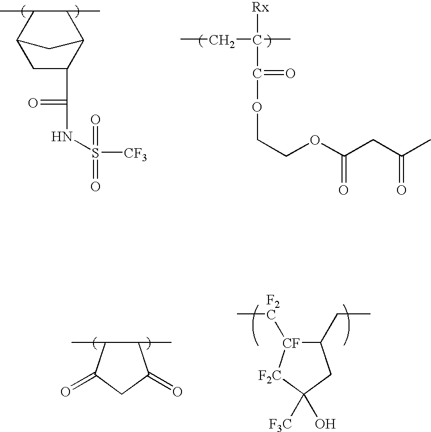

Examples of the (y) group capable of decomposing by the action of an alkali developer to increase the solubility in an alkali developer include a lactone structure-containing group, an acid anhydride group and an acid imide group, with a lactone group being preferred.

As for the repeating unit having (y) a group capable of decomposing by the action of an alkali developer to increase the solubility in an alkali developer, both a repeating unit where (y) a group capable of decomposing by the action of an alkali developer to increase the solubility in an alkali developer is bonded to the main chain of the resin, such as repeating unit by an acrylic acid ester or a methacrylic acid ester, and a repeating unit where (y) a group capable of increasing the solubility in an alkali developer is introduced into the polymer chain terminal by using a polymerization initiator or chain transfer agent containing the group at the polymerization are preferred.

The content of the repeating unit having (y) a group capable of increasing the solubility in an alkali developer is preferably from 1 to 40 mol %, more preferably from 3 to 30 mol %, still more preferably from 5 to 15 mol %, based on all repeating units in the polymer.

Specific examples of the repeating unit having (y) a group capable of increasing the solubility in an alkali developer are the same as those of the repeating unit having a lactone structure described for the resin as the component (A).

Specific examples of the repeating unit having (z) a group capable of decomposing by the action of an acid, contained in the hydrophobic resin (HR), include the followings. The group capable of decomposing by the action of an acid is a group capable of decomposing by the action of an acid to produce an alkali-soluble group (hereinafter sometimes referred to as an “acid-decomposable group”).

Examples of the alkali-soluble group include groups having a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, tris(alkylcarbonyl)methylene group or a tris(alkylsulfonyl)methylene group.

Preferred alkali-soluble groups include a carboxylic acid group, a fluorinated alcohol group (preferably hexafluoroisopropanol) and a sulfonic acid group.

The group preferred as the acid-decomposable group is a group where a hydrogen atom of the alkali-soluble group above is substituted for by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group, and R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like, more preferably a tertiary alkyl ester group.

The hydrophobic resin (HR) preferably contains a repeating unit having an acid-decomposable group. The repeating unit having an acid-decomposable group is preferably a repeating unit represented by the following formula (AI):

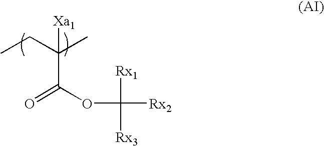

In formula (AI), Xa₁ represents a hydrogen atom, a methyl group, a trifluoromethyl group or a hydroxymethyl group.

Each of Rx₁ to Rx₃ independently represents an alkyl group (linear or branched) or a cycloalkyl group (monocyclic or polycyclic).

At least two members out of Rx₁ to Rx₃ may combine to form a cycloalkyl group (monocyclic or polycyclic).

The alkyl group of Rx₁ to Rx₃ is preferably an alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic alkyl group such as cyclopentyl group and cyclohexyl group, or a polycyclic alkyl group such as norbornyl group, tetracyclodecanyl group, tetracyclododecanyl group and adamantyl group.

The cycloalkyl group formed by combining at least two members out of Rx₁ to Rx₃ is preferably a monocyclic alkyl group such as cyclopentyl group and cyclohexyl group, or a polycyclic alkyl group such as norbornyl group, tetracyclodecanyl group, tetracyclododecanyl group and adamantyl group.

An embodiment where Rx₁ is a methyl group or an ethyl group and Rx₂ and Rx₃ are combined to form the above-described cycloalkyl group is preferred.

Specific preferred examples of the repeating unit having an acid-decomposable group are set forth below, but the present invention is not limited thereto.

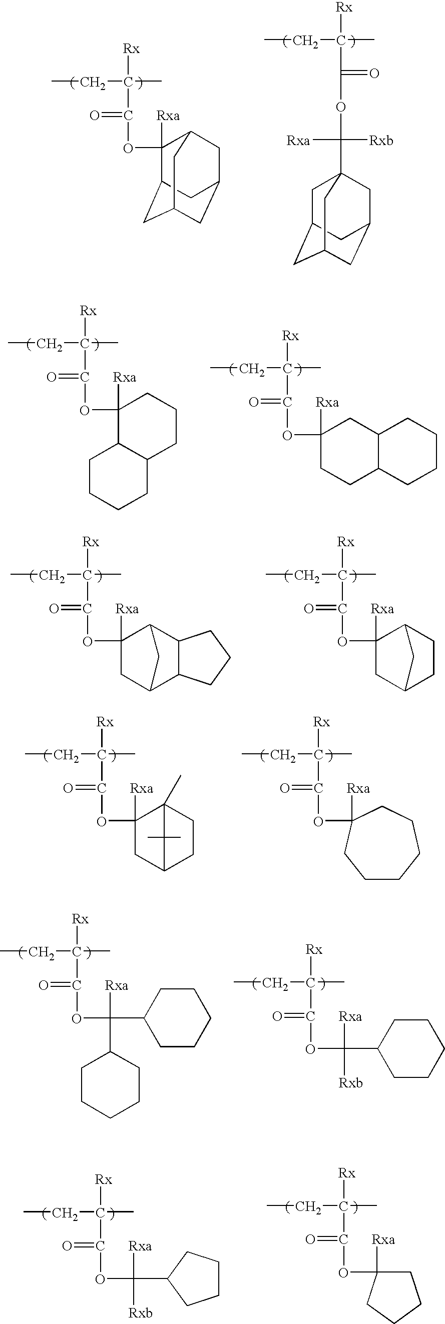

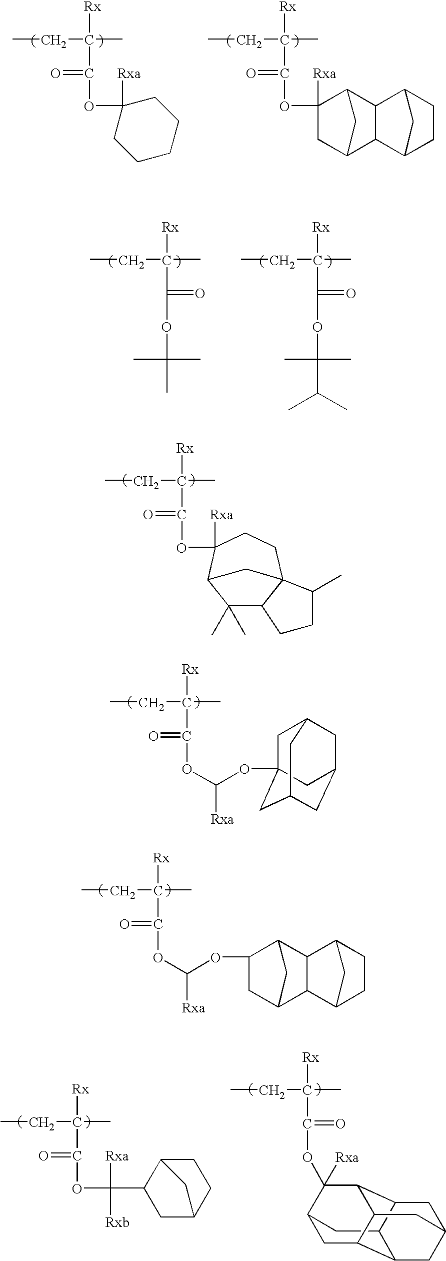

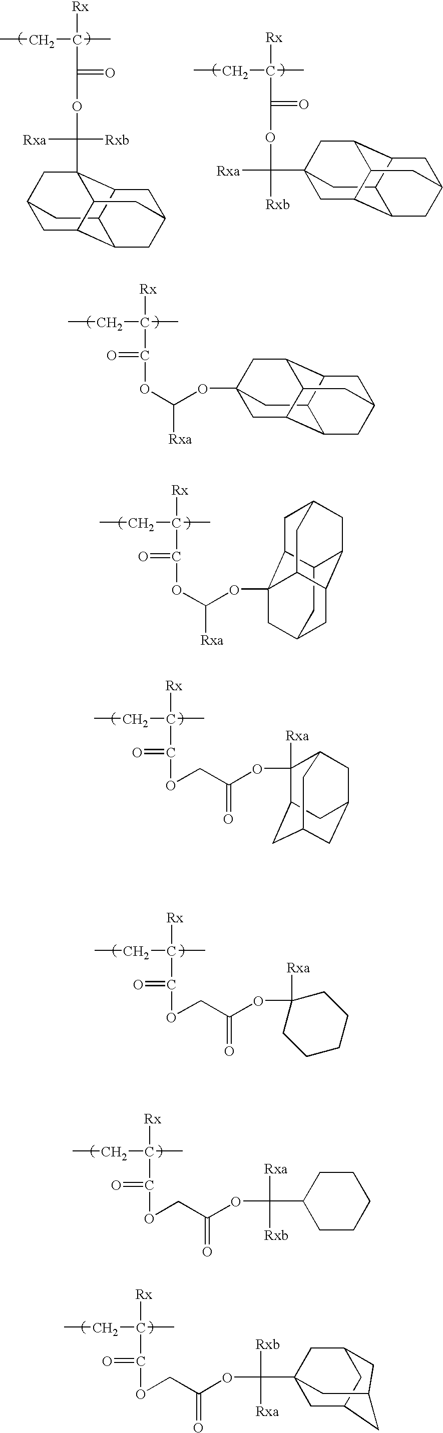

In specific examples, Rx represents H, CH₃, CF₃ or CH₂OH, and each of Rxa and Rxb independently represents an alkyl group (preferably having a carbon number of 1 to 4).

In the hydrophobic resin (HR), the content of the repeating unit having (z) a group capable of decomposing by the action of an acid is preferably from 1 to 80 mol %, more preferably from 10 to 80 mol %, still more preferably from 20 to 60 mol %, based on all repeating units in the polymer.

The hydrophobic resin (HR) may further contain a repeating unit represented by the following formula (III):

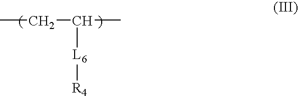

In formula (III), R₄ represents a group having an alkyl group, a cycloalkyl group, an alkenyl group or a cycloalkenyl group.

L₆ represents a single bond or a divalent linking group.

In formula (III), the alkyl group of R₄ is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The divalent linking group of L₆ is preferably an alkylene group (preferably having a carbon number of 1 to 5) or an oxy group.

In the case where the hydrophobic resin (HR) contains a fluorine atom, the fluorine atom content is preferably from 5 to 80 mass %, more preferably from 10 to 80 mass %, based on the molecular weight of the hydrophobic resin (HR). Also, the fluorine atom-containing repeating unit preferably occupies from 10 to 100 mass %, more preferably from 30 to 100 mass %, in the hydrophobic resin (HR).

In the case where the hydrophobic resin (HR) contains a silicon atom, the silicon atom content is preferably from 2 to 50 mass %, more preferably from 2 to 30 mass %, based on the molecular weight of the hydrophobic resin (HR). Also, the silicon atom-containing repeating unit preferably occupies from 10 to 100 mass %, more preferably from 20 to 100 mass %, in the hydrophobic resin (HR).

The standard polystyrene-equivalent weight average molecular of the hydrophobic resin (HR) is preferably from 1,000 to 100,000, more preferably from 1,000 to 50,000, still more preferably from 2,000 to 15,000.

In the hydrophobic resin (HR), similarly to the resin as the component (A), it is of course preferred that the content of impurities such as metal is small, but also, the content of residual monomers or oligomer components is preferably from 0 to 10 mass %, more preferably from 0 to 5 mass %, still more preferably from 0 to 1 mass %. When these conditions are satisfied, a resist free of extraneous substances in the liquid or change with aging of sensitivity or the like can be obtained. Furthermore, in view of resolution, resist profile, side wall of resist pattern, roughness and the like, the molecular weight distribution (Mw/Mn, sometimes referred to as “polydispersity”) is preferably from 1 to 5, more preferably from 1 to 3, still more preferably from 1 to 2.

As for the hydrophobic resin (HR), various commercially available products may be used or the resin may be synthesized by an ordinary method (for example, radical polymerization)). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone. The polymerization is more preferably performed using the same solvent as the solvent used in the negative resist composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methylpropionate). The concentration at the reaction is from 5 to 50 mass %, preferably from 30 to 50 mass %, and the reaction temperature is usually from 10 to 150° C., preferably from 30 to 120° C., more preferably from 60 to 100° C.

After the completion of reaction, the reaction solution is allowed to cool to room temperature and purified. The purification may be performed by a normal method, for example, a liquid-liquid extraction method of applying water washing or combining an appropriate solvent to remove residual monomers or oligomer components; a purification method in a solution sate, such as ultrafiltration of removing by extraction only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent to the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing such a solvent, and the like according to the kind of the polymer. Among these solvents, a solvent containing at least an alcohol (particularly, methanol or the like) or water is preferred as the precipitation or reprecipitation solvent.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by taking into consideration the efficiency or operability but is usually on the order of 0 to 50° C., preferably in the vicinity of room temperature (for example, approximately from 20 to 35° C.). The precipitation or reprecipitation operation may be performed using a commonly employed mixing vessel such as stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C., preferably on the order of 30 to 50° C.

Incidentally, after the resin is once precipitated and separated, the resin may be again dissolved in a solvent and then put into contact with a solvent in which the resin is sparingly soluble or insoluble. That is, there may be used a method comprising, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

Specific examples of the hydrophobic resin (HR) are set forth below. Also, the molar ratio of repeating units (corresponding to respective repeating units from the left), weight average molecular weight and polydispersity of each resin are shown in Table 1 later.

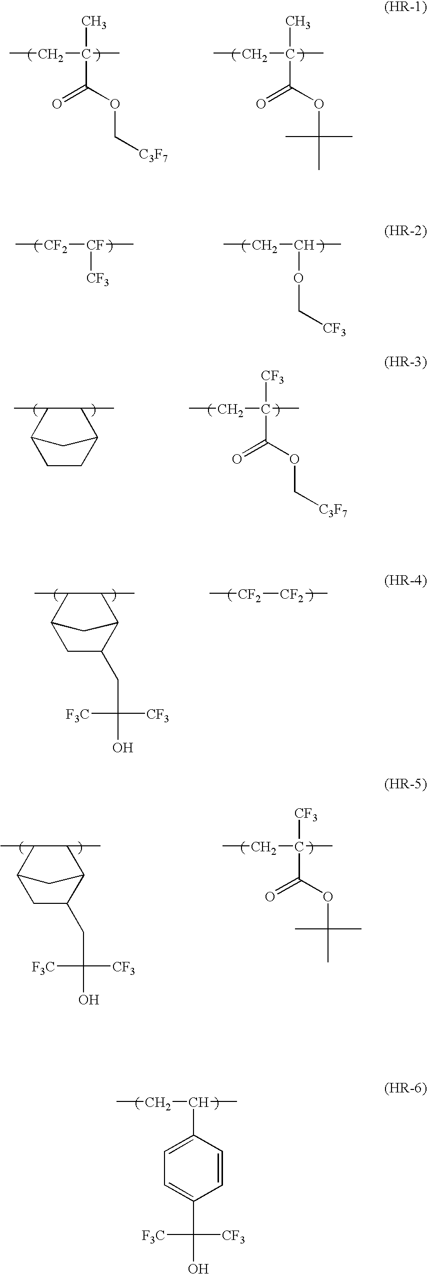

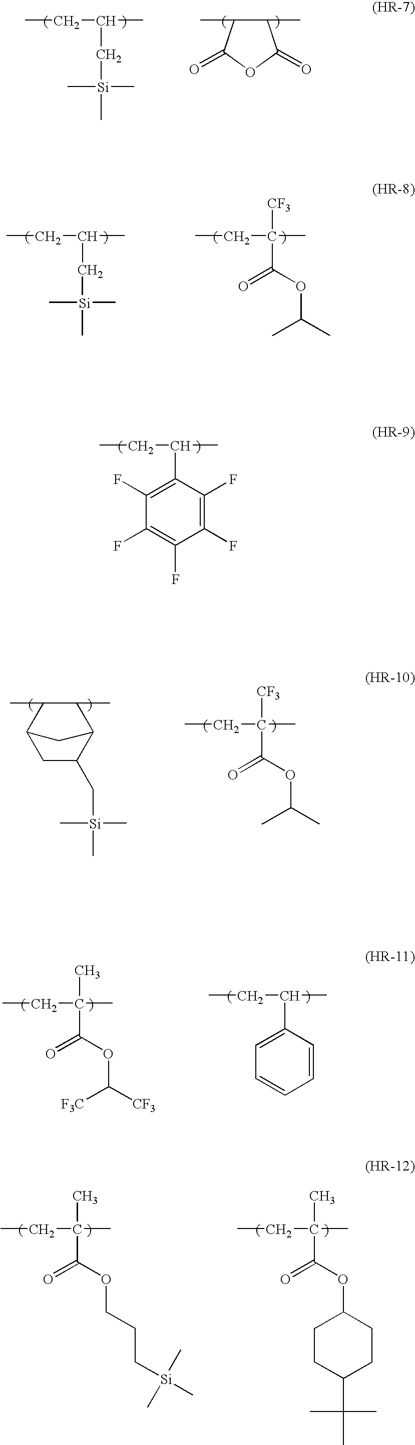

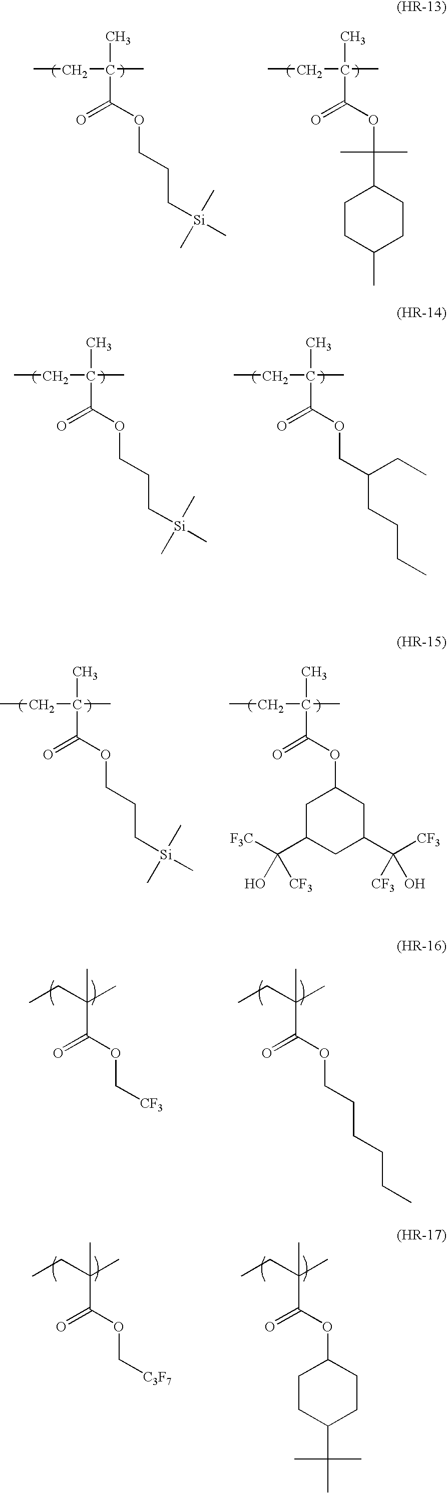

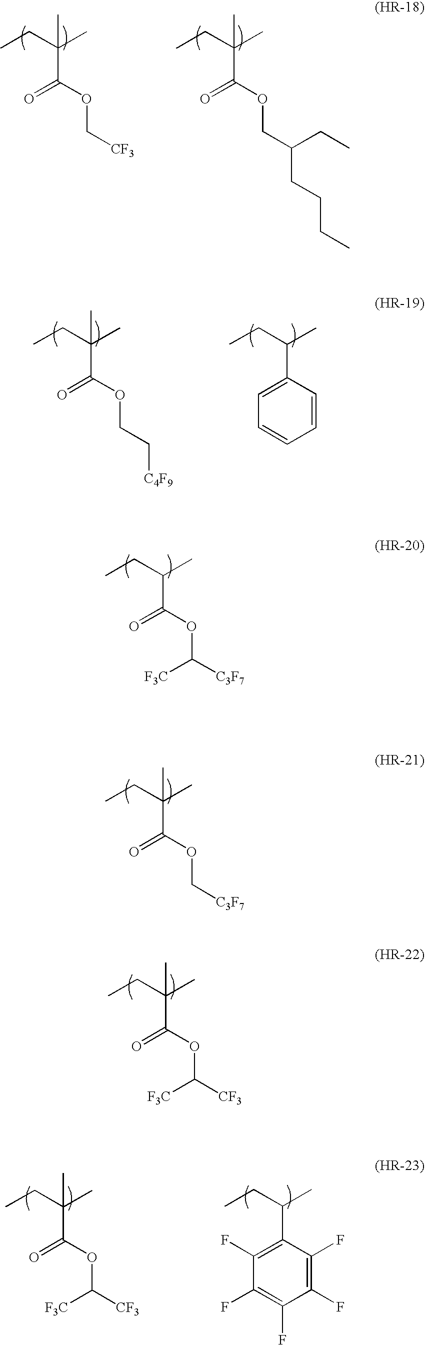

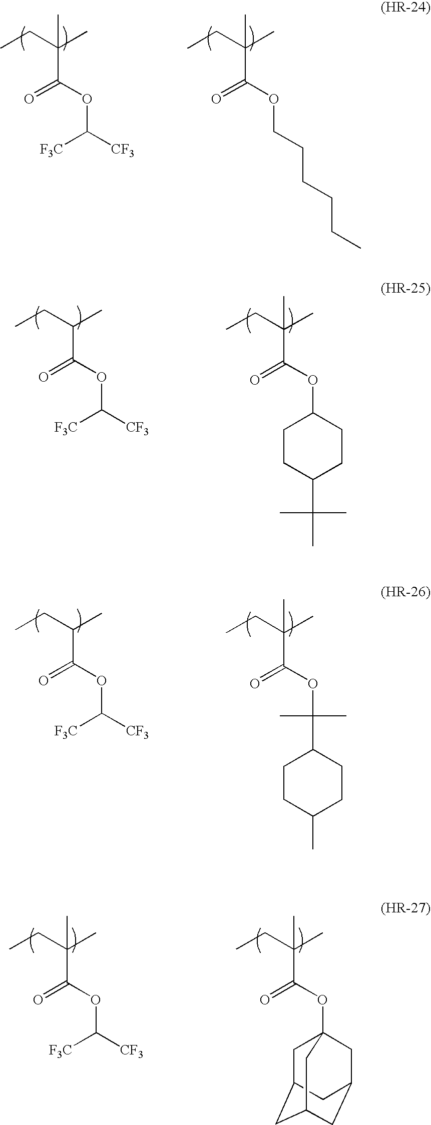

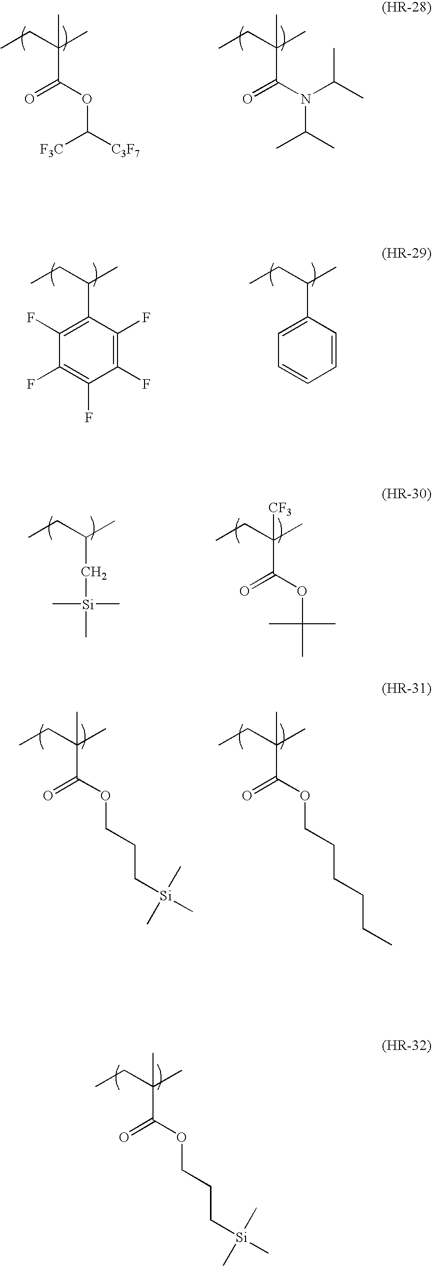

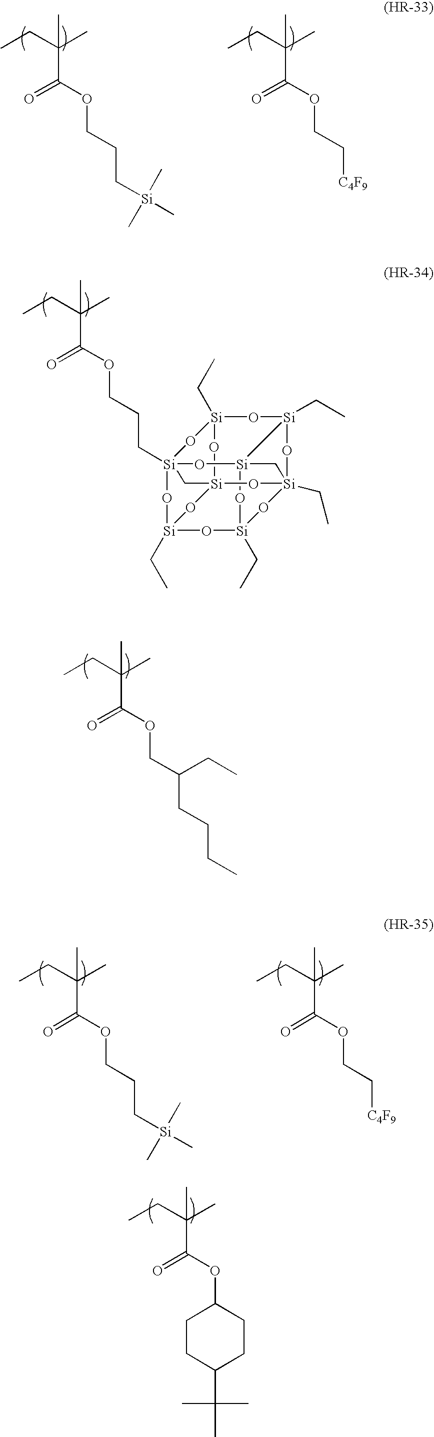

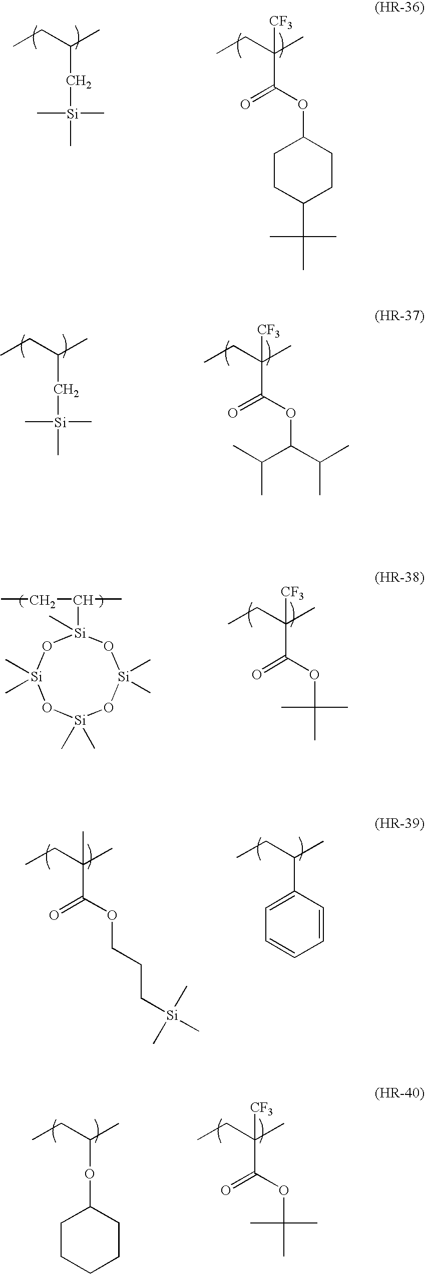

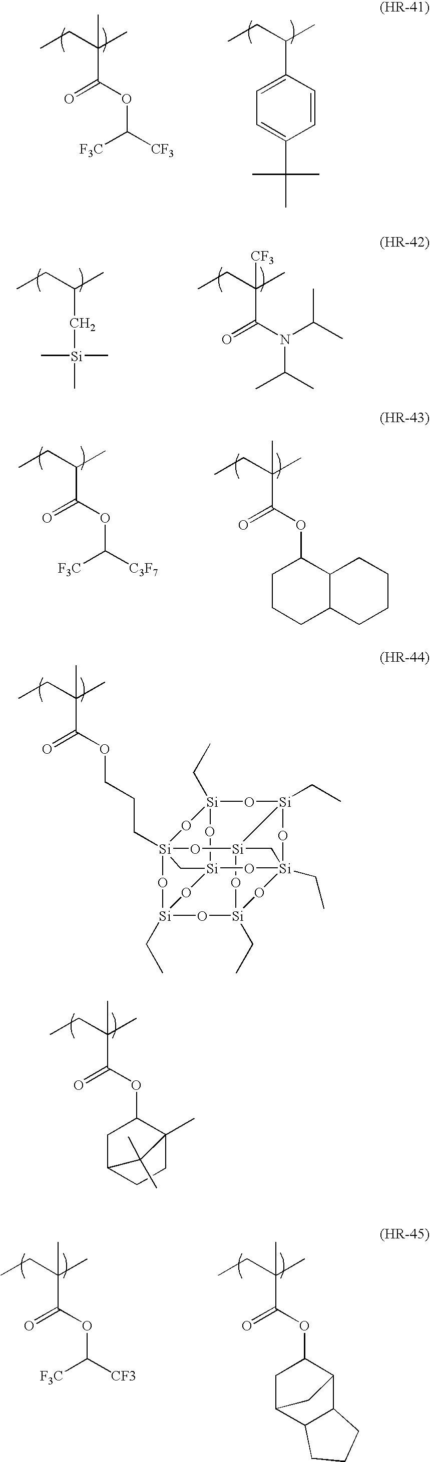

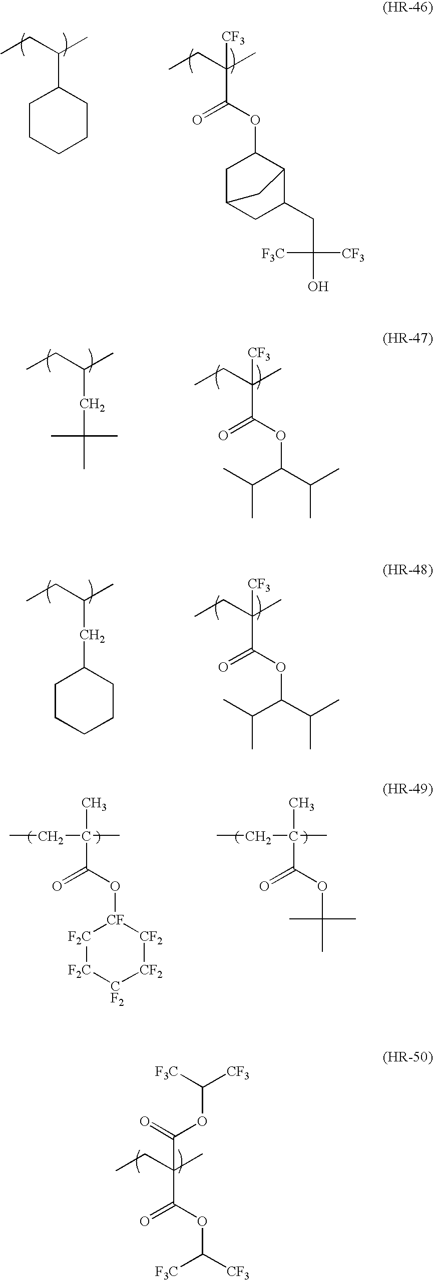

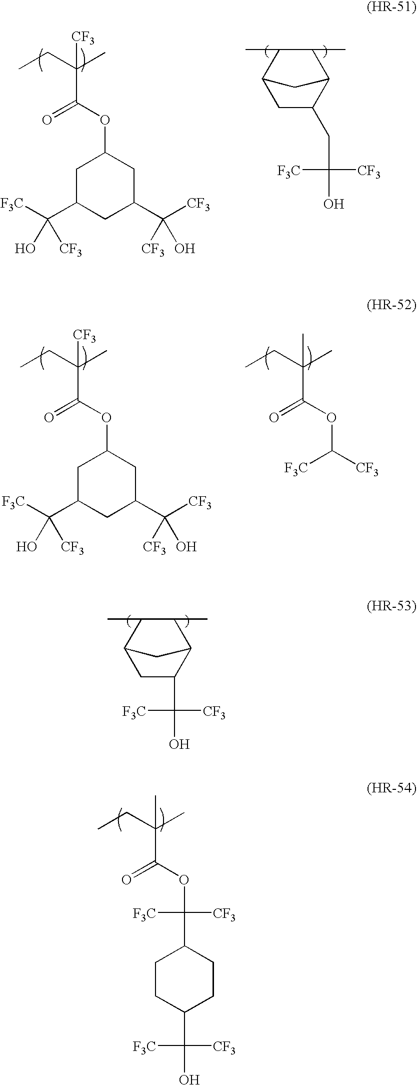

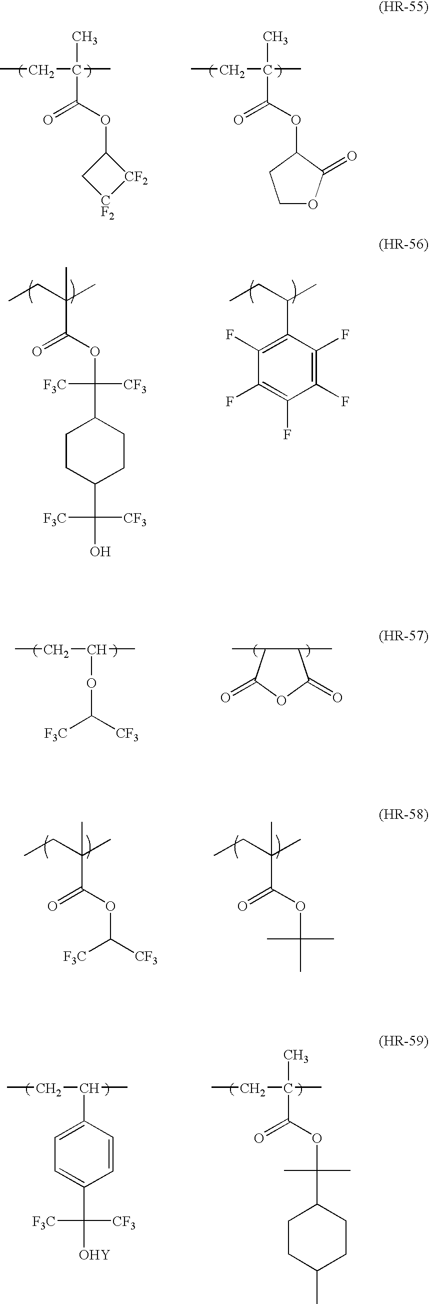

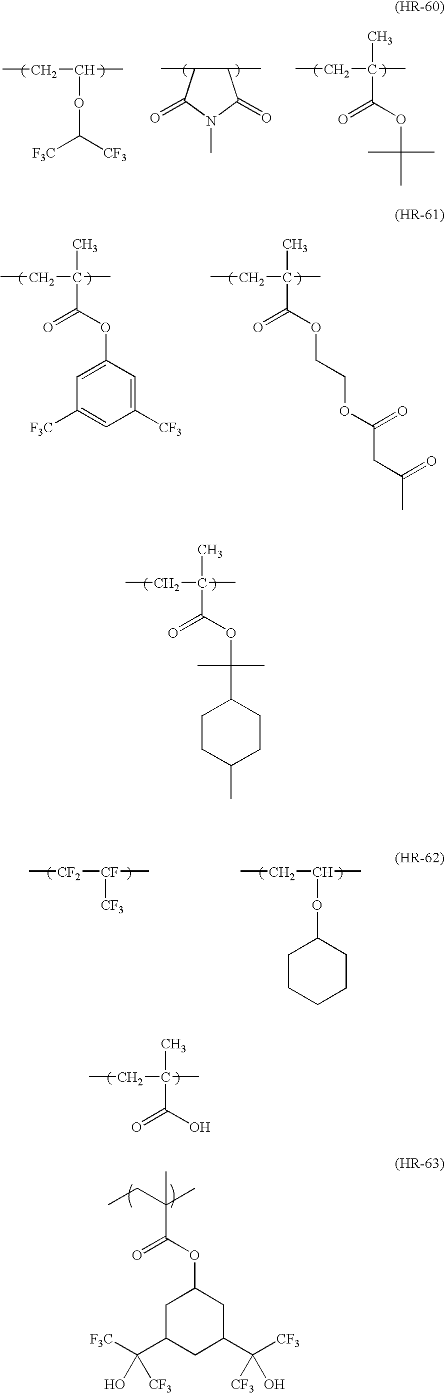

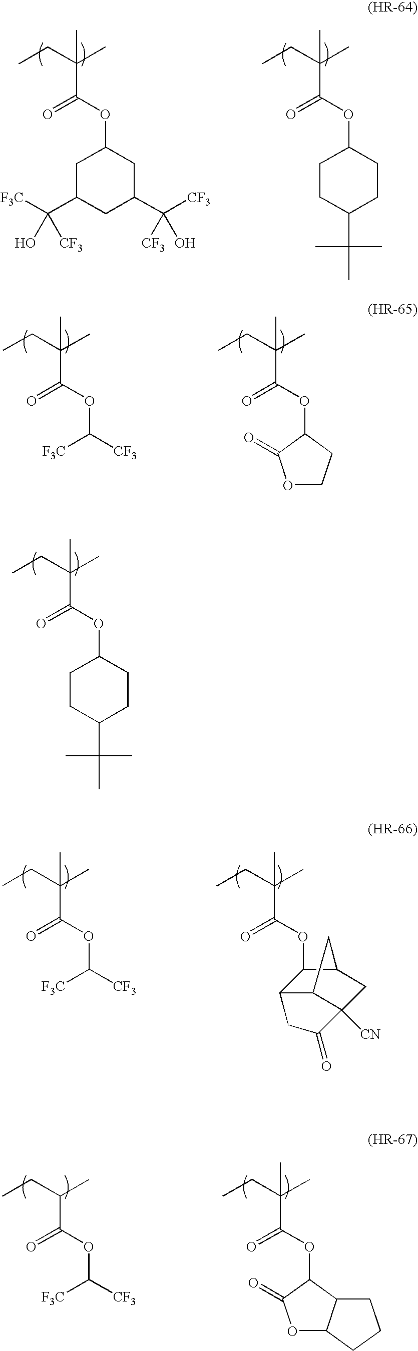

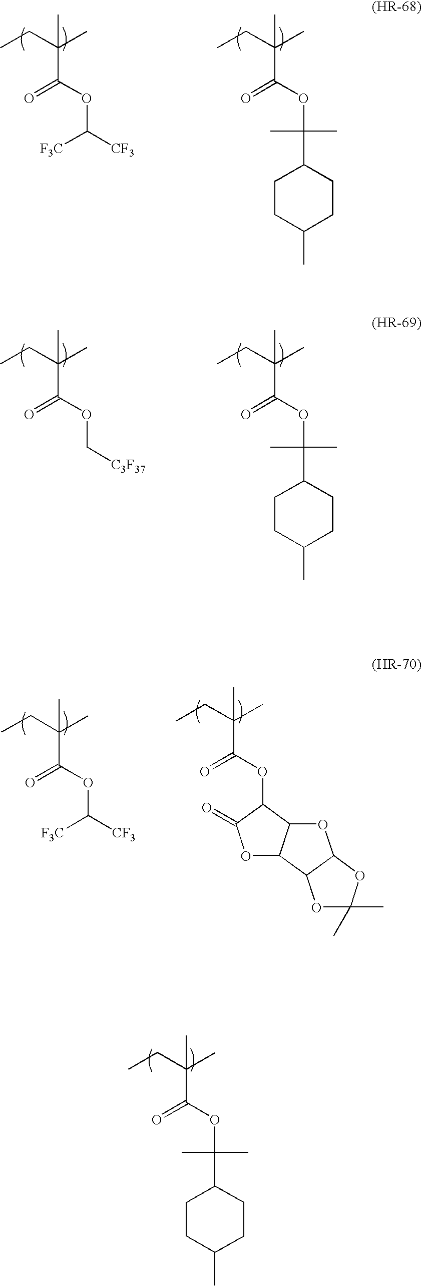

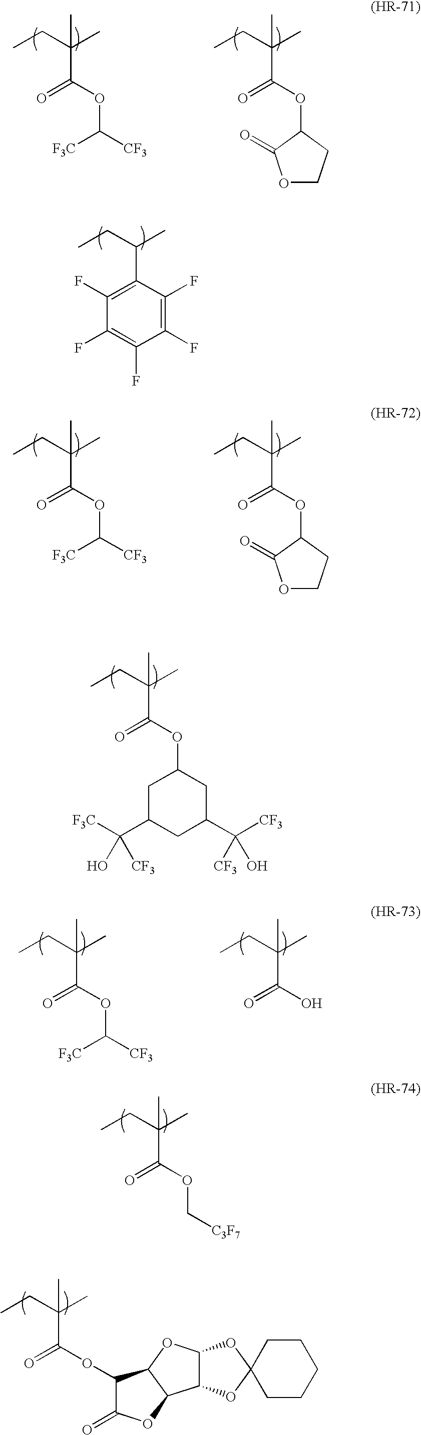

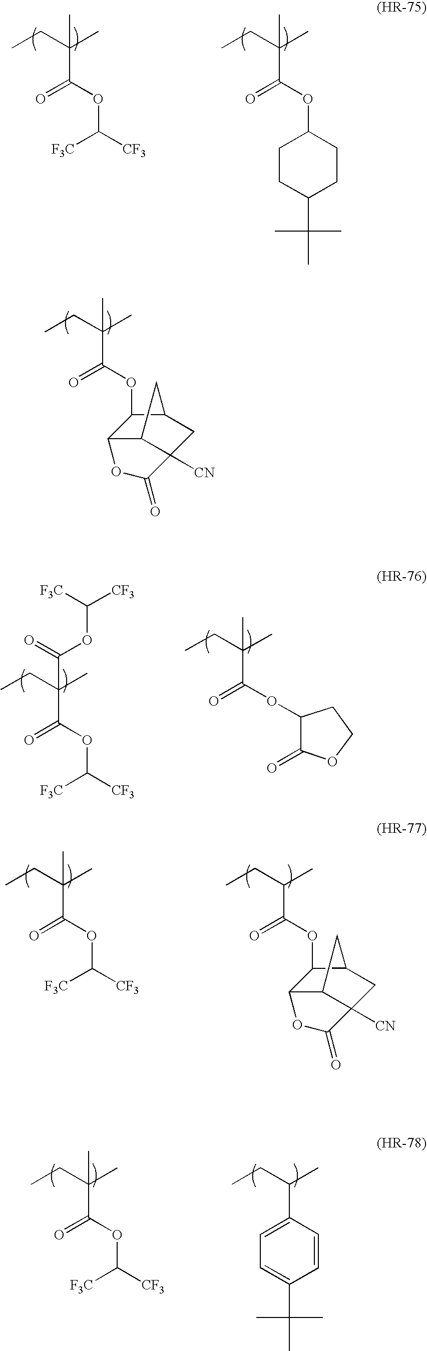

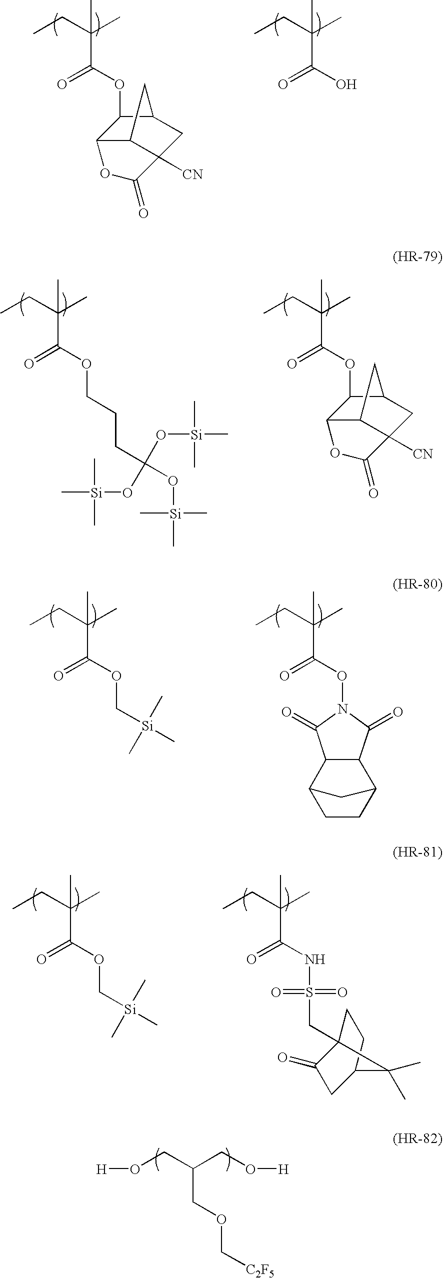

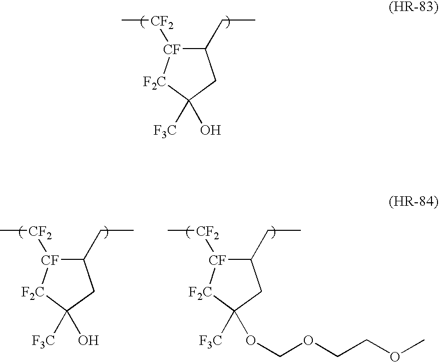

TABLE 1

| Resin | Composition | Mw | Mw/Mn |
|---|---|---|---|
| HR-1 | 50/50 | 8800 | 2.1 |
| HR-2 | 50/50 | 5200 | 1.8 |
| HR-3 | 50/50 | 4800 | 1.9 |
| HR-4 | 50/50 | 5300 | 1.9 |
| HR-5 | 50/50 | 6200 | 1.9 |
| HR-6 | 100 | 12000 | 2.0 |
| HR-7 | 50/50 | 5800 | 1.9 |
| HR-8 | 50/50 | 6300 | 1.9 |
| HR-9 | 100 | 5500 | 2.0 |
| HR-10 | 50/50 | 7500 | 1.9 |
| HR-11 | 70/30 | 10200 | 2.2 |
| HR-12 | 40/60 | 15000 | 2.2 |
| HR-13 | 40/60 | 13000 | 2.2 |
| HR-14 | 80/20 | 11000 | 2.2 |
| HR-15 | 60/40 | 9800 | 2.2 |
| HR-16 | 50/50 | 8000 | 2.2 |
| HR-17 | 50/50 | 7600 | 2.0 |
| HR-18 | 50/50 | 12000 | 2.0 |
| HR-19 | 20/80 | 6500 | 1.8 |
| HR-20 | 100 | 6500 | 1.2 |
| HR-21 | 100 | 6000 | 1.6 |
| HR-22 | 100 | 2000 | 1.6 |
| HR-23 | 50/50 | 6000 | 1.7 |
| HR-24 | 50/50 | 8800 | 1.9 |
| HR-25 | 50/50 | 7800 | 2.0 |
| HR-26 | 50/50 | 8000 | 2.0 |
| HR-27 | 80/20 | 8000 | 1.8 |
| HR-28 | 30/70 | 7000 | 1.7 |
| HR-29 | 50/50 | 6500 | 1.6 |
| HR-30 | 50/50 | 6500 | 1.6 |
| HR-31 | 50/50 | 9000 | 1.8 |
| HR-32 | 100 | 10000 | 1.6 |
| HR-33 | 70/30 | 8000 | 2.0 |
| HR-34 | 10/90 | 8000 | 1.8 |
| HR-35 | 30/30/40 | 9000 | 2.0 |
| HR-36 | 50/50 | 6000 | 1.4 |
| HR-37 | 50/50 | 5500 | 1.5 |
| HR-38 | 50/50 | 4800 | 1.8 |
| HR-39 | 60/40 | 5200 | 1.8 |
| HR-40 | 50/50 | 8000 | 1.5 |
| HR-41 | 20/80 | 7500 | 1.8 |
| HR-42 | 50/50 | 6200 | 1.6 |
| HR-43 | 60/40 | 16000 | 1.8 |
| HR-44 | 80/20 | 10200 | 1.8 |
| HR-45 | 50/50 | 12000 | 2.6 |
| HR-46 | 50/50 | 10900 | 1.9 |
| HR-47 | 50/50 | 6000 | 1.4 |
| HR-48 | 50/50 | 4500 | 1.4 |
| HR-49 | 50/50 | 6900 | 1.9 |
| HR-50 | 100 | 2300 | 2.6 |
| HR-51 | 60/40 | 8800 | 1.5 |
| HR-52 | 68/32 | 11000 | 1.7 |
| HR-53 | 100 | 8000 | 1.4 |
| HR-54 | 100 | 8500 | 1.4 |
| HR-55 | 80/20 | 13000 | 2.1 |
| HR-56 | 70/30 | 18000 | 2.3 |
| HR-57 | 50/50 | 5200 | 1.9 |
| HR-58 | 50/50 | 10200 | 2.2 |
| HR-59 | 60/40 | 7200 | 2.2 |
| HR-60 | 32/32/36 | 5600 | 2.0 |
| HR-61 | 30/30/40 | 9600 | 1.6 |
| HR-62 | 40/40/20 | 12000 | 2.0 |
| HR-63 | 100 | 6800 | 1.6 |
| HR-64 | 50/50 | 7900 | 1.9 |
| HR-65 | 40/30/30 | 5600 | 2.1 |
| HR-66 | 50/50 | 6800 | 1.7 |
| HR-67 | 50/50 | 5900 | 1.6 |
| HR-68 | 49/51 | 6200 | 1.8 |
| HR-69 | 50/50 | 8000 | 1.9 |
| HR-70 | 30/40/30 | 9600 | 2.3 |
| HR-71 | 30/40/30 | 9200 | 2.0 |
| HR-72 | 40/29/31 | 3200 | 2.1 |
| HR-73 | 90/10 | 6500 | 2.2 |
| HR-74 | 50/50 | 7900 | 1.9 |
| HR-75 | 20/30/50 | 10800 | 1.6 |
| HR-76 | 50/50 | 2200 | 1.9 |
| HR-77 | 50/50 | 5900 | 2.1 |
| HR-78 | 40/20/30/10 | 14000 | 2.2 |
| HR-79 | 50/50 | 5500 | 1.8 |
| HR-80 | 50/50 | 10600 | 1.9 |
| HR-81 | 50/50 | 8600 | 2.3 |
| HR-82 | 100 | 15000 | 2.1 |
| HR-83 | 100 | 6900 | 2.5 |
| HR-84 | 50/50 | 9900 | 2.3 |

In order to prevent the resist film from directly contacting with the immersion liquid, a film sparingly soluble in an immersion liquid (hereinafter, sometimes referred to as a “topcoat”) may be provided between the immersion liquid and the resist film formed of the negative resist composition of the present invention. The functions required of the topcoat are suitability for coating as an overlayer of the resist, transparency to radiation, particularly light at a wavelength of 193 nm, and sparing solubility in the immersion liquid. The topcoat is preferably unmixable with the resist and capable of being uniformly coated as an overlayer of the resist.

In view of transparency to light at a wavelength of 193 nm, the topcoat is preferably a polymer not abundantly containing an aromatic, and specific examples thereof include a hydrocarbon polymer, an acrylic acid ester polymer, a polymethacrylic acid, a polyacrylic acid, a polyvinyl ether, a silicon-containing polymer and a fluorine-containing polymer. The above-described hydrophobic resin (HR) is suitable also as the topcoat. If impurities dissolve out into the immersion liquid from the topcoat, the optical lens is contaminated. In this viewpoint, the topcoat preferably contains little residual monomer components of the polymer.

On peeling off the topcoat, a developer may be used or a releasing agent may be separately used. The releasing agent is preferably a solvent less permeating the resist film. From the standpoint that the peeling step can be performed simultaneously with the development step of the resist film, the topcoat is preferably peelable with an alkali developer and for enabling the peeling with an alkali developer, the topcoat is preferably acidic, but in view of non-intermixing with the resist film, the topcoat may be neutral or alkaline.

With no difference in the refractive index between the topcoat and the immersion liquid, the resolution is enhanced. In the case of using water as the immersion liquid at the exposure to ArF excimer laser (wavelength: 193 nm), the topcoat for ArF immersion exposure preferably has a refractive index close to the refractive index of the immersion liquid. From the standpoint of making the refractive index close to that of the immersion liquid, the topcoat preferably contains a fluorine atom. Also, in view of transparency and refractive index, the topcoat is preferably a thin film.

The topcoat is preferably unmixable with the resist film and further unmixable with the immersion liquid. From this standpoint, when the immersion liquid is water, the solvent used for the topcoat is preferably a medium which is sparingly soluble in the solvent used for the negative resist composition and insoluble in water. Furthermore, when the immersion liquid is an organic solvent, the topcoat may be either water-soluble or water-insoluble.

The negative resist composition of the present invention may be applied to a multilayer resist process (particularly, a three-layer resist process). The multilayer resist process comprises the following steps:

(a) forming a lower resist layer composed of an organic material on a substrate to be processed,

(b) sequentially stacking on the lower resist layer an intermediate layer and an upper resist layer composed of an organic material capable of polymerizing or decomposing upon irradiation with radiation, and

(c) after forming a predetermined pattern on the upper resist layer, sequentially etching the intermediate layer, the lower layer and the substrate.

An organopolysiloxane (silicone resin) or SiO₂ coating solution (SOG) is generally used for the intermediate layer. As for the lower resist layer, an appropriate organic polymer film is used, but various known photoresists may be used. Examples thereof include various series such as FH Series and FHi Series produced by Fujifilm Arch Co., Ltd., and PFI Series produced by Sumitomo Chemical Co., Ltd.

The film thickness of the lower resist layer is preferably from 0.1 to 4.0 μm, more preferably from 0.2 to 2.0 μm, still more preferably from 0.25 to 1.5 μm. The film thickness is preferably 0.1 μm or more in view of antireflection or dry etching resistance and preferably 4.0 μm or less in view of aspect ratio or pattern collapse of a fine pattern formed.

(F) Surfactant Having at Least Either Fluorine Atom or Silicon Atom (Fluorine- and/or Silicon-Containing Surfactant)

The negative resist composition of the present invention preferably further contains a surfactant, more preferably any one of fluorine-containing and/or silicon-containing surfactants (a fluorine-containing surfactant, a silicon-containing surfactant and a surfactant containing both a fluorine atom and a silicon atom), or two or more thereof.

By incorporating the above-described surfactant into the negative resist composition of the present invention, a resist pattern with good performance in terms of sensitivity, resolution and adherence as well as little development defect can be formed when using an exposure light source at a wavelength of 250 nm or less, particularly at a wavelength of 220 nm or less.

Examples of the fluorine-containing and/or silicon-containing surfactant include surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451. The following commercially available surfactants each may also be used as it is.

Examples of the commercially available surfactant which can be used include a fluorine-containing surfactant and a silicon-containing surfactant, such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by Dainippon Ink & Chemicals, Inc.); Surflon S-382, SC101, 102, 103, 104, 105 and 106 (produced by Asahi Glass Co., Ltd.); Troysol S-366 (produced by Troy Chemical); GF-300 and GF-150 (produced by Toagosei Chemical Industry Co., Ltd.); Surflon S-393 (produced by Seimi Chemical Co., Ltd.); EFtop EF121, EF122A, EF122B, RF122C, EF125M, EF135M, EF351, 352, EF801, EF802 and EF601 (produced by JEMCO Inc.); PF636, PF656, PF6320 and PF6520 (produced by OMNOVA); and FTX-204D, 208G, 218G, 230G, 204D, 208D, 212D, 218 and 222D (produced by NEOS Co., Ltd.). In addition, polysiloxane polymer KP-341 (produced by Shin-Etsu Chemical Co., Ltd.) may also be used as a silicon-containing surfactant.

Other than these known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

The polymer having a fluoro-aliphatic group is preferably a copolymer of a fluoro-aliphatic group-containing monomer with at least one kind of a monomer selected from a (poly(oxyalkylene)) acrylate and a (poly(oxyalkylene)) methacrylate, and the polymer may have an irregular distribution or may be a block copolymer. Examples of the poly(oxyalkylene) group include a poly(oxyethylene) group, a poly(oxypropylene) group and a poly(oxybutylene) group. This group may also be a unit having alkylenes differing in the chain length within the same chain, such as block-linked poly(oxyethylene, oxypropylene and oxyethylene) and block-linked poly(oxyethylene and oxypropylene). Furthermore, the copolymer of a fluoro-aliphatic group-containing monomer and a (poly(oxyalkylene)) acrylate (or methacrylate) is not limited only to a binary copolymer but may also be a ternary or greater copolymer obtained by simultaneously copolymerizing two or more different fluoro-aliphatic group-containing monomers or two or more different (poly(oxyalkylene)) acrylates (or methacrylates).

Examples thereof include, as the commercially available surfactant, Megaface F178, F-470, F-473, F-475, F-476 and F-472 (produced by Dainippon Ink & Chemicals, Inc.) and further include a copolymer of a C₆F₁₃ group-containing acrylate (or methacrylate) with a (poly(oxyalkylene)) acrylate (or methacrylate), and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactant may also be used. Specific examples thereof include a nonionic surfactant such as polyoxyethylene alkyl ethers (e.g., polyoxyethylene lauryl ether, polyoxyethylene stearyl ether, polyoxyethylene cetyl ether, polyoxyethylene oleyl ether), polyoxyethylene alkylallyl ethers (e.g., polyoxyethylene octylphenol ether, polyoxyethylene nonylphenol ether), polyoxyethylene•polyoxypropylene block copolymers, sorbitan fatty acid esters (e.g., sorbitan monolaurate, sorbitan monopalmitate, sorbitan monostearate, sorbitan monooleate, sorbitan trioleate, sorbitan tristearate), and polyoxyethylene sorbitan fatty acid esters (e.g., polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate).

One of these surfactants may be used alone, or some of them may be used in combination.

The amount of the surfactant used is preferably from 0.01 to 10 mass %, more preferably from 0.1 to 5 mass %, based on the entire amount of the resist composition (excluding the solvent).

### (G) Organic Solvent

The negative resist composition of the present invention is used by dissolving the above-described components in a predetermined organic solvent. Examples of the organic solvent which can be used include ethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methyl pyruvate, ethyl pyruvate, propyl pyruvate, N,N-dimethylformamide, dimethylsulfoxide, N-methylpyrrolidone, methoxybutanol and tetrahydrofuran.

In the present invention, a mixed solvent prepared by mixing a solvent having a hydroxyl group in the structure and a solvent having no hydroxyl group may be used as the organic solvent.

Examples of the solvent having a hydroxyl group include ethylene glycol, ethylene glycol monomethyl ether, ethylene glycol monoethyl ether, propylene glycol, propylene glycol monomethyl ether, propylene glycol monoethyl ether and ethyl lactate. Among these, propylene glycol monomethyl ether and ethyl lactate are preferred.

Examples of the solvent having no hydroxyl group include propylene glycol monomethyl ether acetate, ethyl ethoxypropionate, 2-heptanone, γ-butyrolactone, cyclohexanone, butyl acetate, N-methylpyrrolidone, N,N-dimethylacetamide and dimethylsulfoxide. Among these, propylene glycol monomethyl ether acetate, ethyl ethoxypropionate, 2-heptanone, γ-butyrolactone, cyclohexanone and butyl acetate are preferred, and propylene glycol monomethyl ether acetate, ethyl ethoxypropionate and 2-heptanone are more preferred.

The mixing ratio (by mass) of the solvent having a hydroxyl group and the solvent having no hydroxyl group is preferably from 1/99 to 99/1, more preferably from 10/90 to 90/10, still more preferably from 20/80 to 60/40. A mixed solvent containing 50 mass % or more of a solvent having no hydroxyl group is preferred in view of coating uniformity.

### (H) Use Method

From the standpoint of enhancing the resolution, the negative resist composition of the present invention is preferably used in a film thickness of 30 to 250 nm, more preferably from 30 to 200 nm. Such a film thickness can be obtained by setting the solid content concentration in the negative resist composition to a proper range so as to impart an appropriate viscosity and enhance the coatability and film-forming property.

The entire solid content concentration in the negative resist composition is generally from 1 to 10 mass %, preferably from 1 to 8 mass %, more preferably from 1 to 6 mass %.

The negative resist composition of the present invention is used by dissolving the above-described components in a predetermined organic solvent, preferably the mixed solvent above, filtering the solution through a filter, and coating it on a predetermined support as follows. The filter used for filtration is preferably a polytetrafluoroethylene-, polyethylene- or nylon-made filter having a pore size of 0.1 micron or less, more preferably 0.05 microns or less, still more preferably 0.03 microns or less.

For example, the negative resist composition is coated on such a substrate (e.g., silicon/silicon dioxide-coated substrate) as used in the production of a precision integrated circuit device, by an appropriate coating method such as spinner or coater, and dried to form a resist film.

The resist film formed is irradiated with an actinic ray or radiation through a predetermined mask and subjected to development and rinsing. A baking step may be provided after the irradiation with an actinic ray or radiation. By such a process, a good pattern can be obtained.

Examples of the actinic ray or radiation include infrared light, visible light, ultraviolet light, far ultraviolet light, X-ray and electron beam, but the radiation is preferably far ultraviolet light at a wavelength of 250 nm or less, more preferably 220 nm or less, still more preferably from 1 to 200 nm. Specific examples thereof include KrF excimer laser (wavelength: 248 nm), ArF excimer laser (wavelength: 193 nm), F₂ excimer laser (wavelength: 157 nm), X-ray and electron beam. Of these, ArF excimer laser (wavelength: 193 nm), F₂ excimer laser (157 nm), EUV (wavelength: 13 nm) and electron beam are preferred, and ArF excimer laser (wavelength: 193 nm) is more preferred.

Before forming the resist film, an antireflection film may be previously provided by coating on the substrate.

The antireflection film used may be either an inorganic film type such as titanium, titanium dioxide, titanium nitride, chromium oxide, carbon and amorphous silicon, or an organic film type composed of a light absorber and a polymer material. Also, the organic antireflection film may be a commercially available organic antireflection film such as DUV30 Series and DUV-40 Series produced by Brewer Science, Inc., and AR-2, AR-3 and AR-5 produced by Shipley Co., Ltd.

In the development step, an alkali developer is used as follows. The alkali developer which can be used for the negative resist composition is an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine.

Furthermore, this alkali developer may be used after adding thereto an appropriate amount of alcohols or a surfactant.

The alkali concentration of the alkali developer is preferably from 0.1 to 20 mass %.

The pH of the alkali developer is preferably from 10.0 to 15.0.

Also, the above-described alkaline aqueous solution may be used after adding thereto an appropriate amount of alcohols or a surfactant.

As for the rinsing solution, pure water is used, and the pure water may be used after adding thereto an appropriate amount of a surfactant.

After the development or rinsing, a treatment of removing the developer or rinsing solution adhering on the pattern by a supercritical fluid may be performed.

### EXAMPLES

Working examples of, the present invention are described below, but the present invention is not limited thereto.

### Synthesis Example 1

### Synthesis of Resin 1

In a nitrogen stream, 18.1 g of a mixed solvent of PGMEA (propylene glycol monomethyl ether acetate)/PGME (propylene glycol monomethyl ether) (mass ratio: 2/8) was charged into a three-neck flask and heated to 80° C. Thereto, a solution prepared by dissolving 4.3 g of methacrylic acid, 35.5 g of 3-hydroxyadamantyl methacrylate and polymerization initiator V-601 (produced by Wako Pure Chemical Industries, Ltd.) in a ratio of 12 mol % based on the monomers, in 163.0 g of a PGMEA/PGME (mass ratio: 2/8) mixed solvent was added dropwise over 6 hours. After the completion of dropwise addition, the reaction was further allowed to proceed at 80° C. for 2 hours. The resulting reaction solution was left standing to cool and then added dropwise to a mixed solution of 1,400 ml of hexane/600 ml of ethyl acetate over 20 minutes, and the precipitated powder was collected by filtration and dried, as a result, 26.4 g of Resin 1 was obtained. The mass average molecular weight of the resin obtained was 7,600 in terms of standard polystyrene and the polydispersity (Mw/Mn) was 1.82.

Resins 2 to 10 were synthesized in the same manner. The structure, molar ratio, weight average molecular weight and polydispersity of each of the resins, synthesized are shown in Table 2 below.

TABLE 2

| | First | Second | Third | Fourth | Composi- | | |
|---|---|---|---|---|---|---|---|
| No. | Component | Component | Component | Component | tion | Mw | Mw/Mn |
| 1 | 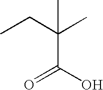 | 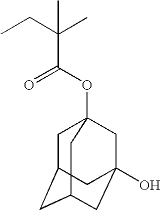 | | | 25/75 | 7600 | 1.82 |
| 2 | 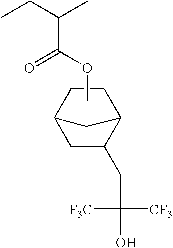 | 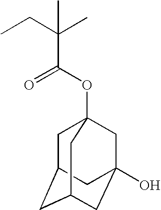 | | 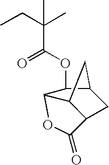 | 40/35/25 | 8900 | 2.01 |
| 3 | 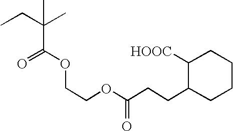 | 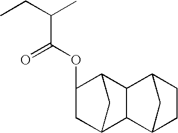 | 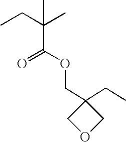 | 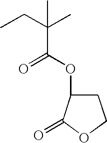 | 30/40/15/15 | 7800 | 1.93 |
| 4 | 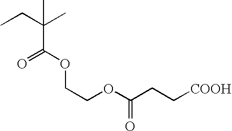 | 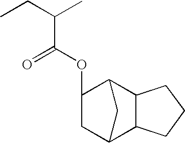 | 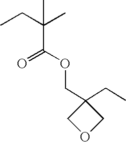 | | 25/50/25 | 7800 | 1.82 |
| 5 | 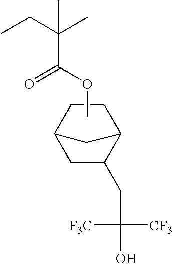 | 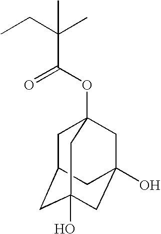 | | 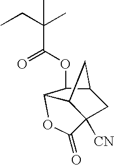 | 57/28/15 | 8000 | 1.72 |
| 6 | 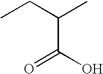 | 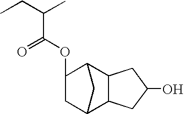 | 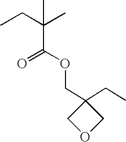 | 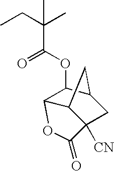 | 15/55/10/20 | 7700 | 1.91 |
| 7 | 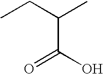 | 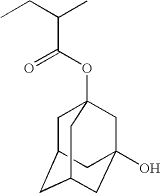 | 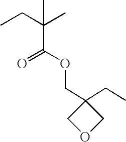 | | 23/55/22 | 7500 | 1.81 |
| 8 | 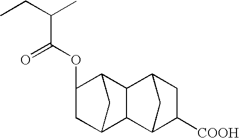 | 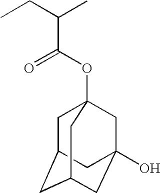 | 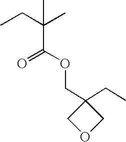 | | 35/40/25 | 7400 | 1.78 |
| 9 | 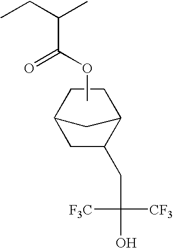 | 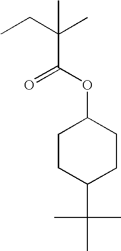 | | 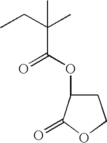 | 42/31/27 | 7200 | 1.80 |
| 10 | 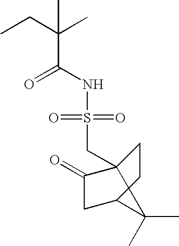 | 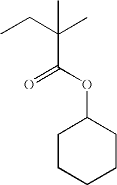 | 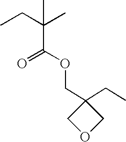 | 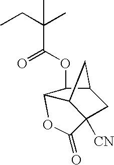 | 30/20/25/25 | 8200 | 1.74 |

### Examples 1 to 30 and Comparative Examples 1 to 3

### Preparation of Resist

The components shown in Table 3 below were dissolved in a solvent to prepare a solution having a solid content concentration of 4.8 mass %, and the obtained solution was filtered through a polyethylene filter having a pore size of 0.1 micron to prepare a negative resist solution. The negative resist solutions prepared were evaluated by the following methods, and the results are shown in Table 3. As for each component in Table 3, the ratio when a plurality of kinds were used is a ratio by mass.

### (Exposure Condition (1))

An organic antireflection film ARC29A (produced by Nissan Chemical Industries, Ltd.) was coated on a silicone wafer and baked at 205° C. for 60 seconds to form a 78 nm-thick antireflection film. The negative resist solution prepared above was coated thereon and baked at 105° C. for 60 seconds to form a 120 nm-thick resist film. The obtained wafer was subjected to pattern exposure by using an ArF excimer laser scanner (PAS5500/1100, NA: 0.75, σo/σi=0.85/0.55, manufactured by ASML). Thereafter, the wafer was heated at 100° C. for 60 seconds, developed with an aqueous tetramethylammonium hydroxide solution (2.38 mass %) for 30 seconds, rinsed with pure water and spin-dried to obtain a resist pattern.

### (Exposure Condition (2))

This condition is to form a resist pattern by an immersion exposure method using pure water.

An organic antireflection film ARC29A (produced by Nissan Chemical Industries, Ltd.) was coated on a silicone wafer and baked at 205° C. for 60 seconds to form a 78 nm-thick antireflection film. The negative resist solution prepared above was coated thereon and baked at 105° C. for 60 seconds to form a 120 nm-thick resist film. The obtained wafer was subjected to pattern exposure by using an ArF excimer laser immersion scanner (NA: 0.85). As for the immersion liquid, ultrapure water was used. Thereafter, the wafer was heated at 100° C. for 60 seconds, developed with an aqueous tetramethylammonium hydroxide solution (2.38 mass %) for 30 seconds, rinsed with pure water and spin-dried to obtain a resist pattern.

With respect to Examples 1 to 25 and Comparative Examples 1 to 3 in (Exposure Condition (1)) and Examples 26 to 30 in (Exposure Condition (2)), the obtained resist pattern was evaluated for pattern profile and pattern collapse.

### [Pattern Profile]

The exposure dose for reproducing a line-and-space 1/1 pattern in a mask size of 130 nm was taken as an optimal exposure dose, and the profile at the optimal exposure dose was observed by a scanning electron microscope (SEM). The pattern profile was rated as A, B, C and D, with A being the best, and when the profile could not be evaluated, this was indicated by “−”.

### Pattern Collapse (PC):

The exposure dose for reproducing a line-and-space 1:1 mask pattern of 130 nm was taken as an optimal exposure dose and with respect to a line-and-space 1:1 dense pattern, the line width at which the pattern was resolved without collapse to a finer mask size than that when exposed with the optimal exposure dose was defined as a limiting pattern collapse line width (nm). A smaller value indicates that a finer pattern is resolved without collapse, namely, pattern collapse is less liable to occur and the performance is higher.

TABLE 3

| | | (B) | | (C) Photo- | | Solvent | | | | | | | | |
|---|---|---|---|---|---|---|---|---|---|---|---|---|---|---|
| | | Polymerizable | | polymerization | | | | Ratio | | Basic | | | | |
| | (A) Resin | Monomer | | Initiator | | | | by | | Compound | | Surfactant | Pattern | PC |
| | (10 g) | Kind | (g) | Kind | (g) | Kind | | Mass | | Kind | (mg) | (0.1 mg) | Profile | (nm) |
| Example | | | | | | | | | | | | | | |
| 1 | 1 | CLO-2 | 6.85 | PAG-G | 0.72 | A1 | A3 | 70 | 30 | PEA | 15 | W-3 | A | 93 |
| 2 | 2 | CLO-2 | 6.85 | PAG-G | 0.72 | A3 | B3 | 50 | 50 | DCMA | 12 | W-1 | A | 84 |
| 3 | 3 | CLO-2 | 6.85 | PAG-G | 0.72 | A2 | B1 | 50 | 50 | TPSA | 13 | W-2 | A | 88 |
| 4 | 4 | CLO-2 | 6.85 | PAG-G | 0.72 | A1 | B1 | 60 | 40 | DHA | 10 | W-5 | A | 76 |
| 5 | 5 | CLO-2 | 6.85 | PAG-G | 0.72 | A2 | B2 | 40 | 60 | TPI | 11 | W-3 | A | 84 |
| 6 | 6 | CLO-2 | 6.85 | PAG-G | 0.72 | A1 | B1 | 50 | 50 | DIA | 15 | W-4 | A | 80 |
| 7 | 7 | CLO-2 | 6.85 | PAG-G | 0.72 | A2 | B2 | 60 | 40 | TPI | 12 | W-3 | A | 88 |
| 8 | 8 | CLO-2 | 6.85 | PAG-G | 0.72 | A1 | B1 | 70 | 30 | PEA | 15 | W-6 | A | 80 |
| 9 | 9 | CLO-2 | 6.85 | PAG-G | 0.72 | A3 | B1 | 40 | 60 | HEP | 11 | W-3 | A | 84 |
| 10 | 10 | CLO-2 | 6.85 | PAG-G | 0.72 | A1 | B3 | 55 | 45 | TOA | 10 | W-4 | A | 64 |
| 11 | 9 | CLO-1 | 13.9 | PAG-G | 0.72 | A1 | B1 | 70 | 30 | TPI | 13 | W-3 | A | 88 |
| 12 | 9 | CLO-2 | 7.01 | PAG-G | 0.72 | A3 | B2 | 50 | 50 | HEP | 13 | W-2 | B | 84 |
| 13 | 9 | CLO-3 | 3.65 | PAG-G | 0.72 | A3 | B2 | 50 | 50 | TOA | 12 | W-1 | B | 80 |
| 14 | 4 | CLO-1 | 12.3 | PAG-A | 0.6 | A1 | A3 | 60 | 40 | DIA | 15 | W-3 | A | 101 |
| 15 | 4 | CLO-1 | 12.3 | PAG-B | 0.44 | A1 | A3 | 70 | 30 | TPA | 14 | W-3 | A | 99 |
| 16 | 4 | CLO-1 | 12.3 | PAG-C | 0.59 | A2 | B1 | 40 | 60 | HAP | 12 | W-3 | A | 88 |
| 17 | 4 | CLO-1 | 12.3 | PAG-D | 0.9 | A1 | B1 | 70 | 30 | TOA | 13 | W-4 | A | 93 |
| 18 | 4 | CLO-1 | 12.3 | PAG-E | 0.76 | A1 | A3 | 40 | 60 | TBAH | 12 | W-3 | A | 93 |
| 19 | 4 | CLO-1 | 12.3 | PAG-F | 0.91 | A1 | B3 | 50 | 50 | TPI | 15 | W-4 | A | 93 |
| 20 | 4 | CLO-1 | 12.3 | PAG-G | 0.72 | A1 | A3 | 60 | 40 | TPI | 10 | W-5 | A | 84 |
| 21 | 4 | CLO-1 | 12.3 | PAG-H | 1.04 | A1 | B1 | 50 | 50 | PBI | 15 | W-3 | A | 81 |
| 22 | 10 | CLO-1 | 5.61 | PAG-H | 0.86 | A1 | A3 | 60 | 40 | DBN | 15 | W-6 | A | 71 |
| 23 | 10 | CLO-1 | 11.8 | PAG-H | 0.86 | A1 | A3 | 70 | 30 | PBI | 14 | W-4 | A | 67 |
| 24 | 10 | CLO-1 | 13.5 | PAG-H | 0.86 | A3 | B2 | 40 | 60 | PEA | 14 | W-3 | A | 66 |
| 25 | 10 | CLO-3 | 3.84 | PAG-E | 0.59 | A1 | A3 | 60 | 40 | TPI | 10 | W-5 | A | 61 |
| 26* | 4 | CLO-2 | 6.85 | PAG-G | 0.72 | A1 | B1 | 60 | 40 | DHA | 10 | W-5 | A | 65 |
| 27* | 5 | CLO-2 | 6.85 | PAG-G | 0.72 | A2 | B2 | 40 | 60 | TPI | 11 | W-3 | A | 79 |
| 28* | 9 | CLO-1 | 13.9 | PAG-G | 0.72 | A1 | B1 | 70 | 30 | TPI | 13 | W-3 | A | 75 |
| 29* | 9 | CLO-2 | 7.01 | PAG-G | 0.72 | A3 | B2 | 50 | 50 | HEP | 13 | W-2 | A | 70 |
| 30* | 10 | CLO-3 | 3.84 | PAG-E | 0.59 | A1 | A3 | 60 | 40 | TPI | 10 | W-5 | A | 56 |
| Comparative | | | | | | | | | | | | | | |
| Example | | | | | | | | | | | | | | |
| 1 | 1 | — | — | PAG-A | 0.6 | A1 | A3 | 70 | 30 | PEA | 13 | W-2 | — | — |
| 2 | 4 | — | — | PAG-A | 0.6 | A1 | A3 | 70 | 30 | PEA | 13 | W-2 | D | 125 |
| 3 | 2 | CLO-4 | 6.85 | PAG-A | 0.6 | A1 | A3 | 70 | 30 | PEA | 13 | W-2 | C | 113 |

*Hydrophobic Resin (HR-22) (0.05 g) was further added, and immersion exposure was performed.

### [Photopolymerization Initiator]

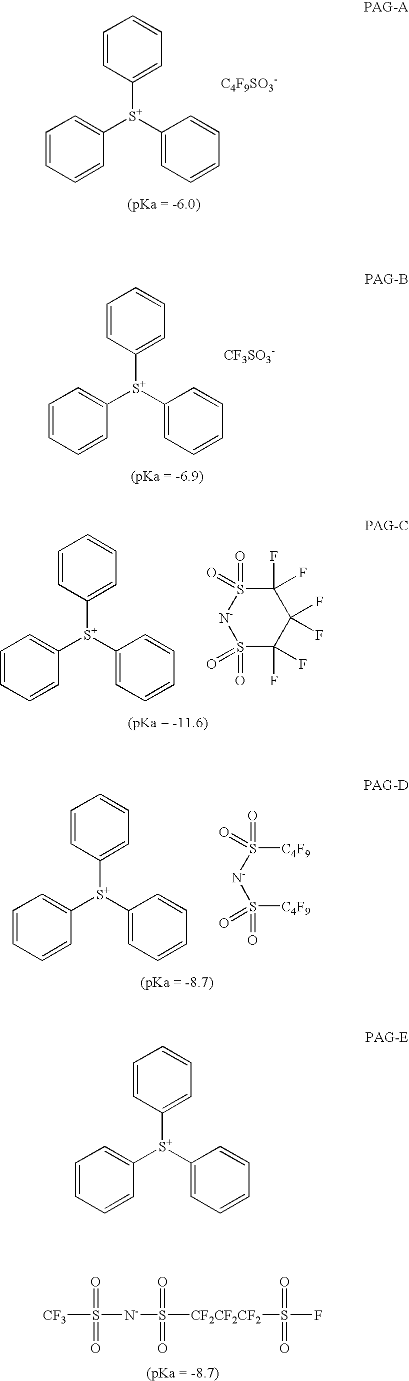

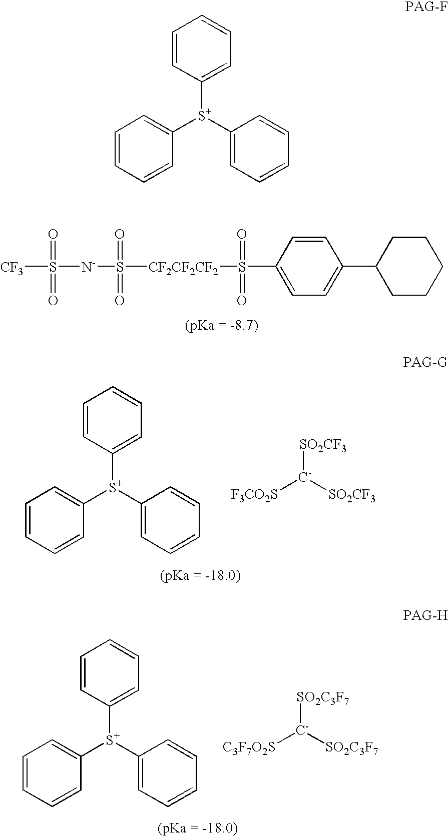

### [Polymerizable Monomer]

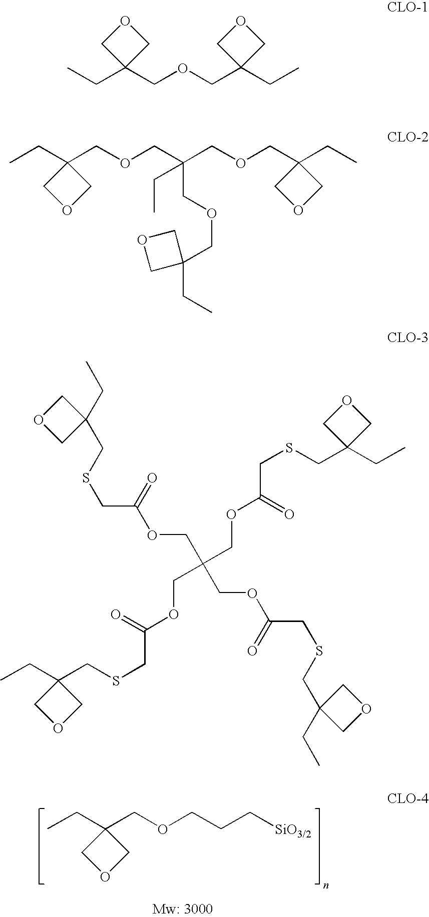

### [Basic Compound]

### HEP: N-Hydroxyethylpiperidine

### DIA: 2,6-Diisopropylaniline

### PEA: N-Phenyldiethanolamine

### TOA: Trioctylamine

### PBI: 2-Phenylbenzimidazole

### DCMA: Dicyclohexylmethylamine

TPSA: Triphenylsulfonium acetate

### DHA: N,N-Dihexylaniline

### TPI: 2,4,5-Triphenylimidazole

### HAP: Hydroxyantipyrine

TBAH: Tetrabutylammonium hydroxide
DBN: 1,5-Diazabicyclo[4.3.0]non-5-ene

### TPA: Tripentylamine

### [Surfactant]

W-1: Megaface F176 (produced by Dainippon Ink & Chemicals, Inc.) (fluorine-containing)
W-2: Megaface R08 (produced by Dainippon Ink & Chemicals, Inc.) (fluorine- and silicon-containing)
W-3: Polysiloxane Polymer KP-341 (produced by Shin-Etsu Chemical Co., Ltd.) (silicon-containing)
W-4: Troysol S-366 (produced by Troy Chemical)
W-5: PF656 (produced by OMNOVA, fluorine-containing)
W-6: PF6320 (produced by OMNOVA, fluorine-containing)

### [Solvent]

A 1: Propylene glycol monomethyl ether acetate

### A2: 2-Heptanone

### A3: Cyclohexanone

B1: Propylene glycol monomethyl ether
B2: Ethyl lactate
B3: Propylene carbonate

As apparent from Table 3, the negative resist composition of the present invention hardly allows occurrence of pattern collapse and exhibits good resolution.

### INDUSTRIAL APPLICABILITY

According to the present invention, a negative resist composition ensuring no pattern collapse and good resolution even in the formation of a fine pattern, and a resist pattern forming method using the composition can be provided.

The negative resist composition of the present invention and the resist pattern forming method using the same are used in lithography for the production of a semiconductor device such as IC, a liquid crystal display device or a circuit board such as thermal head and further for other photofabrication processes.

While the invention has been described in detail and with reference to specific embodiments thereof, it will be apparent to one skilled in the art that various changes and modifications can be made therein without departing from the spirit and scope of the present invention.

This application is based on Japanese Patent Application (Japanese Patent Application No. 2007-250035) filed on Sep. 26, 2007 and Japanese Patent Application (Japanese Patent Application No. 2008-074734) filed on Mar. 21, 2008, the contents of which are incorporated herein by way of reference.

1. A negative resist composition comprising:
(A) an alkali-soluble resin,
(B) a low molecular compound having a molecular weight of 2,000 or less and having an oxetane structure, and
(C) a cationic photopolymerization initiator.

2. The negative resist composition as claimed in claim 1, wherein
said (B) low molecular compound having an oxetane structure is a compound having a plurality of oxetane structures in the molecule.

3. The negative resist composition as claimed in claim 1, wherein
said (A) alkali-soluble resin contains (a1) a repeating unit containing a group having solubility in an alkali developer and (a2) a repeating unit having an alicyclic group.

4. The negative resist composition as claimed in claim 1, wherein
said (A) alkali-soluble resin further contains (a3) a repeating unit having an oxetane structure.

5. The negative resist composition as claimed in claim 1, wherein
the acid generated from the component (C) upon irradiation with an actinic ray or radiation has a pKa of −8 or less.

6. A resist pattern forming method comprising:
a step of forming a resist film by using the negative resist composition claimed in claim 1,
a step of exposing said resist film, and
a step of developing said resist film.
